(19) United States
(12) Patent Application Publication
(10) Pub. No.: US 2024/0164167 A1
(43) Pub. Date: May 16, 2024

(54) ELECTRONIC DEVICE

(71) Applicant: Semiconductor Energy Laboratory Co., Ltd., Atsugi-shi, Kanagawa-ken (JP)

(72) Inventors: Daisuke KUBOTA, Atsugi (JP); Ryo HATSUMI, Hadano (JP); Junpei MOMO, Sagamihara (JP)

(21) Appl. No.: 18/281,593

(22) PCT Filed: Mar. 15, 2022
(86) PCT No.: PCT/IB2022/052305

§ 371 Date: Sep. 12, 2023

(30) Foreign Application Priority Data
Mar. 25, 2021 (JP) 2021-051461

(51) Int. Cl. H10K 59/35; H10K 39/34

(52) U.S. Cl. CPC H10K 59/353; H10K 39/34

(57) ABSTRACT

Provided is an electronic device that can be operated without contact. The electronic device includes a display portion, a processing portion, and a memory portion. The display portion includes a display apparatus including a light-emitting device and a light-receiving device. The display portion has a function of displaying an image using the light-emitting device and a function of capturing an image using the light-receiving device. The memory portion has a machine learning model using a neural network. The processing portion has a function of inferring position data of an object not in contact with the electronic device using the machine learning model from image capturing data captured by the display portion.

### TECHNICAL FIELD

One embodiment of the present invention relates to a display apparatus, a display module, and an electronic device.

Note that one embodiment of the present invention is not limited to the above technical field. Examples of the technical field of one embodiment of the present invention include a semiconductor device, a display apparatus, a light-emitting apparatus, a power storage device, a memory device, an electronic device, a lighting device, an input device (e.g., a touch sensor), an input/output device (e.g., a touch panel), a driving method thereof, and a manufacturing method thereof.

### BACKGROUND ART

In recent years, information terminal devices, for example, mobile phones such as smartphones, tablet information terminals, and notebook PCs (personal computers) have been widely used. Such information terminal devices often include personal information or the like, and thus various authentication technologies for preventing unauthorized use have been developed. Information terminal devices have been required to have a variety of functions such as an image display function, a touch sensor function, and a function of capturing images of fingerprints for authentication.

For example, Patent Document 1 discloses an electronic device provided with a fingerprint sensor in a push button switch portion.

Light-emitting apparatuses including light-emitting devices (also referred to as light-emitting elements) have been developed as display apparatuses, for example. Light-emitting devices (also referred to as EL devices or EL elements) utilizing electroluminescence (hereinafter referred to as EL) have features such as ease of reduction in thickness and weight, high-speed response to input signals, and driving with a constant DC voltage power source, and have been used in display apparatuses.

### REFERENCE

### Patent Document

[Patent Document 1] Specification of United States Published Patent Application No. 2014/0056493

### SUMMARY OF THE INVENTION

### Problems to be Solved by the Invention

From the perspectives of measures against infectious diseases, hygiene, and the like, information terminal devices that can be operated without contact are desired.

An object of one embodiment of the present invention is to provide an electronic device that can be operated without contact.

An object of one embodiment of the present invention is to provide a high-resolution display apparatus having a light detection function. An object of one embodiment of the present invention is to provide a high-definition display apparatus having a light detection function. An object of one embodiment of the present invention is to provide a highly reliable display apparatus having a light detection function.

Note that the description of these objects does not preclude the existence of other objects. One embodiment of the present invention does not need to achieve all of these objects. Other objects can be derived from the description of the specification, the drawings, and the claims.

### Means for Solving the Problems

One embodiment of the present invention is an electronic device including a display portion, a processing portion, and a memory portion, and the display portion includes a display apparatus including a light-emitting device and a light-receiving device. The display portion has a function of displaying an image using the light-emitting device and a function of capturing an image using the light-receiving device. The memory portion has a machine learning model using a neural network. The processing portion has a function of inferring position data of an object not in contact with the electronic device using the machine learning model from image capturing data captured by the display portion.

One embodiment of the present invention is an electronic device including a display portion, a processing portion, and a memory portion, and the display portion includes a display apparatus including a first pixel. The first pixel includes a first light-emitting device, a first light-receiving device, and a second light-receiving device; a wavelength range of light detected by the first light-receiving device includes a maximum peak wavelength in an emission spectrum of the first light-emitting device; and the second light-receiving device has a function of detecting infrared light. The display portion has a function of displaying an image using the first light-emitting device and a function of capturing an image using one or both of the first light-receiving device and the second light-receiving device. The memory portion has a machine learning model using a neural network. The processing portion has a function of inferring position data of an object not in contact with the electronic device using the machine learning model from image capturing data captured by the display portion.

One embodiment of the present invention is an electronic device including a display portion, a processing portion, and a memory portion, and the display portion includes a display apparatus including a first pixel. The first pixel includes a first subpixel, a second subpixel, a third subpixel, a fourth subpixel, and a fifth subpixel. The first subpixel includes a first light-emitting device and has a function of emitting red light. The second subpixel includes a second light-emitting device and has a function of emitting green light. The third subpixel includes a third light-emitting device and has a function of emitting blue light. The fourth subpixel includes a first light-receiving device, and a wavelength range of light detected by the first light-receiving device includes a maximum peak wavelength in an emission spectrum of at least one of the first light-emitting device, the second light-emitting device, and the third light-emitting device. The fifth subpixel includes a second light-receiving device and has a function of detecting infrared light. The display portion has a function of displaying an image using the first subpixel to the third subpixel and a function of capturing an image using one or both of the first light-receiving device and the second light-receiving device. The memory portion has a machine learning model using a neural network. The processing portion has a function of inferring position data of an object not in contact with the electronic device using the machine learning model from image capturing data captured by the display portion.

An area of a light-receiving region of the first light-receiving device is preferably smaller than an area of a light-receiving region of the second light-receiving device.

The display apparatus preferably includes a second pixel including the first light-emitting device, the first light-receiving device, and a sensor device. The electronic device preferably has a function of measuring, with the sensor device, at least one of force, displacement, position, speed, acceleration, angular velocity, rotational frequency, distance, magnetism, temperature, chemical substance, time, hardness, electric field, electric current, voltage, electric power, radiation, flow rate, humidity, gradient, oscillation, odor, physical condition, pulse, body temperature, and blood oxygen level.

Alternatively, the display apparatus preferably includes a second pixel including the first light-emitting device, a fourth light-emitting device, and the first light-receiving device. The fourth light-emitting device preferably has a function of emitting infrared light.

Alternatively, the electronic device of one embodiment of the present invention may include a fourth light-emitting device having a function of emitting infrared light outside the display apparatus. The fourth light-emitting device may emit light outside the electronic device through the display apparatus.

### Effect of the Invention

According to one embodiment of the present invention, a display apparatus that can be operated without contact can be provided.

One embodiment of the present invention can provide a high-resolution display apparatus having a light detection function. One embodiment of the present invention can provide a high-definition display apparatus having a light detection function. One embodiment of the present invention can provide a highly reliable display apparatus having a light detection function.

Note that the description of these effects does not preclude the existence of other effects. One embodiment of the present invention does not need to have all of these effects. Other effects can be derived from the description of the specification, the drawings, and the claims.

### BRIEF DESCRIPTION OF THE DRAWINGS

FIG. 1A is a diagram illustrating an example of an electronic device. FIG. 1B is a diagram illustrating an example of processing executed by the electronic device.

FIG. 2A to FIG. 2G are diagrams illustrating examples of pixels in a display apparatus.

FIG. 3A and FIG. 3B are diagrams illustrating examples of a pixel in a display apparatus. FIG. 3C and FIG. 3D are cross-sectional views illustrating examples of an electronic device.

FIG. 4A and FIG. 4B are cross-sectional views illustrating an example of an electronic device.

FIG. 5A to FIG. 5D are diagrams illustrating examples of pixels in a display apparatus. FIG. 5E is a cross-sectional view illustrating an example of an electronic device.

FIG. 6 is a diagram illustrating an example of a layout of a display apparatus.

FIG. 7 is a diagram illustrating an example of a layout of a display apparatus.

FIG. 8 is a diagram illustrating an example of a layout of a display apparatus.

FIG. 9 is a diagram illustrating an example of a layout of a display apparatus.

FIG. 10 is a diagram illustrating an example of a pixel circuit.

FIG. 11A is a top view illustrating an example of a display apparatus. FIG. 11B is a cross-sectional view illustrating the example of the display apparatus.

FIG. 12A to FIG. 12C are cross-sectional views illustrating examples of a display apparatus.

FIG. 13A and FIG. 13B are cross-sectional views illustrating examples of a display apparatus.

FIG. 14A to FIG. 14C are cross-sectional views illustrating examples of a display apparatus.

FIG. 15A to FIG. 15F are cross-sectional views illustrating examples of a display apparatus.

FIG. 16 is a perspective view illustrating an example of a display apparatus.

FIG. 17A is a cross-sectional view illustrating an example of a display apparatus. FIG. 17B and

FIG. 17C are cross-sectional views illustrating examples of transistors.

FIG. 18A to FIG. 18D are cross-sectional views illustrating examples of a display apparatus.

FIG. 19A to FIG. 19F are diagrams illustrating structure examples of a light-emitting device.

FIG. 20A and FIG. 20B are diagrams illustrating an example of an electronic device.

FIG. 21A to FIG. 21D are diagrams illustrating examples of electronic devices.

FIG. 22A to FIG. 22F are diagrams illustrating examples of electronic devices.

FIG. 23A is a diagram for illustrating an evaluation method in Example. FIG. 23B to FIG. 23D are photographs captured by a display apparatus.

### MODE FOR CARRYING OUT THE INVENTION

Embodiments are described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. Furthermore, the same hatching pattern is used for the portions having similar functions, and the portions are not especially denoted by reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

The term “film” and the term “layer” can be interchanged with each other depending on the case or circumstances. For example, the term “conductive layer” can be replaced with the term “conductive film”. For another example, the term “insulating film” can be replaced with the term “insulating layer”.

### Embodiment 1

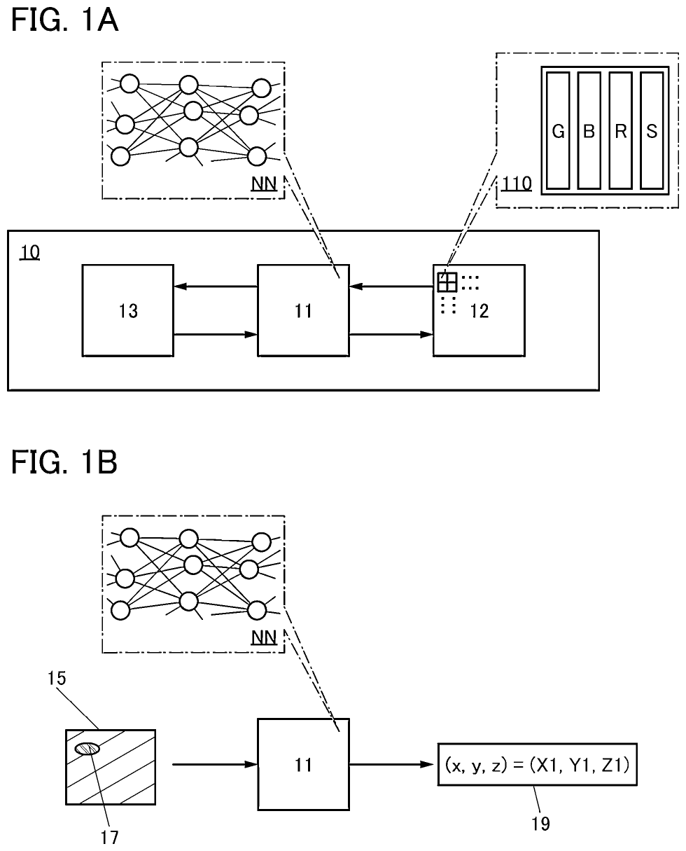

In this embodiment, an electronic device and a display apparatus of one embodiment of the present invention will be described with reference to FIG. 1 to FIG. 10.

One embodiment of the present invention is an electronic device including a display portion, a processing portion, and a memory portion. The display portion includes a display apparatus including a light-emitting device and a light-receiving device. The display portion has a function of displaying an image using the light-emitting device and a function of capturing an image using the light-receiving device. The memory portion has a machine learning model using a neural network. The processing portion has a function of inferring position data of an object not in contact with the electronic device using the machine learning model from image capturing data captured by the display portion.

The use of the machine learning model can increase inference accuracy. Since the display apparatus has an image capturing function, a multifunctional electronic device can be obtained without increasing the number of components of the electronic device.

It is preferable to use artificial intelligence (AI) for at least part of processing of the electronic device of one embodiment of the present invention.

It is particularly preferable to use an artificial neural network (ANN; hereinafter just referred to as neural network) for the electronic device of one embodiment of the present invention. The neural network is obtained with a circuit (hardware) or a program (software).

In this specification and the like, a neural network refers to a general model that is modeled on a biological neural network, determines the connection strength of neurons by learning, and has the capability of solving problems. A neural network includes an input layer, intermediate layers (hidden layers), and an output layer.

In the description of the neural network in this specification and the like, to determine a connection strength of neurons (also referred to as a weight coefficient) from the existing information is referred to as “learning” in some cases.

In this specification and the like, to draw a new conclusion from a neural network formed with the connection strength obtained by learning is referred to as “inference” in some cases.

### [Electronic Device 10]

FIG. 1A is a block diagram of the electronic device of one embodiment of the present invention.

An electronic device 10 illustrated in FIG. 1A includes a processing portion 11, a display portion 12, and a memory portion 13.

The display portion 12 includes a display apparatus including a light-emitting device and a light-receiving device. FIG. 1A illustrates an example of using, for the display portion 12, a display apparatus including a pixel 110 that includes a subpixel G, a subpixel B, a subpixel R, and a subpixel S.

The subpixel G, the subpixel B, and the subpixel R each include a light-emitting device. The subpixel R emits red light, the subpixel G emits green light, and the subpixel B emits blue light.

The subpixel S includes a light-receiving device. There is no particular limitation on the wavelength of light detected by the light-receiving device. A light-receiving device that detects one or both of visible light and infrared light can be used for the subpixel S, for example.

The display portion 12 has a function of displaying an image using the subpixel G, the subpixel B, and the subpixel R (the light-emitting devices) and a function of capturing an image using the subpixel S (the light-receiving device).

The memory portion 13 has a machine learning model using a neural network. Note that the memory portion 13 may be part of the processing portion 11.

The processing portion 11 has a function of inferring position data of an object using the machine learning model from image capturing data captured by the display portion 12. The object may or may not be in contact with the electronic device 10.

A convolutional neural network (CNN) is preferably used for the machine learning model.

The machine learning model preferably learns using image data of an object to be detected. For example, image data of one or more of objects including fingers, hands, and pens can be used. The learning is preferably performed using image data of not only bare hands but also objects of various materials and colors, for example, hands with gloves. In that case, even when the user of the electronic device 10 puts gloves on, the position of an object (a finger or a hand with a glove) can be inferred with high accuracy. It is further preferable that the learning be performed using image data of the case where dust, a drop of water, or the like is attached to the surface of the display portion 12. In that case, the position of an object can be inferred with high accuracy even when dust, a drop of water, or the like is attached to the surface of the display portion 12.

For the learning of the machine learning model, either supervised machine learning or unsupervised machine learning is used.

There is no particular limitation on the machine learning model, and a regression model, a classification model, or a clustering model can be used, for example.

In the case of using a regression model, supervised machine learning in which image data is given as input data (examples) and position data is given as output data (answers) is preferably used as the learning, for example.

In the case of using a classification model, supervised machine learning in which image data is given as input data (examples) and classification data is given as output data (answers) is preferably used as the learning, for example.

In the case of using a clustering model, it is preferable that unsupervised machine learning in which image data is given as input data be performed and then the obtained clusters be labeled.

An example of processing using the processing portion 11 in the electronic device 10 will be described with reference to FIG. 1B.

In the electronic device 10, the display portion 12 can capture an image of an object and the processing portion 11 can infer position data of the object.

As illustrated in FIG. 1B, the processing portion 11 performs processing using a neural network NN. Image capturing data 15 captured by the display portion 12 is input to the processing portion 11. An image 17 of the object is in the image capturing data 15. The image capturing data 15 including the image 17 can be obtained when the light-receiving device detects reflected light, which is reflected by the object, of light from a light source. The processing portion 11 infers position data 19 of the image 17 utilizing a machine learning model using the neural network NN when the image capturing data 15 is input. FIG. 1B illustrates an example in which three-dimensional position data of (x, y, z)=(X1, Y1, Z1) is inferred as the position data 19.

The processing portion 11 can execute processing on the basis of the inferred position data. For example, a signal or a potential supplied to the display portion 12 can be controlled.

In the above manner, a non-contact object is detected and its position data is inferred using the processing portion 11 and the display portion 12, whereby the electronic device 10 can have a non-contact sensor function. Note that the non-contact sensor function can also be referred to as a hover sensor function, a hover touch sensor function, a near touch sensor function, a touchless sensor function, or the like. The electronic device 10 can have a touch sensor function (also referred to as a direct touch sensor function) when an object in contact with the electronic device 10 is detected and its position data is inferred using the processing portion 11 and the display portion 12.

One or both of the non-contact sensor function and the touch sensor function enable the electronic device 10 to detect operation such as tap, long-tap, flick, drag, scroll, multi-touch, swipe, pinch-in, or pinch-out and execute processing in accordance with the operation.

### [Processing Portion 11]

The processing portion 11 has a function of performing arithmetic, inference, and the like using data supplied from the display portion 12, the memory portion 13, and the like. The processing portion 11 can supply arithmetic results, inference results, and the like to the memory portion 13 or the like. The processing portion 11 can control a signal or a potential supplied to the display portion 12 on the basis of the arithmetic results, the inference results, and the like. The processing portion 11 includes, for example, an arithmetic circuit, a central processing unit (CPU), or the like.

The processing portion 11 may include a microprocessor such as a DSP (Digital Signal Processor) or a GPU (Graphics Processing Unit). The microprocessor may be constructed with a PLD (Programmable Logic Device) such as an FPGA (Field Programmable Gate Array) or an FPAA (Field Programmable Analog Array). The processing portion 11 can interpret and execute instructions from programs with the use of a processor to process various kinds of data and control programs. The programs to be executed by the processor are stored in at least one of a memory region of the processor and the memory portion 13.

The processing portion 11 may include a main memory. The main memory includes at least one of a volatile memory such as a RAM (Random Access Memory) and a nonvolatile memory such as a ROM (Read Only Memory).

A DRAM (Dynamic Random Access Memory), an SRAM (Static Random Access Memory), or the like is used as the RAM, for example, and a memory space is virtually assigned as a workspace for the processing portion 11 to be used. An operating system, an application program, a program module, program data, a look-up table, and the like that are stored in the memory portion 13 are loaded into the RAM for execution. The data, program, and program module that are loaded into the RAM are each directly accessed and operated by the processing portion 11.

In the ROM, a BIOS (Basic Input/Output System), firmware, and the like for which rewriting is not needed can be stored. Examples of the ROM include a mask ROM, an OTPROM (One Time Programmable Read Only Memory), and an EPROM (Erasable Programmable Read Only Memory). Examples of the EPROM include a UV-EPROM (Ultra-Violet Erasable Programmable Read Only Memory) which can erase stored data by ultraviolet irradiation, an EEPROM (Electrically Erasable Programmable Read Only Memory), and a flash memory.

A transistor containing a metal oxide (also referred to as an oxide semiconductor) in its channel formation region (such a transistor is also referred to as an OS transistor) is preferably used in the processing portion 11. The OS transistor has an extremely low off-state current; thus, with the use of the OS transistor as a switch for retaining electric charge (data) that has flowed into a capacitor functioning as a memory element, a long data retention period can be ensured. When at least one of a register and a cache memory included in the processing portion 11 has such a feature, the processing portion 11 can be operated only when needed, and otherwise can be off while information processed immediately before turning off the processing portion 11 is stored in the memory element. In other words, normally-off computing is possible and the power consumption of the electronic device can be reduced.

A transistor containing silicon in its channel formation region (also referred to as a Si transistor) may be used in the processing portion 11.

In the processing portion 11, an OS transistor and a Si transistor are preferably used in combination.

### [Memory Portion 13]

The memory portion 13 has a function of storing a program executed by the processing portion 11. The memory portion 13 may have a function of storing an arithmetic result and an inference result generated by the processing portion 11, data of an image captured by the display portion 12, and the like.

The memory portion 13 includes at least one of a volatile memory and a nonvolatile memory. For example, the memory portion 13 may include a volatile memory such as a DRAM or an SRAM. For example, the memory portion 13 may include a nonvolatile memory such as an ReRAM (Resistive Random Access Memory, also referred to as a resistance-change memory), a PRAM (Phase-change Random Access Memory), an FeRAM (Ferroelectric Random Access Memory), an MRAM (Magnetoresistive Random Access Memory, also referred to as a magnetoresistive memory), or a flash memory. The memory portion 13 may include a recording media drive such as a hard disk drive (HDD) or a solid state drive (SSD).

### [Display Portion 12]

As described above, a display apparatus including a light-emitting device and a light-receiving device can be used for the display portion 12. In the case where a pixel of the display apparatus includes three kinds of subpixels that exhibit different colors from each other, as the three subpixels, subpixels of three colors of R, G, and B, subpixels of three colors of yellow (Y), cyan (C), and magenta (M), and the like can be given. In the case where four subpixels are included, as the four subpixels, subpixels of four colors of R, G, B, and white (W), subpixels of four colors of R, G, B, and Y, and the like can be given.

Next, pixel layout in the display apparatus that can be used for the electronic device in this embodiment is described. There is no particular limitation on the arrangement of subpixels included in a pixel, and a variety of methods can be employed. Examples of the arrangement of subpixels include stripe arrangement, S-stripe arrangement, matrix arrangement, delta arrangement, Bayer arrangement, and Pentile arrangement.

Examples of top surface shapes of the subpixels include polygons such as a triangle, a tetragon (including a rectangle and a square), a pentagon, and a hexagon; polygons with rounded corners; an ellipse; and a circle. Here, the top surface shape of the subpixel corresponds to a top surface shape of a light-emitting region of the light-emitting device or a light-receiving region of the light-receiving device.

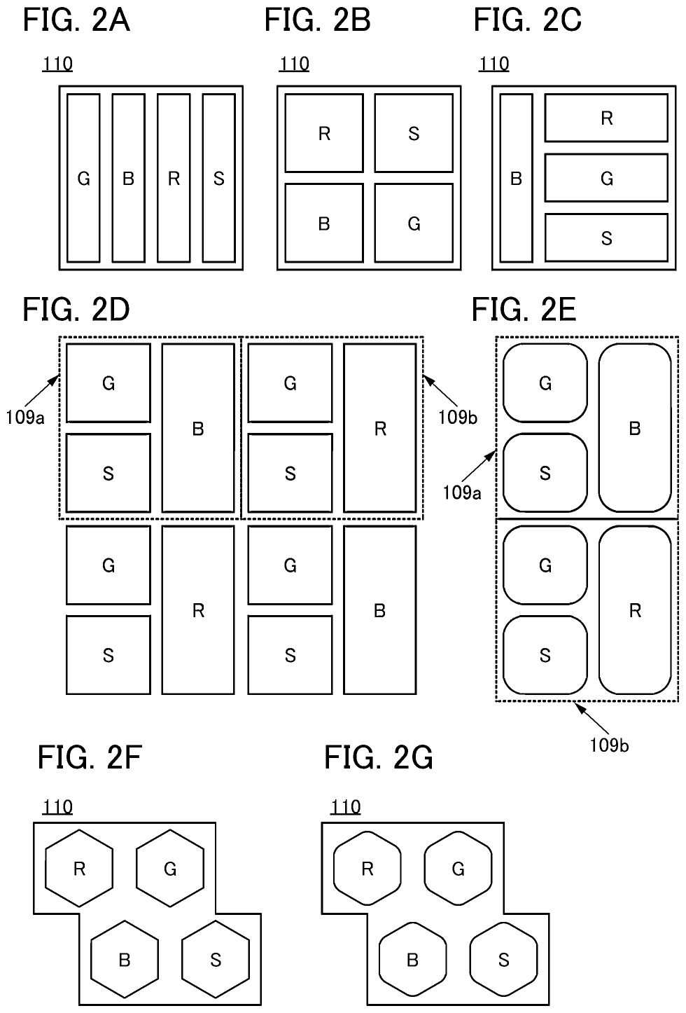

The pixels 110 illustrated in FIG. 2A to FIG. 2C each include the subpixel G, the subpixel B, the subpixel R, and the subpixel S. Note that there is no particular limitation on the arrangement order of the subpixels. In the case of detecting light of a specific color by the subpixel S, a subpixel that emits light of the color is preferably arranged next to the subpixel S, so that detection accuracy can be increased. The size of a subpixel including a light-emitting device with higher reliability can be smaller.

The pixel 110 illustrated in FIG. 2A employs stripe arrangement as in the pixel 110 illustrated in FIG. 1A. Although FIG. 1A and FIG. 2A each illustrate an example in which the subpixel R is positioned between the subpixel B and the subpixel S, the subpixel R and the subpixel G may be adjacent to each other, for example.

The pixel 110 illustrated in FIG. 2B employs matrix arrangement. Although FIG. 2B illustrates an example in which the subpixel R and the subpixel S are positioned in the same row and the subpixel B and the subpixel G are positioned in the same row, the subpixel R and the subpixel G or the subpixel B may be positioned on the same row, for example. Similarly, although an example is illustrated in which the subpixel R and the subpixel B are positioned in the same column and the subpixel S and the subpixel G are positioned in the same column, the subpixel R and the subpixel G or the subpixel S may be positioned in the same column, for example.

The pixel 110 illustrated in FIG. 2C employs a structure in which the fourth subpixel is added to S-stripe arrangement. Although an example in which the pixel 110 illustrated in FIG. 2C includes the vertically oriented subpixel B and the horizontally oriented subpixels R, G, and S is illustrated, the vertically oriented subpixel may be any of the subpixel R, the subpixel G, and the subpixel S and there is no limitation on the arrangement order of the horizontally oriented subpixels.

FIG. 2D illustrates an example in which pixels 109a and pixels 109b are alternately arranged. The pixels 109a each include the subpixel B, the subpixel G, and the subpixel S, and the pixels 109b each include the subpixel R, the subpixel G, and the subpixel S. Although FIG. 2D illustrates an example in which the subpixel G and the subpixel S are included in both of the pixel 109a and the pixel 109b, one embodiment of the present invention is not limited thereto. The subpixel S is preferably included in both of the pixel 109a and the pixel 109b in which case the resolution of image capturing can be increased. In that case, a structure is preferably employed in which light emitted from a subpixel included in both of the pixel 109a and the pixel 109b (the subpixel G in FIG. 2D) is detected by the subpixel S.

FIG. 2E is a modification example in which the subpixels included in the pixels 109a and 109b illustrated in FIG. 2D each have a rough tetragonal top surface shape with rounded corners.

In pixel layout illustrated in FIG. 2F, two-dimensional hexagonal close-packed arrangement is employed. The hexagonal close-packed layout is preferable because the aperture ratio of each subpixel can be increased. FIG. 2F illustrates an example in which each subpixel has a hexagonal top surface shape.

FIG. 2G is a modification example in which the pixel 110 illustrated in FIG. 2F has a rough hexagonal top surface shape with rounded corners.

In a photolithography method, as a pattern to be processed becomes finer, the influence of light diffraction becomes more difficult to ignore; therefore, the fidelity in transferring a photomask pattern by light exposure is degraded, and it becomes difficult to process a resist mask into a desired shape. Thus, a pattern with rounded corners is likely to be formed even with a rectangular photomask pattern. Consequently, a top surface shape of a subpixel is a polygon with rounded corners, an ellipse, a circle, or the like, in some cases.

Furthermore, in a method for fabricating the display apparatus of one embodiment of the present invention, the EL layer is processed into an island shape with the use of a resist mask. A resist film formed over the EL layer needs to be cured at a temperature lower than the upper temperature limit of the EL layer. Therefore, the resist film is insufficiently cured in some cases depending on the upper temperature limit of the material of the EL layer and the curing temperature of the resist material. An insufficiently cured resist film may have a shape different from a desired shape by processing. As a result, a top surface shape of the EL layer may be a polygon with rounded corners, an ellipse, a circle, or the like. For example, when a resist mask whose top surface shape is a square is intended to be formed, a resist mask whose top surface shape is a circle may be formed, and the top surface shape of the EL layer may be a circle.

To obtain a desired top surface shape of the EL layer, a technique of correcting a mask pattern in advance so that a transferred pattern agrees with a design pattern (OPC (Optical Proximity Correction) technique) may be used. Specifically, with the OPC technique, a pattern for correction is added to a corner portion or the like of a figure on a mask pattern.

Note that one pixel may include two or more kinds of light-receiving devices.

For example, the display apparatus of one embodiment of the present invention includes a first pixel including a light-emitting device, a first light-receiving device, and a second light-receiving device.

The area of a light-receiving region (also simply referred to as a light-receiving area) of the first light-receiving device is preferably smaller than that of the second light-receiving device. The first light-receiving device can capture a higher-resolution image than the second light-receiving device owing to its smaller imaging range. In that case, the first light-receiving device can be used to capture an image for personal authentication using a fingerprint, a palm print, the iris, the shape of a blood vessel (including the shape of a vein and the shape of an artery), a face, or the like. The wavelength of light detected by the first light-receiving device can be determined as appropriate depending on the application purpose. For example, the first light-receiving device preferably detects visible light.

The second light-receiving device can be used for a touch sensor, a non-contact sensor, or the like. The wavelength of light detected by the second light-receiving device can be determined as appropriate depending on the application purpose. For example, the second light-receiving device preferably detects infrared light. Thus, a touch can be detected even in a dark place. In the case where the second light-receiving device detects infrared light, highly sensitive detection can sometimes be performed even when dust, a drop of water, or the like is attached to the surface of the electronic device, as compared to a capacitive touch sensor.

Here, the touch sensor or the non-contact sensor can detect an approach or contact of an object (e.g., a finger, a hand, or a pen). The touch sensor can detect an object when the electronic device and the object come in direct contact with each other. The non-contact sensor can detect an object even when the object is not in contact with the electronic device. For example, the display apparatus (or the electronic device) is preferably capable of detecting an object when the distance between the display apparatus and the object is greater than or equal to 0.1 mm and less than or equal to 300 mm, preferably greater than or equal to 3 mm and less than or equal to 50 mm. This structure enables the electronic device to be operated without direct contact of an object; in other words, the display apparatus can be operated in a contactless (touchless) manner. With the above-described structure, the electronic device can have a reduced risk of being dirty or damaged, or can be operated without the object directly touching a dirt (e.g., dust, or a virus) attached to the electronic device.

The refresh rate of the display apparatus of one embodiment of the present invention can be variable. For example, the refresh rate is adjusted (adjusted in the range from 1 Hz to 240 Hz, for example) in accordance with contents displayed on the display apparatus, whereby power consumption can be reduced. The driving frequency of the touch sensor or the non-contact sensor may be changed in accordance with the refresh rate. In the case where the refresh rate of the display apparatus is 120 Hz, for example, the drive frequency of the touch sensor or the non-contact sensor can be higher than 120 Hz (typically 240 Hz). With this structure, low power consumption can be achieved, and the response speed of the touch sensor or the non-contact sensor can be increased.

Since the first light-receiving device and the second light-receiving device have difference in the detection accuracy, methods for detecting an object may be selected depending on the functions. For example, one or both of a function of swiping and a function of scrolling a display screen may be achieved owing to a non-contact sensor function using the second light-receiving device, and an input function with a keyboard displayed on a screen may be achieved owing to a high-resolution touch sensor function using the first light-receiving device.

When one pixel includes two kinds of light-receiving devices, the display apparatus can have two additional functions as well as a display function and thereby can be multifunctional.

For high-resolution image capturing, the first light-receiving device is preferably provided in all pixels included in the display apparatus. By contrast, the second light-receiving device used for a touch sensor, a non-contact sensor, or the like only needs to be provided in some pixels included in the display apparatus because detecting with the second light-receiving device is not required to have high accuracy as compared with detecting with the first light-receiving device. When the number of second light-receiving devices included in the display apparatus is smaller than the number of first light-receiving devices, higher detection speed can be achieved.

In view of the above, the display apparatus of one embodiment of the present invention can have a structure in which a plurality of first pixels described above and a plurality of second pixels are included. The second pixel is similar to the first pixel in that the light-emitting device and the first light-receiving device are included and is different from the first pixel in that the second light-receiving device is not included and includes another device instead.

The second pixel can include any of a variety of sensor devices, a light-emitting device that emits infrared light, or the like. A device different from the devices provided in the first pixel is provided in the second pixel in this way, whereby the display apparatus can be a multifunctional display apparatus.

In the case where light-emitting devices of three colors of red, green, and blue are provided in a pixel for full-color display, one pixel includes five subpixels in total when two light-receiving devices are provided. In such a pixel including many subpixels, a high aperture ratio is extremely difficult to achieve. Alternatively, a high-resolution display apparatus is difficult to achieve with the use of a pixel including many subpixels.

Thus, in the display apparatus of one embodiment of the present invention, an island-shaped EL layer is preferably formed by processing an EL layer formed on the entire surface, not by using a fine metal mask. Accordingly, a high-resolution display apparatus or a display apparatus having a high aperture ratio, which has been difficult to achieve, can be obtained. Moreover, a high-resolution display apparatus or a display apparatus with a high aperture ratio, which incorporates a light-receiving device and has a light detection function, can be obtained.

As described above, the display apparatus of one embodiment of the present invention can be a multifunctional display apparatus having a high aperture ratio or high resolution.

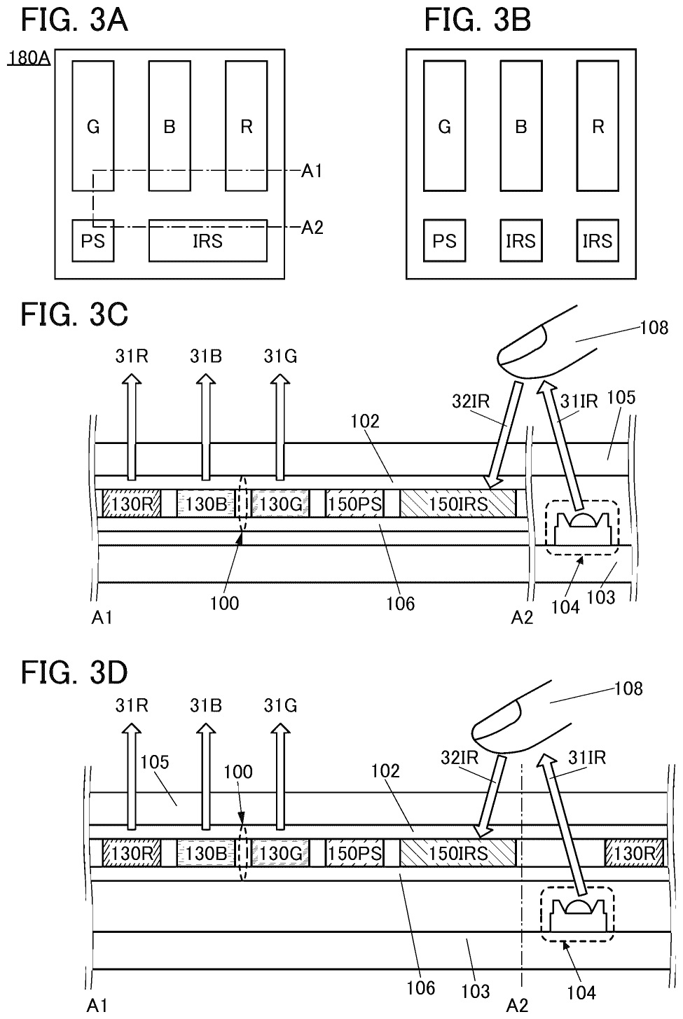

FIG. 3A illustrates an example of a pixel included in the display apparatus of one embodiment of the present invention.

A pixel 180A illustrated in FIG. 3A includes the subpixel G, the subpixel B, the subpixel R, a subpixel PS, and a subpixel IRS.

FIG. 3A illustrates an example in which one pixel 180A is provided in two rows and three columns. The pixel 180A includes three subpixels (the subpixel G, the subpixel B, and the subpixel R) in the upper row (first row) and two subpixels (the subpixel PS and the subpixel IRS) in the lower row (second row). In other words, the pixel 110 includes two subpixels (the subpixel G and the subpixel PS) in the left column (first column), the subpixel B in the center column (second column), the subpixel R in the right column (third column), and the subpixel IRS across the center and right columns.

As illustrated in FIG. 3B, three subpixels (the subpixel PS and two subpixels IRS) may be provided also in the lower row (second row). Aligning the positions of the subpixels in the upper row and the lower row as illustrated in FIG. 3B enables dust and the like that would be produced in the manufacturing process to be removed efficiently. Thus, a display apparatus having high display quality can be provided.

In FIG. 3B, the two subpixels IRS can each independently include a light-receiving device or can share one light-receiving device. That is, the pixel 110 illustrated in FIG. 3B can include one light-receiving device for the subpixel PS and one or two light-receiving devices for the subpixels IRS.

The light-receiving area of the subpixel PS is smaller than the light-receiving area of the subpixel IRS. A smaller light-receiving area leads to a narrower image-capturing range, inhibits a blur in a captured image, and improves the definition. Thus, the use of the subpixel PS enables higher-resolution or higher-definition image capturing than the use of the subpixel IRS. For example, image capturing for personal authentication with the use of a fingerprint, a palm print, the iris, the shape of a blood vessel (including the shape of a vein and the shape of an artery), a face, or the like can be performed by using the subpixel PS.

The resolution at which the subpixels PS are arranged can be higher than or equal to 100 ppi, preferably higher than or equal to 200 ppi, further preferably higher than or equal to 300 ppi, still further preferably higher than or equal to 400 ppi, yet still further preferably higher than or equal to 500 ppi, and lower than or equal to 2000 ppi, lower than or equal to 1000 ppi, or lower than or equal to 600 ppi, for example. In particular, when light-receiving devices are arranged at a resolution higher than or equal to 200 ppi and lower than or equal to 600 ppi, preferably higher than or equal to 300 ppi and lower than or equal to 600 ppi, the light-receiving devices can be suitably used for image capturing of a fingerprint. The resolution is preferably higher than or equal to 500 ppi, in which case the authentication conforms to the standard by the National Institute of Standards and Technology (NIST) or the like. On the assumption that the resolution at which the light-receiving devices are arranged is 500 ppi, the size of each pixel is 50.8 μm, which indicates that the resolution is adequate for image capturing of a fingerprint ridge distance (typically, greater than or equal to 300 lam and less than or equal to 500 μm).

In the case where an arrangement distance between the light-receiving devices is smaller than a distance between two projections of a fingerprint, preferably a distance between a depression and a projection adjacent to each other, a clear fingerprint image can be obtained. The distance between a depression and a projection of a human's fingerprint is approximately 200 μm. The human's fingerprint ridge distance is greater than or equal to 300 lam and less than or equal to 500 lam, or 460 μm±150 μm, for example. The arrangement distance between the light-receiving devices is, for example, less than or equal to 400 μm, preferably less than or equal to 200 μm, further preferably less than or equal to 150 μm, still further preferably less than or equal to 100 μm, yet still further preferably less than or equal to 50 μm, and greater than or equal to 1 μm, preferably greater than or equal to 10 μm, further preferably greater than or equal to 20 μm.

The light-receiving device included in the subpixel PS preferably detects visible light, and preferably detects one or more of blue light, violet light, bluish violet light, green light, greenish yellow light, yellow light, orange light, red light, and the like. The light-receiving device included in the subpixel PS may detect infrared light (including near-infrared light).

The subpixel IRS can be used in a touch sensor, a non-contact sensor, or the like. The wavelength of light detected by the subpixel IRS can be determined as appropriate depending on the application purpose. For example, the subpixel IRS preferably detects infrared light. Thus, touch can be detected even in a dark place.

FIG. 3C and FIG. 3D each illustrate an example of a cross-sectional view of an electronic device including the display apparatus of one embodiment of the present invention.

Each of the electronic devices illustrated in FIG. 3C and FIG. 3D includes a display apparatus 100 and a light source 104 between a housing 103 and a protection member 105.

The light source 104 includes a light-emitting device that emits infrared light 31IR. For example, a light emitting diode (LED) is preferably used for the light source 104.

FIG. 3C illustrates an example in which the light source 104 is provided in a position not overlapping with the display apparatus 100. In this case, light of the light source 104 is emitted to the outside of the electronic device through the protection member 105.

FIG. 3D illustrates an example in which the display apparatus and the light source 104 are provided to overlap with each other. In this case, light of the light source 104 is emitted to the outside of the electronic device through the display apparatus 100 and the protection member 105.

The cross-sectional structures of the display apparatuses 100 illustrated in FIG. 3C and FIG. 3D each correspond to a cross-sectional structure taken along dashed-dotted line A1-A2 in FIG. 3A. The display apparatus 100 includes a plurality of light-emitting devices and a plurality of light-receiving devices between a substrate 106 and a substrate 102.

The subpixel R includes a light-emitting device 130R that emits red light 31R. The subpixel G includes a light-emitting device 130G that emits green light 31G. The subpixel B includes a light-emitting device 130B that emits blue light 31B.

The subpixel PS includes a light-receiving device 150PS, and the subpixel IRS includes a light-receiving device 150IRS. There is no particular limitation on the wavelength of light detected by the subpixel PS and the subpixel IRS.

As illustrated in FIG. 3C and FIG. 3D, the infrared light 311R emitted from the light source 104 is reflected by an object 108 (here, a finger), and reflected light 321R from the object 108 enters the light-receiving device 150IRS. The object 108 is not touching the electronic device, but the object 108 can be detected with the light-receiving device 150IRS.

Although an example in which an object is detected with the use of the infrared light 31IR is described in this embodiment, the wavelength of light detected by the light-receiving device 150IRS is not particularly limited. The light-receiving device 150IRS preferably detects infrared light. Alternatively, the light-receiving device 150IRS may detect visible light or both infrared light and visible light.

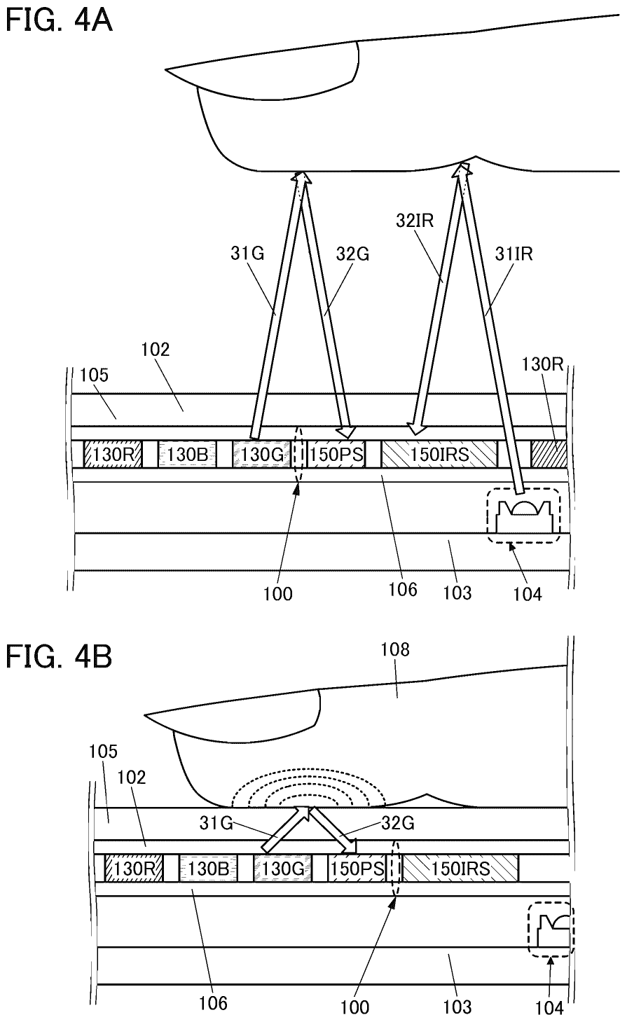

In a touch sensor or a non-contact sensor, an increase in the light-receiving area of a light-receiving device can facilitate detection of an object in some cases. Thus, as illustrated in FIG. 4A, the object 108 may be detected with both the light-receiving device 150PS and the light-receiving device 150IRS.

In FIG. 4A, as in FIG. 3C and FIG. 3D, the infrared light 311R emitted from the light source 104 is reflected by the object 108 (here, a finger), and the reflected light 321R from the object 108 enters the light-receiving device 150IRS. In FIG. 4A, the green light 31G emitted from the light-emitting device 130G is also reflected by the object 108 and reflected light 32G from the object 108 enters the light-receiving device 150PS. The object 108 is not touching the electronic device, but the object 108 can be detected with the light-receiving device 150IRS and the light-receiving device 150PS.

Note that the object 108 that is touching the electronic device can also be detected with the light-receiving device 150IRS (and the light-receiving device 150PS).

For example, as illustrated in FIG. 4B, the green light 31G emitted from the light-emitting device 130G is reflected by the object 108 and the reflected light 32G from the object 108 enters the light-receiving device 150PS. A fingerprint image of the object 108 can be captured with the light-receiving device 150PS.

In this embodiment, an example is described in which the light-receiving device 150PS detects an object with the use of the green light 31G emitted from the light-receiving device 130G; however, the wavelength of light detected by the light-receiving device 150PS is not particularly limited. The light-receiving device 150PS preferably detects visible light, and preferably detects one or more of blue light, violet light, bluish violet light, green light, greenish yellow light, yellow light, orange light, red light, and the like. The light-receiving device 150PS may detect infrared light.

For example, the light-receiving device 150PS may have a function of detecting the red light 31R emitted from the light-emitting device 130R. Furthermore, the light-receiving device 150PS may have a function of detecting the blue light 31B emitted from the light-emitting device 130B.

Note that a light-emitting device that emits light detected by the light-receiving device 150PS is preferably provided in a subpixel positioned close to the subpixel PS in the pixel. For example, the pixel 180A has a structure in which light emission of the light-emitting device 130G included in the subpixel G adjacent to the subpixel PS is detected by the light-receiving device 150PS. With such a structure, the detection accuracy can be increased.

In the display apparatus of one embodiment of the present invention, the above structure of the pixel 180A may be employed for all the pixels; alternatively, the structure of the pixel 180A may be employed for some of the pixels and another structure may be employed for the other pixels.

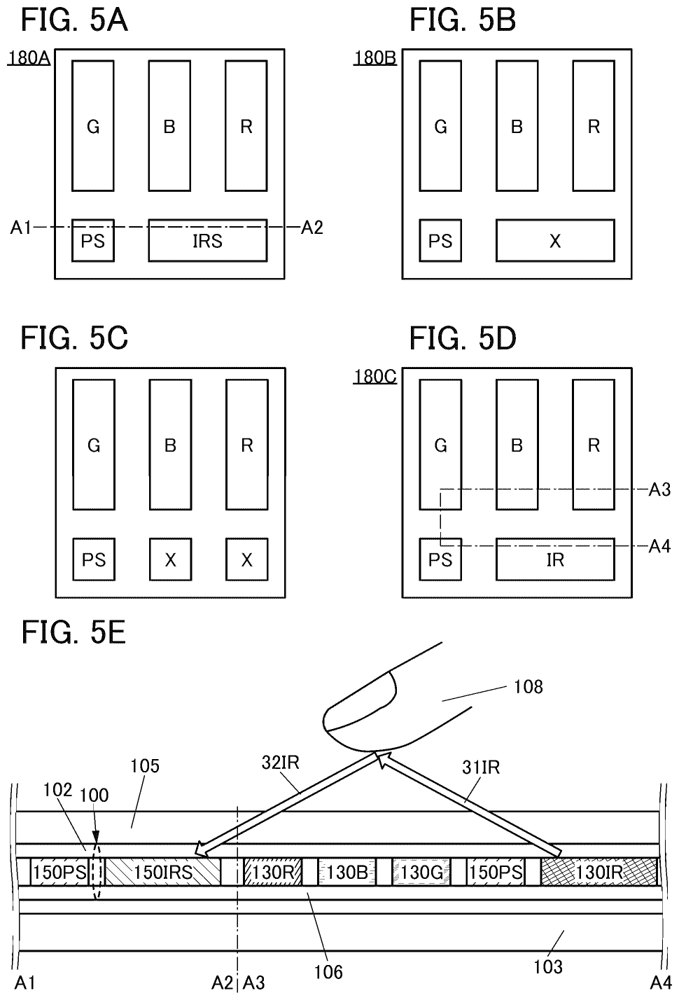

For example, the display apparatus of one embodiment of the present invention may include both the pixel 180A illustrated in FIG. 5A and a pixel 180B illustrated in FIG. 5B.

The pixel 180B illustrated in FIG. 5B includes the subpixel G, the subpixel B, the subpixel R, the subpixel PS, and a subpixel X.

As illustrated in FIG. 5C, a pixel may include three subpixels (the subpixel PS and two subpixels X) in the lower row (second row). As described above, a structure in which the positions of the subpixels in the upper row and the lower row are aligned enables dust and the like that would be produced in the manufacturing process to be removed efficiently. Accordingly, a display apparatus having high display quality can be provided.

With a device included in the subpixel X, the display apparatus or an electronic device including the display apparatus can have a variety of functions.

For example, with the device included in the subpixel X, the display apparatus or the electronic device can have a function of measuring at least one of force, displacement, position, speed, acceleration, angular velocity, rotational frequency, distance, magnetism, temperature, chemical substance, time, electric field, electric current, voltage, electric power, radiation, flow rate, humidity, gradient, oscillation, odor, physical condition, pulse, body temperature, blood oxygen level, and arterial oxygen saturation.

Examples of the function of the display apparatus or the electronic device include a strobe light function, a flashlight function, a degradation correction function, an acceleration sensor function, an odor sensor function, a physical condition detection function, a pulse detection function, a body temperature detection function, a function as a pulse oximeter, and a function of measuring the blood oxygen level.

The strobe light function can be obtained, for example, by repetition of light emission and non-light emission at short intervals.

The flashlight function can be obtained, for example, with a structure where flash of light is caused by instantaneous discharge using principles of an electric double layer.

The strobe light function and the flashlight function can be used for crime prevention or self-defense, for example. The emission color of a strobe light and a flashlight is preferably white. There is no particular limitation on the emission color of the strobe light and the flashlight; the practitioner can appropriately select one or more optimal emission colors from white, blue, violet, bluish violet, green, yellowish green, yellow, orange, red, and the like.

As the degradation correction function, a function of correcting degradation of a light-emitting device included in at least one subpixel selected from the subpixel G, the subpixel B, and the subpixel R can be given. Specifically, in the case where a material used for the light-emitting device included in the subpixel G has poor reliability, a structure including two subpixels G in the pixel 180B can be employed by making the subpixel X have the same structure as the subpixel G. Such a structure can double the area of the subpixel G. When the area of the subpixel G doubles, the reliability can be approximately two times as high as the case of one subpixel G. Alternatively, when a structure in which two subpixels G are provided in the pixel 180B is employed, one subpixel G may compensate for light emission of the other subpixel G that cannot emit light due to degradation or the like.

Although the case of the subpixel G is described in the above, the subpixel B and the subpixel R can also have similar structures.

The acceleration sensor function, the odor sensor function, the physical condition detection function, the pulse detection function, the body temperature detection function, and the function of measuring the blood oxygen level can each be achieved by providing a sensor device necessary for detection in the subpixel X. The display apparatus or the electronic device can have a variety of functions depending on the sensor device provided in the subpixel X.

When a variety of functions are given to the subpixel X illustrated in FIG. 5B as described above, the display apparatus including the pixel 180B can be referred to as a multifunctional display apparatus or a multifunctional panel. Note that the subpixel X may have one function or two or more functions, and the practitioner can appropriately select optimal function(s).

Note that the display apparatus of one embodiment of the present invention may include a pixel composed of four subpixels without the subpixel X nor the subpixel IRS. That is, a pixel composed of the subpixel G, the subpixel B, the subpixel R, and the subpixel PS may be included. In the display apparatus, the number of subpixels may vary among pixels. However, it is preferable that all pixels have the same number of subpixels for uniform quality of the pixels.

The display apparatus of one embodiment of the present invention may include both the pixel 180A illustrated in FIG. 5A and a pixel 180C illustrated in FIG. 5D, for example.

The pixel 180C illustrated in FIG. 5D includes the subpixel G, the subpixel B, the subpixel R, the subpixel PS, and a subpixel IR.

The subpixel IR includes a light-emitting device that emits infrared light. That is, the subpixel IR can be used as a light source of a sensor. When the display apparatus includes a light-emitting device that emits infrared light, a light source need not be provided separately from the display apparatus, reducing the number of components of the electronic device.

FIG. 5E is an example of a cross-sectional view of an electronic device including the display apparatus of one embodiment of the present invention.

The electronic device illustrated in FIG. 5E includes the display apparatus 100 between the housing 103 and the protection member 105.

The cross-sectional structure of the display apparatus 100 in FIG. 5E corresponds to the cross-sectional structure taken along dashed-dotted line A1-A2 in FIG. 5A and the cross-sectional structure taken along dashed-dotted line A3-A4 in FIG. 5D. That is, the display apparatus 100 illustrated in FIG. 5E includes the pixel 180A and the pixel 180C.

The subpixel R includes the light-emitting device 130R that emits the red light 31R. The subpixel G includes the light-emitting device 130G that emits the green light 31G. The subpixel B includes the light-emitting device 130B that emits the blue light 31B.

The subpixel PS includes the light-receiving device 150PS, and the subpixel IRS includes the light-receiving device 150IRS. The subpixel IR includes a light-emitting device 13018 that emits the infrared light 311R.

As illustrated in FIG. 5E, the infrared light 31IR emitted from the light-emitting device 13018 is reflected by the object 108 (here, a finger), and the reflected light 3218 from the object 108 enters the light-receiving device 150IRS. The object 108 is not touching the electronic device, but the object 108 can be detected with the light-receiving device 150IRS.

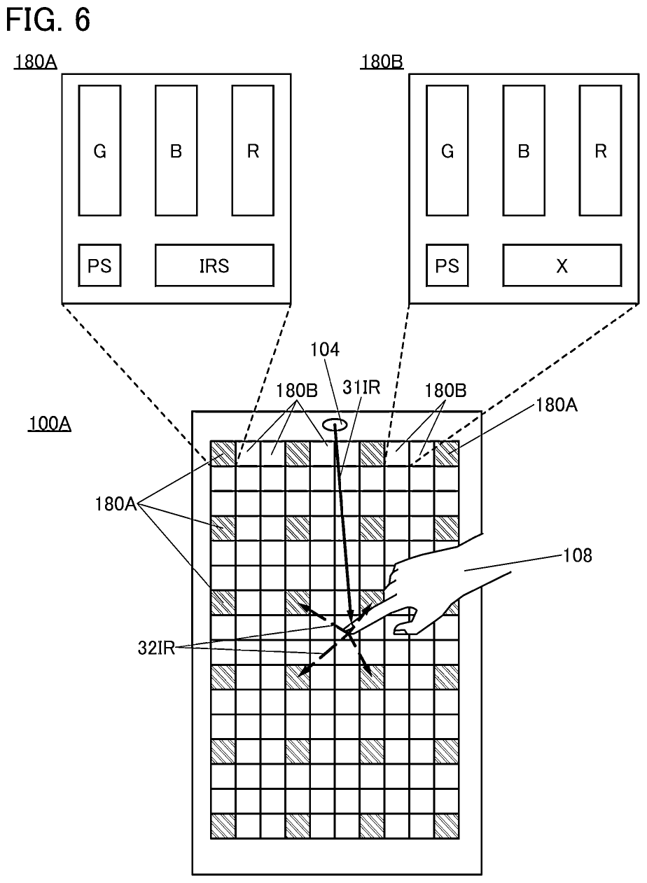

FIG. 6 to FIG. 9 illustrate examples of layouts of display apparatuses.

A non-contact sensor function can be achieved in such a manner that, for example, an object (e.g., a finger, a hand, or a pen) is irradiated with light from a light source fixed to a specific position, reflected light from the object is detected by a plurality of subpixels IRS, and the position of the object is estimated from the detection intensity ratio among the plurality of subpixels IRS.

The pixels 180A including the subpixels IRS can be arranged at regular intervals in a display portion or arranged along the periphery of the display portion, for example.

The driving frequency can be increased when non-contact detection is performed using only some of the pixels. Furthermore, since the subpixel X or the subpixel IR can be included in the other pixels, the display apparatus can be a multifunctional display apparatus.

A display apparatus 100A illustrated in FIG. 6 includes two kinds of pixels, the pixel 180A and the pixel 180B. In the display apparatus 100A, one pixel 180A is provided in every 3×3 pixels (9 pixels), and the other pixels are the pixels 180B.

Note that the placement interval of the pixels 180A is not limited to one in every 3×3 pixels. For example, the placement interval of pixels used for touch detection can be determined as appropriate to be one pixel in every 4 pixels (2×2 pixels), one pixel in every 16 pixels (4×4 pixels), one pixel in every 100 pixels (10×10 pixels), one pixel in every 900 pixels (30×30 pixels), or the like.

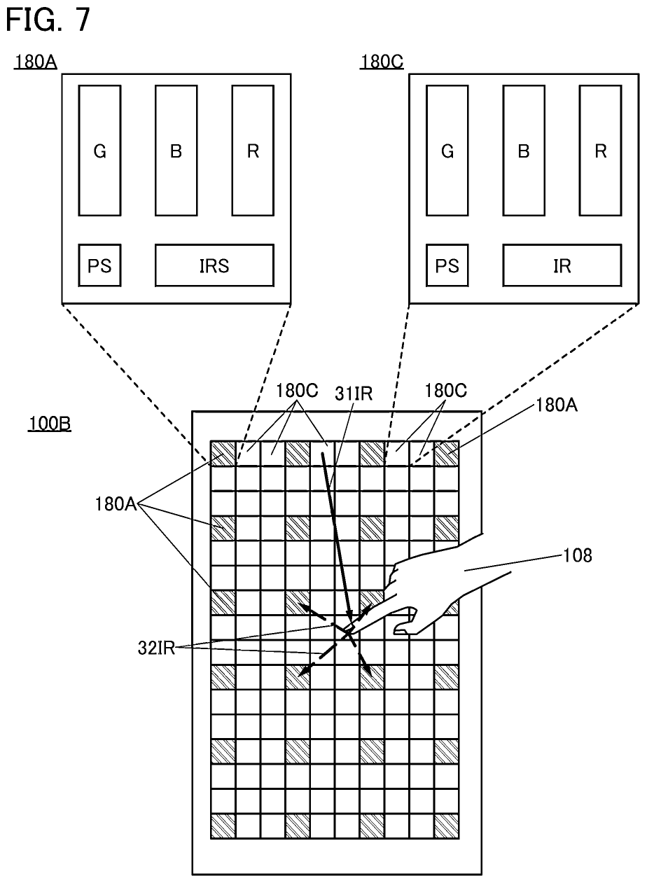

A display apparatus 100B illustrated in FIG. 7 includes two kinds of pixels, the pixel 180A and the pixel 180C. In the display apparatus 100B, one pixel 180A is provided in every 3×3 pixels (9 pixels), and the other pixels are the pixels 180C.

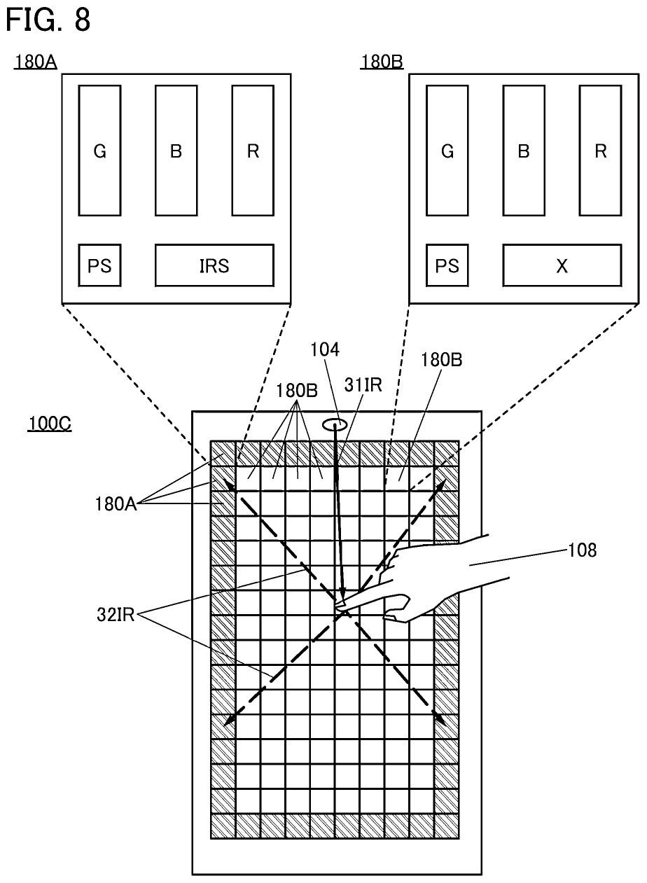

A display apparatus 100C illustrated in FIG. 8 includes two kinds of pixels, the pixel 180A and the pixel 180B. In the display apparatus 100C, the pixels 180A are provided along the periphery of a display portion, and the other pixels are the pixels 180B.

In the case where the pixels 180A are provided along the periphery of the display portion, the pixels 180A can be arranged in a variety of ways: the pixels 180A may be arranged to surround all four sides as in FIG. 8; the pixels 180A may be provided at four corners; or one or more of the pixels 180A may be provided for each side.

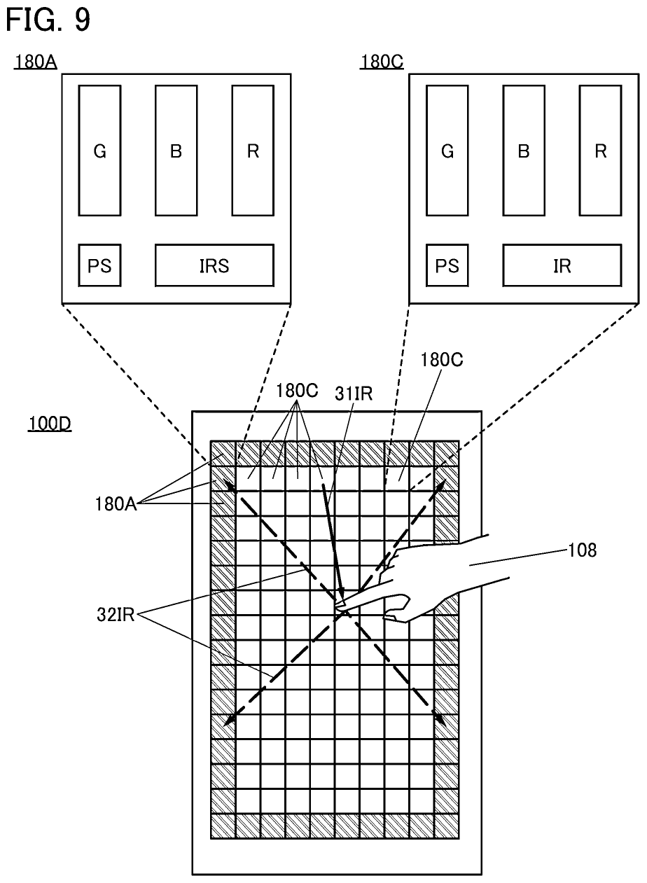

A display apparatus 100D illustrated in FIG. 9 includes two kinds of pixels, the pixel 180A and the pixel 180C. In the display apparatus 100D, the pixels 180A are provided along the periphery of a display portion, and the other pixels are the pixels 180C.

In FIG. 6 and FIG. 8, the infrared light 31IR emitted from the light source 104 provided in the outside of the display portion of the display apparatus is reflected by the object 108, and the reflected light 3218 from the object 108 enters the plurality of pixels 180A. The reflected light 321R is detected by the subpixels IRS provided in the pixels 180A, and thus the position of the object 108 can be estimated from the detection intensity ratio among the plurality of subpixels IRS. Note that the light source 104 is provided at least in the outside of the display portion of the display apparatus, and may be incorporated in the display apparatus or mounted on the electronic device separately from the display apparatus. As the light source 104, a light-emitting diode that emits infrared light can be used, for example.

In FIG. 7 and FIG. 9, the infrared light 31IR emitted from the subpixel IR included in the pixel 180C is reflected by the object 108, and the reflected light 321R from the object 108 enters the plurality of pixels 180A. The reflected light 321R is detected by the subpixels IRS provided in the pixels 180A, and thus the position of the object 108 can be estimated from the detection intensity ratio among the plurality of subpixels IRS.

As described above, the display apparatus can have a variety of layouts.

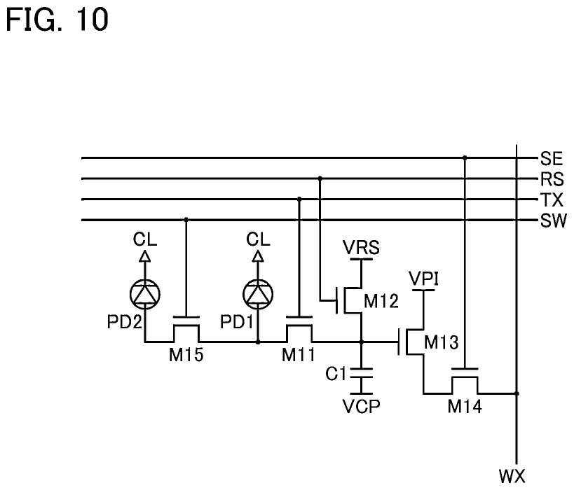

FIG. 10 illustrates an example of a pixel circuit including two light-receiving devices.

The pixel illustrated in FIG. 10 includes transistors M11, M12, M13, M14, and M15, a capacitor C1, and light-receiving devices PD1 and PD2.

A gate of the transistor M11 is electrically connected to a wiring TX, one of a source and a drain of the transistor M11 is electrically connected to an anode electrode of the light-receiving device PD1 and one of a source and a drain of the transistor M15, and the other of the source and the drain of the transistor M11 is electrically connected to one of a source and a drain of the transistor M12, a first electrode of the capacitor C1, and a gate of the transistor M13. A gate of the transistor M12 is electrically connected to a wiring RS, and the other of the source and the drain of the transistor M12 is electrically connected to a wiring VRS. One of a source and a drain of the transistor M13 is electrically connected to a wiring VPI, and the other of the source and the drain of the transistor M13 is electrically connected to one of a source and a drain of the transistor M14. A gate of the transistor M14 is electrically connected to a wiring SE, and the other of the source and the drain of the transistor M14 is electrically connected to a wiring WX. A gate of the transistor M15 is electrically connected to a wiring SW, and the other of the source and the drain of the transistor M15 is electrically connected to an anode electrode of the light-receiving device PD2. Cathode electrodes of the light-receiving device PD1 and the light-receiving device PD2 are electrically connected to a wiring CL. A second electrode of the capacitor C1 is electrically connected to a wiring VCP.

Each of the transistor M11, the transistor M12, the transistor M14, and the transistor M15 functions as a switch. The transistor M13 functions as an amplifier element (amplifier).

In the display apparatus of one embodiment of the present invention, it is preferable to use transistors containing a metal oxide (also referred to as an oxide semiconductor) in their semiconductor layers where channels are formed (such transistors are also referred to as OS transistors) as all the transistors included in the pixel circuit. An OS transistor has an extremely low off-state current and enables charge stored in a capacitor that is series-connected to the transistor to be retained for a long time. Furthermore, the use of an OS transistor can reduce power consumption of the display apparatus.

Alternatively, in the display apparatus of one embodiment of the present invention, it is preferable to use transistors containing silicon in their semiconductor layers where channels are formed (such transistors are also referred to as Si transistors) as all the transistors included in the pixel circuit. As silicon, single crystal silicon, polycrystalline silicon, amorphous silicon, and the like can be given. It is particularly preferable to use transistors containing low-temperature polysilicon (LTPS) in their semiconductor layers (such transistors are hereinafter also referred to as LTPS transistors). An LTPS transistor has a high field-effect mobility and can operate at high speed.

In the display apparatus of one embodiment of the present invention, two kinds of transistors are preferably used in the pixel circuit. Specifically, the pixel circuit preferably includes an OS transistor and an LTPS transistor. Changing the material of the semiconductor layer depending on the desired function of the transistor can increase the quality of the pixel circuit and the accuracy of sensing or image capturing.

For example, it is preferable to use, as all of the transistor M11 to the transistor M15, LTPS transistors containing low-temperature polysilicon in their semiconductor layers. Alternatively, it is preferable that OS transistors containing a metal oxide in their semiconductor layers be used as the transistor M11, the transistor M12, and the transistor M15 and an LTPS transistor be used as the transistor M13. In that case, the transistor M14 may be either an OS transistor or an LTPS transistor.

By using OS transistors as the transistor M11, the transistor M12, and the transistor M15, a potential held in the gate of the transistor M13 on the basis of charge generated in the light-receiving device PD1 and the light-receiving device PD2 can be prevented from leaking through the transistor M11, the transistor M12, or the transistor M15.

By contrast, an LTPS transistor is preferably used as the transistor M13. The LTPS transistor can have a higher field-effect mobility than the OS transistor, and has excellent drive capability and current capability. Thus, the transistor M13 can operate at higher speed than the transistor M11, the transistor M12, and the transistor M15. By using the LTPS transistor as the transistor M13, an output in accordance with the extremely low potential based on the amount of light received by the light-receiving device PD1 or the light-receiving device PD2 can be quickly supplied to the transistor M14.

In other words, in the pixel circuit illustrated in FIG. 10, the transistor M11, the transistor M12, and the transistor M15 have low leakage current and the transistor M13 has high drive capability, whereby, when the light-receiving device PD1 and the light-receiving device PD2 receive light, the charge transferred through the transistor M11 and the transistor M15 can be retained without leakage and high-speed reading can be performed.

Low off-state current, high-speed operation, and the like, which are required for the transistor M11 to the transistor M13 and the transistor M15, are not necessarily required for the transistor M14 because the transistor M14 functions as a switch for supplying the output from the transistor M13 to the wiring WX. For this reason, either low-temperature polysilicon or an oxide semiconductor may be used for the semiconductor layer of the transistor M14.

Although the transistors in FIG. 10 are illustrated as n-channel transistors, p-channel transistors can be used.

As described above, in the case where a high-resolution and clear image is required to be captured for personal authentication or the like, the aperture ratio (the light-receiving area) of the light-receiving device is preferably small. By contrast, in the case of a non-contact sensor which only needs to detect an approximate position, for example, the aperture ratio (the light-receiving area) of the light-receiving device is preferably large. Accordingly, the aperture ratio (the light-receiving area) of the light-receiving device PD1 is preferably smaller than the aperture ratio (the light-receiving area) of the light-receiving device PD2. In addition, in the case where a high-resolution image is required to be captured, it is preferable that the image be captured only with the light-receiving device PD1 by turning on the transistor M11 and turning off the transistor M15. By contrast, in the case where detection in a large area is performed, it is preferable to capture an image with both the light-receiving device PD1 and the light-receiving device PD2 by turning on both the transistor M11 and the transistor M15. In this manner, the amount of light received for image capturing can be increased and an object at a position away from the display apparatus can be easily detected.

As described above, the electronic device of one embodiment of the present invention can detect a non-contact object and infer the position data using the processing portion and the display portion. The use of the machine learning model in the processing portion can increase inference accuracy.

Providing two kinds of light-receiving devices in one pixel in the display apparatus of one embodiment of the present invention can provide two functions in addition to a display function, enabling a multifunctional electronic device. For example, a high-resolution image capturing function and a sensing function of a touch sensor, a non-contact sensor, or the like can be achieved. Furthermore, when a pixel including two kinds of light-receiving devices and a pixel having another structure are combined, the electronic device can have more functions. For example, a pixel including a light-emitting device that emits infrared light, any of a variety of sensor devices, or the like can be used.

This embodiment can be combined with the other embodiments as appropriate. In the case where a plurality of structure examples are described in one embodiment in this specification, the structure examples can be combined as appropriate.

### Embodiment 2

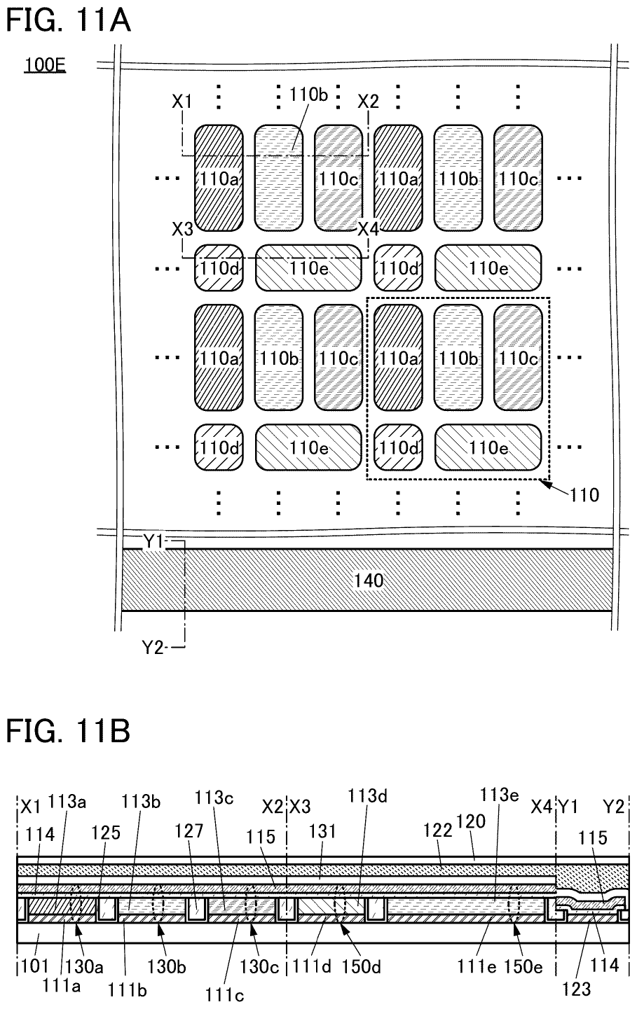

In this embodiment, the display apparatus of one embodiment of the present invention will be described with reference to FIG. 11 to FIG. 15.

The display apparatus of one embodiment of the present invention includes a light-emitting device and a light-receiving device in a pixel. In the display apparatus of one embodiment of the present invention, the pixel has a light-receiving function, which enables the contact or approach of an object to be detected while an image is displayed. For example, all the subpixels included in the display apparatus can display an image; alternatively, some of the subpixels can emit light as a light source, some of the rest of the subpixels can detect light, and the other subpixels can display an image.

In the display apparatus of one embodiment of the present invention, the light-emitting devices are arranged in a matrix in the display portion, and an image can be displayed on the display portion. Furthermore, the light-receiving devices are arranged in a matrix in the display portion, and the display portion has one or both of an image capturing function and a sensing function in addition to an image displaying function. The display portion can be used as an image sensor or a touch sensor. That is, by detecting light with the display portion, an image can be captured or the approach or contact of an object (e.g., a finger, a hand, or a pen) can be detected. Furthermore, in the display apparatus of one embodiment of the present invention, the light-emitting devices can be used as a light source of the sensor. Accordingly, a light-receiving portion and a light source do not need to be provided separately from the display apparatus; hence, the number of components of an electronic device can be reduced.

In the display apparatus of one embodiment of the present invention, when an object reflects (or scatters) light emitted from the light-emitting device included in the display portion, the light-receiving device can detect the reflected light (or scattered light); thus, image capturing or touch detection is possible even in a dark place.

The display apparatus of one embodiment of the present invention has a function of displaying an image using the light-emitting devices. That is, the light-emitting devices function as display devices (also referred to as display elements).

As the light-emitting device, an OLED (Organic Light Emitting Diode) or a QLED (Quantum-dot Light Emitting Diode) is preferably used. Examples of a light-emitting substance (also referred to as a light-emitting material) contained in the light-emitting device include a substance that emits fluorescent light (a fluorescent material), a substance that emits phosphorescent light (a phosphorescent material), and a substance that exhibits thermally activated delayed fluorescence (a thermally activated delayed fluorescent (TADF) material). Note that as a TADF material, a material that is in a thermal equilibrium state between a singlet excited state and a triplet excited state may be used. Since such a TADF material enables a short emission lifetime (excitation lifetime), an efficiency decrease of a light-emitting device in a high-luminance region can be inhibited. In addition, an LED (Light Emitting Diode) such as a micro-LED can also be used as the light-emitting device. An inorganic compound (e.g., a quantum dot material) can also be used as the light-emitting substance contained in the light-emitting device.

The display apparatus of one embodiment of the present invention has a function of detecting light using the light-emitting device.

In the case where the light-receiving device is used as an image sensor, the display apparatus can capture an image with the use of the light-receiving device. For example, the display apparatus of this embodiment can be used as a scanner.

For example, data on biological information such as a fingerprint or a palm print can be obtained with the use of the image sensor. That is, a biometric authentication sensor can be incorporated in the display apparatus. When the display apparatus incorporates a biometric authentication sensor, the number of components of an electronic device can be reduced as compared with the case where a biometric authentication sensor is provided separately from the display apparatus; thus, the size and weight of the electronic device can be reduced.

In the case where the light-receiving device is used as the touch sensor, the display apparatus can detect the approach or contact of an object with the use of the light-receiving device.

For example, a pn or pin photodiode can be used as the light-receiving device. The light-receiving device functions as a photoelectric conversion device (also referred to as a photoelectric conversion element) that detects light entering the light-receiving device and generates charge. The amount of charge generated from the light-receiving device depends on the amount of light entering the light-receiving device.

It is particularly preferable to use an organic photodiode including a layer containing an organic compound, as the light-receiving device. An organic photodiode, which is easily made thin, lightweight, and large in area and has a high degree of freedom for shape and design, can be used in a variety of display apparatuses.

In one embodiment of the present invention, an organic EL device is used as the light-emitting device, and an organic photodiode is used as the light-receiving device. The organic EL device and the organic photodiode can be formed over the same substrate. Thus, the organic photodiode can be incorporated in the display apparatus including the organic EL device.

Since a large number of layers in the organic photodiodes can have structures in common with the layers in the organic EL devices, forming the layers having common structures concurrently can inhibit an increase in the number of film formation steps.

For example, one of a pair of electrodes (a common electrode) can be a layer shared by the light-receiving device and the light-emitting device. For another example, at least one of a hole-injection layer, a hole-transport layer, an electron-transport layer, and an electron-injection layer is preferably shared by the light-receiving device and the light-emitting device.

Note that a layer shared by the light-receiving device and the light-emitting device may have different functions in the light-emitting device and the light-receiving device. In this specification, the name of a component is based on its function in the light-emitting device. For example, a hole-injection layer functions as a hole-injection layer in the light-emitting device and functions as a hole-transport layer in the light-receiving device. Similarly, an electron-injection layer functions as an electron-injection layer in the light-emitting device and functions as an electron-transport layer in the light-receiving device. A layer shared by the light-receiving device and the light-emitting device may have the same function in both the light-emitting device and the light-receiving device. The hole-transport layer functions as a hole-transport layer in both the light-emitting device and the light-receiving device, and the electron-transport layer functions as an electron-transport layer in both the light-emitting device and the light-receiving device.

In the case of fabricating a display apparatus including a plurality of organic EL devices that emit light of different colors from their light-emitting layers, the light-emitting layers that emit light of different colors each need to be formed in an island shape.

For example, an island-shaped light-emitting layer can be formed by a vacuum evaporation method using a metal mask (also referred to as a shadow mask). However, this method causes a deviation from the designed shape and position of an island-shaped light-emitting layer due to various influences such as the low accuracy of the metal mask position, the positional deviation between the metal mask and a substrate, a warp of the metal mask, and the vapor-scattering-induced expansion of outline of the formed film; accordingly, it is difficult to achieve high resolution and a high aperture ratio of the display apparatus.

In a method for fabricating the display apparatus of one embodiment of the present invention, an island-shaped pixel electrode (also referred to as a lower electrode) is formed, a first layer (also referred to as an EL layer or part of an EL layer) including a light-emitting layer emitting light of a first color is formed on the entire surface, and then a first sacrificial layer is formed over the first layer. Then, a first resist mask is formed over the first sacrificial layer and the first layer and the first sacrificial layer are processed using the first resist mask, so that the first layer is formed into an island shape. Next, in a manner similar to that for the first layer, a second layer (also referred to as an EL layer or part of an EL layer) including a light-emitting layer emitting light of a second color is formed into an island shape using a second sacrificial layer and a second resist mask.

As described above, in the method for fabricating a display apparatus of one embodiment of the present invention, the island-shaped EL layers are formed not by using a fine metal mask but by processing an EL layer formed over the entire surface. Accordingly, a high-resolution display apparatus or a display apparatus with a high aperture ratio, which has been difficult to obtain, can be obtained. Moreover, EL layers can be formed separately for the respective colors, enabling the display apparatus to perform extremely clear display with high contrast and high display quality. In addition, the sacrificial layers (which may be also referred to as mask layers) provided over the EL layers can reduce damage to the EL layers during the fabrication process of the display apparatus, increasing the reliability of a light-emitting device.

It is difficult to set the distance between adjacent light-emitting devices to be less than 10 μm with a formation method using a metal mask, for example; however, with the above method, the distance can be decreased to less than or equal to 3 μm, less than or equal to 2 μm, or less than or equal to 1 μm.

Furthermore, a pattern of the EL layer itself (also referred to as a processing size) can be made much smaller than that in the case of using a metal mask. For example, in the case of using a metal mask for forming EL layers separately, the thickness of the center of the EL layer varies from that of the edge of the EL layer, which causes a reduction in an effective area that can be used as a light-emitting region with respect to the area of the EL layer. By contrast, in the above fabrication method, an EL layer is formed by processing a film that has been formed with uniform thickness, which enables uniform thickness in the EL layer; thus, almost the entire area can be used as a light-emitting region even in the case of a fine pattern. Thus, a display apparatus having both high resolution and a high aperture ratio can be fabricated.

Here, each of the first layer and the second layer includes at least a light-emitting layer and preferably consists of a plurality of layers. Specifically, each of the first layer and the second layer preferably includes one or more layers over the light-emitting layer. A layer between the light-emitting layer and the sacrificial layer can inhibit the light-emitting layer from being exposed on the outermost surface during the fabrication process of the display apparatus and can reduce damage to the light-emitting layer. Accordingly, the reliability of the light-emitting device can be increased.

Note that it is not necessary to form all layers included in the EL layers separately for each of the light-emitting devices emitting light of different colors, and some layers of the EL layers can be formed in the same step. In the method for fabricating a display apparatus of one embodiment of the present invention, after some layers included in the EL layers are formed into an island shape separately for each color, the sacrificial layer is removed and then other layers included in the EL layers and a common electrode (also referred to as an upper electrode) are formed so as to be shared by the light-emitting devices of the respective colors.

A fabrication method similar to that of the light-emitting device can be employed for the light-receiving device. An island-shaped active layer (also referred to as a photoelectric conversion layer) included in the light-receiving device is formed by processing a film that is to be the active layer and formed on the entire surface, not by using a fine metal mask; thus, the island-shaped active layer can have a uniform thickness. In addition, a sacrificial layer provided over the active layer can reduce damage to the active layer in the fabrication process of the display apparatus, increasing the reliability of the light-receiving device.

### [Structure Example of Display Apparatus]

FIG. 11A and FIG. 11B illustrate the display apparatus of one embodiment of the present invention.

FIG. 11A illustrates a top view of a display apparatus 100E. The display apparatus 100E includes a display portion in which a plurality of pixels 110 are arranged in a matrix, and a connection portion 140 outside the display portion. One pixel 110 consists of five subpixels 110a, 110b, 110c, 110d, and 110e. Note that the structure of the pixels is not limited to that in FIG. 11A, and the structures described as examples in Embodiment 1 can be each employed, for example.

FIG. 11A illustrates an example in which one pixel 110 is provided in two rows and three columns. The pixel 110 includes three subpixels (the subpixels 110a, 110b, and 110c) in the upper row (first row) and two subpixels (the subpixels 110d and 110e) in the lower row (second row). In other words, the pixel 110 includes two subpixels (the subpixels 110a and 110d) in the left column (first column), the subpixel 110b in the center column (second column), the subpixel 110c in the right column (third column), and the subpixel 110e across the center and right columns.

In this embodiment, an example is described in which the subpixels 110a, 110b, and 110c include light-emitting devices that emit light of different colors and the subpixels 110d and 110e include light-receiving devices that have different light-receiving areas. For example, the subpixels 110a, 110b, and 110c correspond to the subpixels G, B, and R illustrated in FIG. 5A or the like. The subpixel 110d corresponds to the subpixel PS illustrated in FIG. 5A or the like and the subpixel 110e corresponds to the subpixel IRS illustrated in FIG. 5A or the like.

Note that the kind of devices provided in the subpixels 110e may differ among the pixels. Thus, a structure may be employed in which some of the subpixels 110e correspond to the subpixels IRS and the other subpixels 110e correspond to the subpixels X (see FIG. 5B) or the subpixels IR (see FIG. 5D).

Although FIG. 11A illustrates an example in which the connection portion 140 is positioned on the lower side of the display portion in a top view, one embodiment of the present invention is not particularly limited. The connection portion 140 only needs to be provided on at least one of the upper side, the right side, the left side, and the lower side of the display portion in a top view, or may be provided so as to surround the four sides of the display portion. The number of connection portions 140 may be one or more.

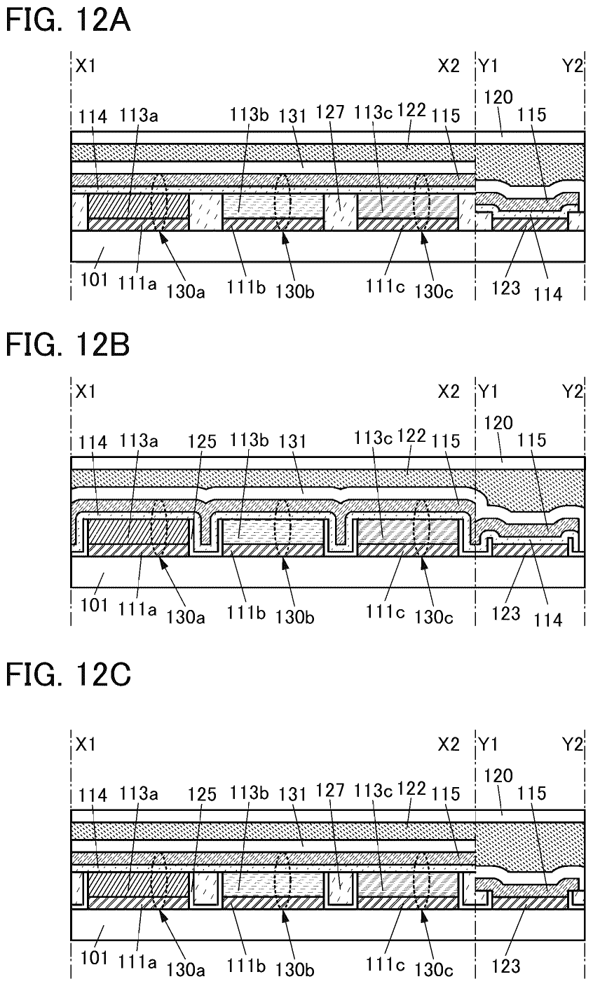

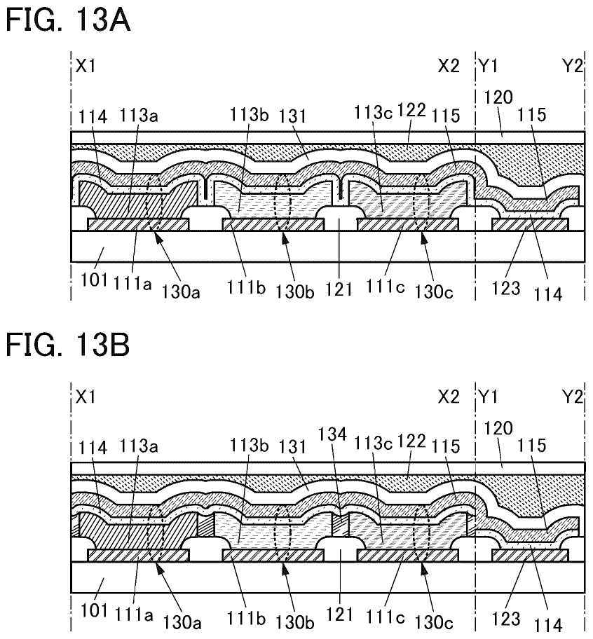

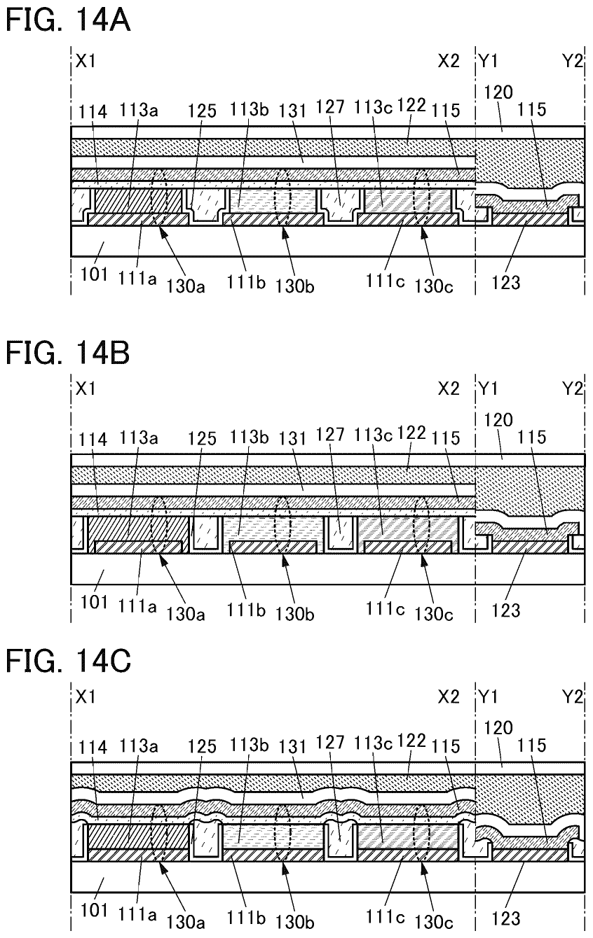

FIG. 11B illustrates a cross-sectional view taken along dashed-dotted lines X1-X2, X3-X4, and Y1-Y2 in FIG. 11A. Moreover, FIG. 12A to FIG. 12C, FIG. 13A and FIG. 13B, and FIG. 14A to FIG. 14C illustrate cross-sectional views taken along dashed-dotted lines X1-X2 and Y1-Y2 in FIG. 11A as modification examples.

As illustrated in FIG. 11B, in the display apparatus 100E, light-emitting devices 130a, 130b, and 130c and light-receiving devices 150d and 150e are provided over a layer 101 including transistors and a protective layer 131 is provided to cover these light-emitting devices and light-receiving devices. A substrate 120 is bonded to the protective layer 131 with a resin layer 122. In a region between two adjacent devices (a light-emitting device and a light-receiving device, two light-emitting devices, or two light-receiving devices), an insulating layer 125 and an insulating layer 127 over the insulating layer 125 are provided.

The display apparatus of one embodiment of the present invention can have any of the following structures: a top-emission structure in which light is emitted in a direction opposite to the substrate where the light-emitting device is formed, a bottom-emission structure in which light is emitted toward the substrate where the light-emitting device is formed, and a dual-emission structure in which light is emitted toward both surfaces.

The layer 101 including transistors can have a stacked-layer structure in which a plurality of transistors are provided over a substrate and an insulating layer is provided to cover these transistors, for example. The layer 101 including transistors may have a depressed portion between adjacent two devices. For example, an insulating layer positioned as the outermost surface of the layer 101 including transistors may have a depressed portion. Structure examples of the layer 101 including transistors will be described in Embodiment 3.

The light-emitting devices 130a, 130b, and 130c emit light of different colors. Preferably, the light-emitting devices 130a, 130b, and 130c emit light of three colors, red (R), green (G), and blue (B), for example.

Each of the light-emitting devices includes an EL layer between a pair of electrodes. In this specification and the like, one of the pair of electrodes may be referred to as a pixel electrode and the other may be referred to as a common electrode.

One of the pair of electrodes of the light-emitting device functions as an anode, and the other electrode functions as a cathode. Hereinafter, the case where the pixel electrode functions as an anode and the common electrode functions as a cathode is described as an example.

The light-emitting device 130a includes a conductive layer 111a over the layer 101 including transistors, an island-shaped first layer 113a over the conductive layer 111a, a fourth layer 114 over the island-shaped first layer 113a, and a common electrode 115 over the fourth layer 114. The conductive layer 111a functions as a pixel electrode. In the light-emitting device 130a, the first layer 113a and the fourth layer 114 can be collectively referred to as an EL layer. Description in Embodiment 4 can be referred to for the structure example of the light-emitting device.

The first layer 113a includes a hole-injection layer, a hole-transport layer, a light-emitting layer, and an electron-transport layer, for example. Alternatively, the first layer 113a includes a first light-emitting unit, a charge generation layer, and a second light-emitting unit, for example.

The fourth layer 114 includes an electron-injection layer, for example. Alternatively, the fourth layer 114 may include a stack of an electron-transport layer and an electron-injection layer.

The light-emitting device 130b includes a conductive layer 111b over the layer 101 including transistors, an island-shaped second layer 113b over the conductive layer 111b, the fourth layer 114 over the island-shaped second layer 113b, and the common electrode 115 over the fourth layer 114. The conductive layer 111b functions as a pixel electrode. In the light-emitting device 130b, the second layer 113b and the fourth layer 114 can be collectively referred to as an EL layer.

The light-emitting device 130c includes a conductive layer 111c over the layer 101 including transistors, an island-shaped third layer 113c over the conductive layer 111c, the fourth layer 114 over the island-shaped third layer 113c, and the common electrode 115 over the fourth layer 114. The conductive layer 111c functions as a pixel electrode. In the light-emitting device 130c, the third layer 113c and the fourth layer 114 can be collectively referred to as an EL layer.

The light-emitting devices 130a, 130b, and 130c emit light of different colors. Preferably, the light-emitting devices 130a, 130b, and 130c emit light of three colors, red (R), green (G), and blue (B), for example.

Each of the light-receiving devices includes an active layer between a pair of electrodes. In this specification and the like, one of the pair of electrodes may be referred to as a pixel electrode and the other may be referred to as a common electrode.

One of the pair of electrodes of the light-receiving device functions as an anode, and the other electrode functions as a cathode. Hereinafter, the case where the pixel electrode functions as an anode and the common electrode functions as a cathode is described as an example. That is, when the light-receiving device is driven by application of reverse bias between the pixel electrode and the common electrode, light entering the light-receiving device can be detected and charge can be generated and extracted as current. Alternatively, the pixel electrode may function as a cathode and the common electrode may function as an anode.

The light-receiving device 150d includes a conductive layer 111d over the layer 101 including transistors, an island-shaped fifth layer 113d over the conductive layer 111d, the fourth layer 114 over the island-shaped fifth layer 113d, and the common electrode 115 over the fourth layer 114. The conductive layer 111d functions as a pixel electrode.

The fifth layer 113d includes a hole-transport layer, an active layer, and an electron-transport layer, for example.

The light-receiving device 150e includes a conductive layer 111e over the layer 101 including transistors, an island-shaped sixth layer 113e over the conductive layer 111e, the fourth layer 114 over the island-shaped sixth layer 113e, and the common electrode 115 over the fourth layer 114. The conductive layer 111e functions as a pixel electrode.

The sixth layer 113e includes a hole-transport layer, an active layer, and an electron-transport layer, for example.

The fourth layer 114 is a layer shared by the light-emitting devices and the light-receiving devices. As described above, the fourth layer 114 includes an electron-injection layer, for example. Alternatively, the fourth layer 114 may include a stack of an electron-transport layer and an electron-injection layer.

The common electrode 115 is electrically connected to a conductive layer 123 provided in the connection portion 140. Note that FIG. 11B illustrates an example in which the fourth layer 114 is provided over the conductive layer 123 and the conductive layer 123 and the common electrode 115 are electrically connected to each other through the fourth layer 114. The fourth layer 114 is not necessarily provided in the connection portion 140. For example, FIG. 12C illustrates an example in which the fourth layer 114 is not provided over the conductive layer 123 and the conductive layer 123 and the common electrode 115 are directly connected to each other.

For example, by using a mask for specifying a film formation area (also referred to as an area mask, a rough metal mask, or the like), the fourth layer 114 and the common electrode 115 can be formed in different regions.

The side surfaces of the conductive layer 111a to the conductive layer 111e, the first layer 113a, the second layer 113b, the third layer 113c, the fifth layer 113d, and the sixth layer 113e are each covered with the insulating layer 125 and the insulating layer 127. Accordingly, the fourth layer 114 (or the common electrode layer 115) is inhibited from being in contact with the side surface of any of the conductive layer 111a to the conductive layer 111e, the first layer 113a, the second layer 113b, the third layer 113c, the fifth layer 113d, and the sixth layer 113e, whereby a short circuit of the light-emitting devices and the light-receiving devices can be inhibited. Accordingly, the reliability of the light-emitting devices and the light-receiving devices can be increased.

The insulating layer 125 preferably covers at least the side surfaces of the conductive layer 111a to the conductive layer 111e. In addition, the insulating layer 125 further preferably covers the side surfaces of the first layer 113a, the second layer 113b, the third layer 113c, t the fifth layer 113d, and the sixth layer 113e. The insulating layer 125 can be in contact with the side surfaces of the conductive layer 111a to the conductive layer 111e, the first layer 113a, the second layer 113b, the third layer 113c, the fifth layer 113d, and the sixth layer 113e.

The insulating layer 127 is provided over the insulating layer 125 to fill a depressed portion formed on the insulating layer 125. The insulating layer 127 can overlap with the side surfaces (or cover the side surfaces) of the conductive layer 111a to the conductive layer 111e, the first layer 113a, the second layer 113b, the third layer 113c, the fifth layer 113d, and the sixth layer 113e with the insulating layer 125 therebetween.

Moreover, providing the insulating layer 125 and the insulating layer 127 can fill a gap between the adjacent island-shaped layers, whereby the formation surface of a layer (the common electrode or the like) provided over the island-shaped layers can be less uneven and flatter. Thus, the coverage with the common electrode can be increased and disconnection of the common electrode can be prevented.

The insulating layer 125 or the insulating layer 127 can be provided in contact with the island-shaped layers. Thus, film separation of the island-shaped layers can be prevented. When the insulating layer and the island-shaped layers are in close contact with each other, an effect of fixing the adjacent island-shaped layers by or attaching the adjacent island-shaped layers to the insulating layer can be attained.

An organic resin film is suitable as the insulating layer 127. In the case where the side surface of an EL layer and a photosensitive organic resin film are in direct contact with each other, the EL layer might be damaged by an organic solvent or the like that might be contained in the photosensitive organic resin film. When an aluminum oxide film formed by an atomic layer deposition (ALD) method is used as the insulating layer 125, a structure can be employed in which the photosensitive organic resin film used as the insulating layer 127 and the side surface of the EL layer are not in direct contact with each other. Thus, the EL layer can be inhibited from being dissolved by the organic solvent, for example.

Note that one of the insulating layer 125 and the insulating layer 127 is not necessarily provided. For example, when the insulating layer 125 having a single-layer structure using an inorganic material is formed, the insulating layer 125 can be used as a protective insulating layer of the EL layer. In this way, the reliability of the display apparatus can be increased. For another example, when the insulating layer 127 having a single-layer structure using an organic material is formed, the insulating layer 127 can fill a gap between adjacent EL layers and planarization can be performed. In this way, the coverage with the common electrode (upper electrode) formed over the EL layers and the insulating layer 127 can be increased.

FIG. 12A illustrates an example in which the insulating layer 125 is not provided. In the case where the insulating layer 125 is not provided, a structure can be employed in which the insulating layer 127 is in contact with the side surfaces of the conductive layer 111a to the conductive layer 111e, the first layer 113a, the second layer 113b, the third layer 113c, the fifth layer 113d, and the sixth layer 113e. The insulating layer 127 can be provided to fill gaps between the EL layers of the light-emitting devices.

In that case, the insulating layer 127 is preferably formed using an organic material that causes less damage to the first layer 113a, the second layer 113b, the third layer 113c, the fifth layer 113d, and the sixth layer 113e. For the insulating layer 127, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin is preferably used, for example.

FIG. 12B illustrates an example in which the insulating layer 127 is not provided.

The fourth layer 114 and the common electrode 115 are provided over the first layer 113a, the second layer 113b, the third layer 113c, the fifth layer 113d, the sixth layer 113e, the insulating layer 125, and the insulating layer 127. At the stage before the insulating layer 125 and the insulating layer 127 are provided, a level difference due to a region where the pixel electrode and the EL layer are provided and a region where neither the pixel electrode nor the EL layer is provided (region between the light-emitting elements) is caused. The display apparatus of one embodiment of the present invention can eliminate the level difference by including the insulating layer 125 and the insulating layer 127, whereby the coverage with the fourth layer 114 and the common electrode 115 can be improved. Thus, connection defects caused by disconnection can be inhibited. Alternatively, it is possible to inhibit an increase in electric resistance due to local thinning of the common electrode 115 by the step.

In order to improve the planarity of the formation surfaces of the fourth layer 114 and the common electrode 115, the level of the top surface of the insulating layer 125 and the level of the top surface of the insulating layer 127 are each preferably the same or substantially the same as the level of the top surface of at least one of the first layer 113a, the second layer 113b, the third layer 113c, the fifth layer 113d, and the sixth layer 113e. The top surface of the insulating layer 127 preferably has a flat shape and may have a projection portion, a convex curve, a concave curve, or a depressed portion.

The insulating layer 125 includes regions in contact with the side surfaces of the first layer 113a, the second layer 113b, the third layer 113c, the fifth layer 113d, and the sixth layer 113e and functions as a protective insulating layer for the first layer 113a, the second layer 113b, the third layer 113c, the fifth layer 113d, and the sixth layer 113e. Providing the insulating layer 125 can inhibit impurities (e.g., oxygen and moisture) from entering the first layer 113a, the second layer 113b, the third layer 113c, the fifth layer 113d, and the sixth layer 113e through their side surfaces, whereby the display apparatus can have high reliability.

When the width (thickness) of the insulating layer 125 in the regions in contact with the side surfaces of the first layer 113a, the second layer 113b, the third layer 113c, the fifth layer 113d, and the sixth layer 113e is large in a cross-sectional view, the distances between the first layer 113a, the second layer 113b, the third layer 113c, the fifth layer 113d, and the sixth layer 113e are large, so that the aperture ratio might be low. When the width (thickness) of the insulating layer 125 is small, the effect of inhibiting impurities from entering the first layer 113a, the second layer 113b, the third layer 113c, the fifth layer 113d, and the sixth layer 113e through their side surfaces might be weakened. The width (thickness) of the insulating layer 125 in the regions in contact with the side surfaces of the first layer 113a, the second layer 113b, the third layer 113c, the fifth layer 113d, and the sixth layer 113e is preferably greater than or equal to 3 nm and less than or equal to 200 nm, further preferably greater than or equal to 3 nm and less than or equal to 150 nm, further preferably greater than or equal to 5 nm and less than or equal to 150 nm, still further preferably greater than or equal to 5 nm and less than or equal to 100 nm, still further preferably greater than or equal to 10 nm and less than or equal to 100 nm, yet further preferably greater than or equal to 10 nm and less than or equal to 50 nm. When the width (thickness) of the insulating layer 125 is within the above range, the display apparatus can have both a high aperture ratio and high reliability.

The insulating layer 125 can be an insulating layer containing an inorganic material. As the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium-gallium-zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. Aluminum oxide is particularly preferable because it has high selectivity with respect to the EL layer in etching and has a function of protecting the EL layer in forming the insulating layer 127 which is to be described later. In particular, when an inorganic insulating film such as an aluminum oxide film, a hafnium oxide film, or a silicon oxide film that is formed by an ALD method is employed for the insulating layer 125, it is possible to form the insulating layer 125 that has few pinholes and an excellent function of protecting the EL layer. The insulating layer 125 may have a stacked-layer structure of a film formed by an ALD method and a film formed by a sputtering method. For example, the insulating layer 125 may have a stacked-layer structure of an aluminum oxide film formed by an ALD method and a silicon nitride film formed by a sputtering method.

Note that in this specification and the like, an oxynitride refers to a material in which an oxygen content is higher than a nitrogen content, and a nitride oxide refers to a material in which a nitrogen content is higher than an oxygen content. For example, silicon oxynitride refers to a material in which an oxygen content is higher than a nitrogen content, and silicon nitride oxide refers to a material in which a nitrogen content is higher than an oxygen content.

The insulating layer 125 can be formed by a sputtering method, a chemical vapor deposition (CVD) method, a pulsed laser deposition (PLD) method, an ALD method, or the like. The insulating layer 125 is preferably formed by an ALD method enabling good coverage.

The insulating layer 127 provided over the insulating layer 125 has a function of enabling planarization in the depressed portion on the insulating layer 125, which is formed between the adjacent light-emitting devices. In other words, the insulating layer 127 has an effect of improving the planarity of the formation surface of the common electrode 115. An insulating layer containing an organic material can be suitably used as the insulating layer 127. For example, the insulating layer 127 can be formed using an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like. For the insulating layer 127, an organic material such as polyvinyl alcohol (PVA), polyvinyl butyral, polyvinylpyrrolidone, polyethylene glycol, polyglycerin, pullulan, water-soluble cellulose, or an alcohol-soluble polyamide resin may be used. The insulating layer 127 can be formed using a photosensitive resin. A photoresist may be used as the photosensitive resin. As the photosensitive resin, a positive photosensitive material or a negative photosensitive material can be used.

The difference between the level of the top surface of the insulating layer 127 and the level of the top surface of any of the first layer 113a, the second layer 113b, the third layer 113c, the fifth layer 113d, and the sixth layer 113e is preferably less than or equal to 0.5 times, further preferably less than or equal to 0.3 times the thickness of the insulating layer 127, for example. For another example, the insulating layer 127 may be provided such that the level of the top surface of any of the first layer 113a, the second layer 113b, the third layer 113c, the fifth layer 113d, and the sixth layer 113e is higher than the level of the top surface of the insulating layer 127. For another example, the insulating layer 127 may be provided such that the level of the top surface of the insulating layer 127 is higher than the level of the top surface of the light-emitting layer included in the first layer 113a, the second layer 113b, or the third layer 113c.

The protective layer 131 is preferably provided over the light-emitting devices 130a, 130b, and 130c and the light-receiving devices 150d and 150e. Providing the protective layer 131 can improve the reliability of the light-emitting devices and the light-receiving devices.

There is no limitation on the conductivity of the protective layer 131. For the protective layer 131, at least one of an insulating film, a semiconductor film, and a conductive film can be used.

The protective layer 131 including an inorganic film can inhibit deterioration of the light-emitting devices 130a, 130b, and 130c and the light-receiving devices 150d and 150e by preventing oxidation of the common electrode 115 and inhibiting entry of impurities (e.g., moisture and oxygen) into the light-emitting devices and the light-receiving devices, for example; thus, the reliability of the display apparatus can be improved.

For the protective layer 131, an inorganic insulating film such as an oxide insulating film, a nitride insulating film, an oxynitride insulating film, or a nitride oxide insulating film can be used, for example. Examples of the oxide insulating film include a silicon oxide film, an aluminum oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film.

The protective layer 131 preferably includes a nitride insulating film or a nitride oxide insulating film, and further preferably includes a nitride insulating film.

For the protective layer 131, an inorganic film containing an In—Sn oxide (also referred to as ITO), an In—Zn oxide, a Ga—Zn oxide, an Al—Zn oxide, an indium gallium zinc oxide (In—Ga—Zn oxide, also referred to as IGZO), or the like can also be used. The inorganic film preferably has high resistance, specifically, higher resistance than the common electrode 115. The inorganic film may further contain nitrogen.

When light emitted from the light-emitting device is extracted through the protective layer 131, the protective layer 131 preferably has a high visible-light-transmitting property. For example, ITO, IGZO, and aluminum oxide are preferable because they are inorganic materials having a high visible-light-transmitting property.

The protective layer 131 can have, for example, a stacked-layer structure of an aluminum oxide film and a silicon nitride film over the aluminum oxide film, or a stacked-layer structure of an aluminum oxide film and an IGZO film over the aluminum oxide film. Such a stacked-layer structure can inhibit entry of impurities (such as water and oxygen) into the EL layer.

Furthermore, the protective layer 131 may include an organic film. For example, the protective layer 131 may include both an organic film and an inorganic film.

The end portions of top surfaces of the conductive layer 111a to the conductive layer 111c are not covered with an insulating layer. This allows the distance between adjacent light-emitting devices to be extremely narrowed. As a result, the display apparatus can have high resolution or high definition.

Note that as illustrated in FIG. 13A and FIG. 13B, the end portions of the conductive layer 111a to the conductive layer 111c may be covered with an insulating layer 121.

The insulating layer 121 can have a single-layer structure or a stacked-layer structure including one or both of an inorganic insulating film and an organic insulating film.

Examples of an organic insulating material that can be used for the insulating layer 121 include an acrylic resin, an epoxy resin, a polyimide resin, a polyamide resin, a polyimide-amide resin, a polysiloxane resin, a benzocyclobutene-based resin, and a phenol resin. As an inorganic insulating film that can be used as the insulating layer 121, an inorganic insulating film that can be used as the protective layer 131 can be used.

When an inorganic insulating film is used as the insulating layer 121 that covers the end portions of the pixel electrodes, impurities are less likely to enter the light-emitting devices as compared with the case where an organic insulating film is used; therefore, the reliability of the light-emitting devices can be improved. When an organic insulating film is used as the insulating layer 121 that covers the end portions of the pixel electrodes, high step coverage can be obtained as compared with the case where an inorganic insulating film is used; therefore, an influence of the shape of the pixel electrodes can be small. Therefore, a short circuit in the light-emitting devices can be prevented. Specifically, when an organic insulating film is used as the insulating layer 121, the insulating layer 121 can be processed into a tapered shape or the like. In this specification and the like, a tapered shape indicates a shape in which at least part of the side surface of a structure is inclined to a substrate surface or a formation surface. For example, a tapered shape preferably includes a region where the angle between the inclined side surface and the substrate surface or the formation surface (such an angle is also referred to as a taper angle) is less than 90°.

Note that the insulating layer 121 is not necessarily provided. The aperture ratio of the subpixel can be sometimes increased without providing the insulating layer 121. Alternatively, the distance between subpixels can be shortened and the resolution or the definition of the display apparatus can be sometimes increased.

Note that FIG. 13A illustrates an example in which the fourth layer 114 is also formed in a region between the first layer 113a and the second layer 113b, for example; however, as illustrated in FIG. 13B, a space 134 may be formed in the region.

The space 134 contains, for example, one or more selected from air, nitrogen, oxygen, carbon dioxide, and Group 18 elements (typified by helium, neon, argon, xenon, and krypton). Alternatively, a resin or the like may fill the space 134.

FIG. 11B and the like each illustrate an example in which the end portion of the conductive layer 111a and the end portion of the first layer 113a are aligned or substantially aligned with each other. In other words, the top surface shapes of the conductive layer 111a and the first layer 113a are the same or substantially the same.

The size relationships of the shapes between the conductive layer 111a and the first layer 113a, between the conductive layer 111b and the second layer 113b, between the conductive layer 111c and the third layer 113c, and the like are not particularly limited. FIG. 14A illustrates an example in which the end portion of the first layer 113a is positioned on an inner side than the end portion of the conductive layer 111a. In FIG. 14A, the end portion of the first layer 113a is positioned over the conductive layer 111a. FIG. 14B illustrates an example in which the end portion of the first layer 113a is positioned on an outer side than the end portion of the conductive layer 111a. FIG. 14B, the first layer 113a is provided to cover the end portion of the conductive layer 111a.

In the case where end portions are aligned or substantially aligned with each other and the case where top surface shapes are the same or substantially the same, it can be said that outlines of stacked layers at least partly overlap with each other in a top view. For example, the case of processing the upper layer and the lower layer with the use of the same mask pattern or mask patterns that are partly the same is included. However, in some cases, the outlines do not completely overlap with each other and the upper layer is positioned inward from the lower layer or the upper layer is positioned outward from the lower layer; such a case is also described with the expression “end portions are substantially aligned with each other” or “top surface shapes are substantially the same”.

FIG. 14C illustrates a modification example of the insulating layer 127. In FIG. 14C, in a cross-sectional view, the top surface of the insulating layer 127 has a shape gently bulged toward the center, i.e., a convex surface, and has a shape in which the center and its vicinity are depressed, i.e., a concave surface.

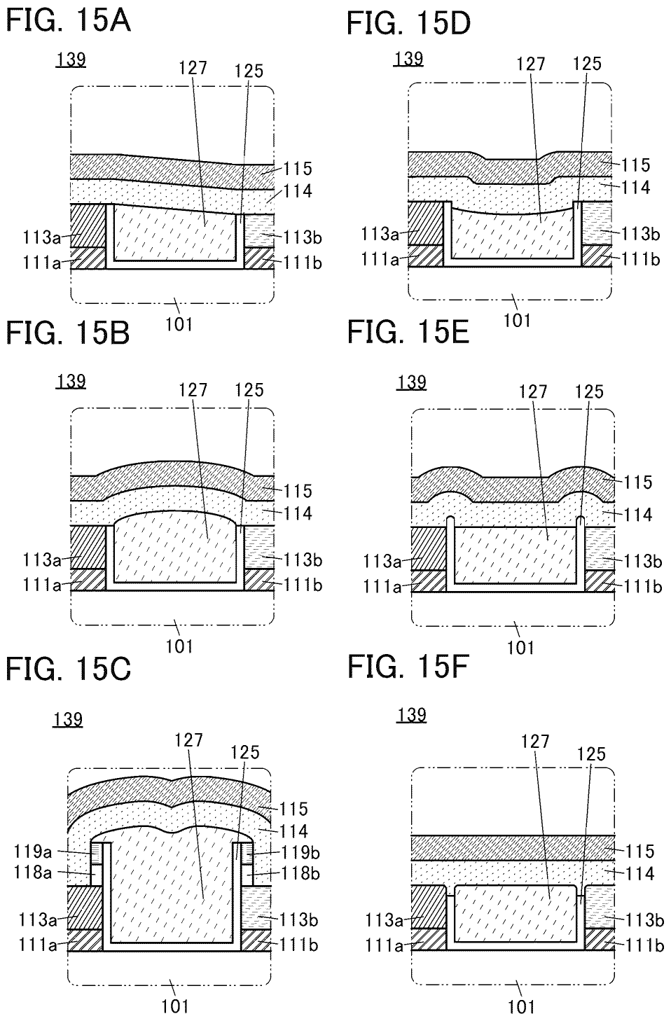

FIG. 15A to FIG. 15F each illustrate a cross-sectional structure of a region 139 including the insulating layer 127 and its surroundings.

FIG. 15A illustrates an example in which the first layer 113a and the second layer 113b have different thicknesses. The top surface of the insulating layer 125 is level or substantially level with the top surface of the first layer 113a on the first layer 113a side, and level or substantially level with the top surface of the second layer 113b on the second layer 113b side. The top surface of the insulating layer 127 has a gentle slope whose side closer to the first layer 113a is higher and side closer to the second layer 113b is lower. In this manner, the top surfaces of the insulating layer 125 and the insulating layer 127 are preferably level with the top surface of the adjacent EL layer. Alternatively, the top surfaces of the insulating layer 125 and the insulating layer 127 may have a flat portion that is level with the top surface of any adjacent EL layers.

In FIG. 15B, the top surface of the insulating layer 127 has a region whose level is higher than the levels of the top surface of the first layer 113a and the top surface of the second layer 113b. In FIG. 15B, the top surface of the insulating layer 127 can have, in a cross-sectional view, a shape in which the center and its vicinity are bulged, i.e., a shape including a convex surface.

In FIG. 15C, in a cross-sectional view, the top surface of the insulating layer 127 has a shape gently bulged toward the center, i.e., a convex surface, and has a shape in which the center and its vicinity are depressed, i.e., a concave surface. The insulating layer 127 has a region whose level is higher than the levels of the top surface of the first layer 113a and the top surface of the second layer 113b. In the region 139, the display apparatus includes at least one of a sacrificial layer 118a and a sacrificial layer 119a, the insulating layer 127 includes a first region that is higher in level than the top surface of the first layer 113a and the top surface of the second layer 113b and positioned outside the insulating layer 125, and the first region is positioned over at least one of the sacrificial layer 118a and the sacrificial layer 119a. In addition, in the region 139, the display apparatus includes at least one of a sacrificial layer 118b and a sacrificial layer 119b, the insulating layer 127 includes a second region that is higher in level than the top surface of the first layer 113a and the top surface of the second layer 113b and positioned outside the insulating layer 125, and the second region is positioned over at least one of the sacrificial layer 118b and the sacrificial layer 119b.

In FIG. 15D, the top surface of the insulating layer 127 has a region whose level is lower than the levels of the top surface of the first layer 113a and the top surface of the second layer 113b. The top surface of the insulating layer 127 has, in a cross-sectional view, a shape in which the center and its vicinity are depressed, i.e., a shape including a concave surface.

In FIG. 15E, the top surface of the insulating layer 125 has a region whose level is higher than the levels of the top surface of the first layer 113a and the top surface of the second layer 113b. That is, the insulating layer 125 protrudes from the formation surface of the fourth layer 114 and forms a projecting portion.

In formation of the insulating layer 125, for example, when the insulating layer 125 is formed to be level or substantially level with the sacrificial layer, the insulating layer 125 may protrude as illustrated in FIG. 15E.

In FIG. 15F, the top surface of the insulating layer 125 has a region whose level is lower than the levels of the top surface of the first layer 113a and the top surface of the second layer 113b. That is, the insulating layer 125 forms a depressed portion on the formation surface of the fourth layer 114.

As described above, the insulating layer 125 and the insulating layer 127 can have a variety of shapes.

As the sacrificial layer, an inorganic film such as a metal film, an alloy film, a metal oxide film, a semiconductor film, or an inorganic insulating film can be used, for example.

For the sacrificial layer, a metal material such as gold, silver, platinum, magnesium, nickel, tungsten, chromium, molybdenum, iron, cobalt, copper, palladium, titanium, aluminum, yttrium, zirconium, or tantalum or an alloy material containing the metal material can be used, for example.

For the sacrificial layer, a metal oxide such as an In—Ga—Zn oxide can be used. As the sacrificial layer, an In—Ga—Zn oxide film can be formed by a sputtering method, for example. It is also possible to use indium oxide, an In—Zn oxide, an In—Sn oxide, an indium titanium oxide (In—Ti oxide), an indium tin zinc oxide (In—Sn—Zn oxide), an indium titanium zinc oxide (In—Ti—Zn oxide), an indium gallium tin zinc oxide (In—Ga—Sn—Zn oxide), or the like. Alternatively, an indium tin oxide containing silicon, or the like can also be used.

In place of gallium described above, an element M (M is one or more of aluminum, silicon, boron, yttrium, copper, vanadium, beryllium, titanium, iron, nickel, germanium, zirconium, molybdenum, lanthanum, cerium, neodymium, hafnium, tantalum, tungsten, and magnesium) may be used.

As the sacrificial layer, any of a variety of inorganic insulating films that can be used as the protective layer 131 can be used. In particular, an oxide insulating film is preferable because its adhesion to the EL layer is higher than that of a nitride insulating film. For example, an inorganic insulating material such as aluminum oxide, hafnium oxide, or silicon oxide can be used for the sacrificial layer. As the sacrificial layer, an aluminum oxide film can be formed by an ALD method, for example. An ALD method is preferably used, in which case damage to a base (in particular, the EL layer or the like) can be reduced. As the sacrificial layer, a silicon nitride film can be formed by a sputtering method, for example.

For example, the sacrificial layer can employ a stacked-layer structure of an inorganic insulating film (e.g., an aluminum oxide film) formed by an ALD method and an In—Ga—Zn oxide film formed by a sputtering method. Alternatively, the sacrificial layer can employ a stacked-layer structure of an inorganic insulating film (e.g., an aluminum oxide film) formed by an ALD method and an aluminum film, a tungsten film, or an inorganic insulating film (e.g., a silicon nitride film) formed by a sputtering method.

In this specification and the like, a device formed using a metal mask or an FMM (fine metal mask) may be referred to as a device having an MM (metal mask) structure. In this specification and the like, a device formed without using a metal mask or an FMM may be referred to as a device having an MML (metal maskless) structure.

In this specification and the like, a structure in which light-emitting layers in light-emitting devices of different colors (here, blue (B), green (G), and red (R)) are separately formed or separately patterned may be referred to as an SBS (Side By Side) structure. The SBS structure allows optimization of materials and structures of light-emitting devices and thus can extend freedom of choice of the materials and the structures, which makes it easy to improve the luminance and the reliability.

In this specification and the like, a light-emitting device capable of emitting white light may be referred to as a white-light-emitting device. Note that a combination of white-light-emitting devices with coloring layers (e.g., color filters) enables a full-color display apparatus.

Structures of light-emitting devices can be classified roughly into the single structure and the tandem structure. A device with the single structure includes one light-emitting unit between a pair of electrodes, and the light-emitting unit preferably includes one or more light-emitting layers. When white light emission is obtained using two light-emitting layers, the two light-emitting layers are selected such that emission colors of the light-emitting layers are complementary colors. For example, when emission colors of a first light-emitting layer and a second light-emitting layer are complementary colors, the light-emitting device can be configured to emit white light as a whole. When white light emission is obtained using three or more light-emitting layers, the light-emitting device is configured to emit white light as a whole by combining emission colors of the three or more light-emitting layers.

A device having the tandem structure includes two or more light-emitting units between a pair of electrodes, and each light-emitting unit preferably includes one or more light-emitting layers. To obtain white light emission, the structure is employed in which light from light-emitting layers of a plurality of light-emitting units is combined to enable white light emission. Note that a structure for obtaining white light emission is similar to a structure of the case of the single structure. In the device having the tandem structure, a charge-generation layer is suitably provided between the plurality of light-emitting units.

When the above-described white-light-emitting device (having the single structure or the tandem structure) and a light-emitting device having the SBS structure are compared with each other, the light-emitting device having the SBS structure can have lower power consumption than the white-light-emitting device. To reduce power consumption, a light-emitting device having the SBS structure is preferably used. Meanwhile, the white-light-emitting device is preferable in terms of lower manufacturing cost or higher manufacturing yield because the manufacturing process of the white-light-emitting device is simpler than that of a light-emitting device having the SBS structure.

In the display apparatus of this embodiment, the distance between the light-emitting devices can be narrowed. Specifically, the distance between the light-emitting devices, the distance between the EL layers, or the distance between the pixel electrodes can be less than 10 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to nm. In other words, the display apparatus includes a region where the distance between the side surface of the first layer 113a and the side surface of the second layer 113b or the distance between the side surface of the second layer 113b and the side surface of the third layer 113c is less than or equal to 1 μm, preferably less than or equal to 0.5 μm (500 nm), further preferably less than or equal to 100 nm.

Note that the distance between the light-emitting device and the light-receiving device can be set within the above range. In order to inhibit leakage between the light-emitting device and the light-receiving device, the distance between the light-emitting device and the light-receiving device is preferably larger than the distance between the light-emitting devices. For example, the distance between the light-emitting device and the light-receiving device can be set to 8 μm or less, 5 μm or less, or 3 μm or less.

A light-blocking layer may be provided on the surface of the substrate 120 on the resin layer 122 side. Any of a variety of optical members can be arranged on the outer surface of the substrate 120. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film suppressing the attachment of stain, a hard coat film inhibiting generation of a scratch caused by the use, an impact-absorbing layer, or the like may be arranged on the outer surface of the substrate 120.

For the substrate 120, glass, quartz, ceramics, sapphire, a resin, a metal, an alloy, a semiconductor, or the like can be used. The substrate on the side from which light from the light-emitting device is extracted is formed using a material that transmits the light. When the substrate 120 is formed using a flexible material, the flexibility of the display apparatus can be increased and a flexible display can be obtained. Furthermore, a polarizing plate may be used as the substrate 120.

For the substrate 120, any of the following can be used, for example: polyester resins such as polyethylene terephthalate (PET) and polyethylene naphthalate (PEN), a polyacrylonitrile resin, an acrylic resin, a polyimide resin, a polymethyl methacrylate resin, a polycarbonate (PC) resin, a polyethersulfone (PES) resin, polyamide resins (e.g., nylon and aramid), a polysiloxane resin, a cycloolefin resin, a polystyrene resin, a polyamide-imide resin, a polyurethane resin, a polyvinyl chloride resin, a polyvinylidene chloride resin, a polypropylene resin, a polytetrafluoroethylene (PTFE) resin, an ABS resin, and cellulose nanofiber. Glass that is thin enough to have flexibility may be used for the substrate 120.

In the case where a circularly polarizing plate overlaps with the display apparatus, a substrate with high optical isotropy is preferably used as the substrate included in the display apparatus. A substrate with high optical isotropy has a low birefringence (in other words, a small amount of birefringence).

The absolute value of a retardation (phase difference) of a substrate having high optical isotropy is preferably less than or equal to 30 nm, further preferably less than or equal to 20 nm, still further preferably less than or equal to 10 nm.

Examples of a film having high optical isotropy include a triacetyl cellulose (TAC, also referred to as cellulose triacetate) film, a cycloolefin polymer (COP) film, a cycloolefin copolymer (COC) film, and an acrylic film.

When a film is used for the substrate and the film absorbs water, the shape of a display panel might be changed, e.g., creases are generated. Thus, for the substrate, a film with a low water absorption rate is preferably used. For example, the water absorption rate of the film is preferably lower than or equal to 1%, further preferably lower than or equal to 0.1%, still further preferably lower than or equal to 0.01%.

For the resin layer 122, any of a variety of curable adhesives such as a reactive curable adhesive, a thermosetting curable adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, an imide resin, a PVC (polyvinyl chloride) resin, a PVB (polyvinyl butyral) resin, and an EVA (ethylene-vinyl acetate) resin. In particular, a material with low moisture permeability, such as an epoxy resin, is preferable. A two-component-mixture-type resin may be used. An adhesive sheet or the like may be used.

As examples of the materials that can be used for the gate, the source, and the drain of the transistor and conductive layers such as a variety of wirings and electrodes included in the display apparatus, metals such as aluminum, titanium, chromium, nickel, copper, yttrium, zirconium, molybdenum, silver, tantalum, and tungsten, and an alloy containing any of these metals as its main component can be given. A single-layer structure or a stacked-layer structure including a film containing any of these materials can be used.

As a light-transmitting conductive material, a conductive oxide such as indium oxide, indium tin oxide, indium zinc oxide, zinc oxide, or zinc oxide containing gallium, or graphene can be used. It is also possible to use a metal material such as gold, silver, platinum, magnesium, nickel, tungsten, chromium, molybdenum, iron, cobalt, copper, palladium, or titanium; or an alloy material containing any of these metal materials. Alternatively, a nitride of the metal material (e.g., titanium nitride) or the like may be used. Note that in the case of using the metal material or the alloy material (or the nitride thereof), the thickness is preferably set small enough to allow light transmission. Alternatively, a stacked-layer film of any of the above materials can be used for the conductive layers. For example, a stacked-layer film of indium tin oxide and an alloy of silver and magnesium is preferably used to increase conductivity. They can also be used for conductive layers such as a variety of wirings and electrodes included in the display apparatus, and the conductive layer (the conductive layer functioning as the pixel electrode or the common electrode) included in the light-emitting device.

Examples of insulating materials that can be used for the insulating layers include a resin such as an acrylic resin or an epoxy resin, and an inorganic insulating material such as silicon oxide, silicon oxynitride, silicon nitride oxide, silicon nitride, or aluminum oxide.

Next, materials that can be used in the light-emitting device and the light-receiving device will be described.

A conductive film that transmits visible light and infrared light is used for the electrode through which light is extracted among the pixel electrode and the common electrode. A conductive film that reflects visible light and infrared light is preferably used for the electrode through which light is not extracted.

As a material that forms the pair of electrodes (the pixel electrode and the common electrode) of the light-emitting device and the light-receiving device, a metal, an alloy, an electrically conductive compound, a mixture thereof, or the like can be used as appropriate. Specific examples include an indium tin oxide (an In—Sn oxide, also referred to as ITO), an In—Si—Sn oxide (also referred to as ITSO), an indium zinc oxide (In—Zn oxide), an In—W—Zn oxide, an alloy containing aluminum (an aluminum alloy) such as an alloy of aluminum, nickel, and lanthanum (Al—Ni—La), and an alloy containing silver such as an alloy of silver and magnesium and an alloy of silver, palladium, and copper (Ag—Pd—Cu, also referred to as APC). In addition, it is possible to use a metal such as aluminum (Al), magnesium (Mg), titanium (Ti), chromium (Cr), manganese (Mn), iron (Fe), cobalt (Co), nickel (Ni), copper (Cu), gallium (Ga), zinc (Zn), indium (In), tin (Sn), molybdenum (Mo), tantalum (Ta), tungsten (W), palladium (Pd), gold (Au), platinum (Pt), silver (Ag), yttrium (Y), or neodymium (Nd) or an alloy containing an appropriate combination of any of these metals. It is also possible to use a Group 1 element or a Group 2 element in the periodic table, which is not described above (e.g., lithium (Li), cesium (Cs), calcium (Ca), or strontium (Sr)), a rare earth metal such as europium (Eu) or ytterbium (Yb), an alloy containing an appropriate combination of any of these elements, graphene, or the like.

The light-emitting device and the light-receiving device preferably have a microcavity structure. Therefore, one of the pair of electrodes of the light-emitting device and the light-receiving device preferably includes an electrode having properties of transmitting and reflecting visible light (a semi-transmissive and semi-reflective electrode), and the other preferably includes an electrode having a property of reflecting visible light (a reflective electrode). When the light-emitting device has a microcavity structure, light obtained from the light-emitting layer can be resonated between the electrodes, whereby light emitted from the light-emitting device can be intensified. When the light-receiving device has a microcavity structure, light received by the active layer can be resonated between the electrodes, whereby the detection accuracy of the light-receiving device can be increased.

Note that the semi-transmissive and semi-reflective electrode can have a stacked-layer structure of a reflective electrode and an electrode having a property of transmitting visible light (also referred to as a transparent electrode).

The transparent electrode has a light transmittance higher than or equal to 40%. For example, an electrode having a visible light (light with a wavelength greater than or equal to 400 nm and less than 750 nm) transmittance higher than or equal to 40% is preferably used in the light-emitting device. The semi-transmissive and semi-reflective electrode has a visible light reflectance higher than or equal to 10% and lower than or equal to 95%, preferably higher than or equal to 30% and lower than or equal to 80%. The reflective electrode has a visible light reflectance higher than or equal to 40% and lower than or equal to 100%, preferably higher than or equal to 70% and lower than or equal to 100%. These electrodes preferably have a resistivity lower than or equal to 1×10⁻² Ωcm. The near-infrared light (light at wavelengths greater than or equal to 750 nm and less than or equal to 1300 nm) transmittance and reflectivity of these electrodes preferably satisfy the above-described numerical ranges of the visible light transmittance and reflectivity.

The first layer 113a, the second layer 113b, and the third layer 113c each include the light-emitting layer. The first layer 113a, the second layer 113b, and the third layer 113c preferably include the light-emitting layers that emit light of different colors.

The light-emitting layer is a layer containing a light-emitting substance. The light-emitting layer can contain one or more kinds of light-emitting substances. As the light-emitting substance, a substance that exhibits an emission color of blue, violet, bluish violet, green, yellowish green, yellow, orange, red, or the like is appropriately used. A substance that emits near-infrared light can also be used as the light-emitting substance.

Examples of the light-emitting substance include a fluorescent material, a phosphorescent material, a thermally activated delayed fluorescent (TADF) material, and a quantum dot material.

Examples of the fluorescent material include a pyrene derivative, an anthracene derivative, a triphenylene derivative, a fluorene derivative, a carbazole derivative, a dibenzothiophene derivative, a dibenzofuran derivative, a dibenzoquinoxaline derivative, a quinoxaline derivative, a pyridine derivative, a pyrimidine derivative, a phenanthrene derivative, and a naphthalene derivative.

Examples of the phosphorescent material include an organometallic complex (particularly an iridium complex) having a 4H-triazole skeleton, a 1H-triazole skeleton, an imidazole skeleton, a pyrimidine skeleton, a pyrazine skeleton, or a pyridine skeleton; an organometallic complex (particularly an iridium complex) having a phenylpyridine derivative including an electron-withdrawing group as a ligand; a platinum complex; and a rare earth metal complex.

The light-emitting layer may contain one or more kinds of organic compounds (e.g., a host material and an assist material) in addition to the light-emitting substance (a guest material). As one or more kinds of organic compounds, one or both of the hole-transport material and the electron-transport material can be used. As one or more kinds of organic compounds, a bipolar material or a TADF material may be used.

The light-emitting layer preferably includes, for example, a phosphorescent material and a combination of a hole-transport material and an electron-transport material that easily forms an exciplex. With such a structure, light emission can be efficiently obtained by ExTET (Exciplex-Triplet Energy Transfer), which is energy transfer from an exciplex to a light-emitting substance (a phosphorescent material). When a combination of materials is selected so as to form an exciplex that exhibits light emission whose wavelength overlaps with the wavelength of a lowest-energy-side absorption band of the light-emitting substance, energy can be smoothly transferred and light emission can be efficiently obtained. With this structure, high efficiency, low-voltage driving, and a long lifetime of the light-emitting device can be achieved at the same time.

In addition to the light-emitting layer, the first layer 113a, the second layer 113b, and the third layer 113c may further include layers containing a substance with a high hole-injection property, a substance with a high hole-transport property (also referred to as a hole-transport material), a hole-blocking material, a substance with a high electron-transport property (also referred to as an electron-transport material), a substance with a high electron-injection property, an electron-blocking material, a substance with a bipolar property (also referred to as a substance with a high electron-transport property and a high hole-transport property or a bipolar material), and the like.

Either a low molecular compound or a high molecular compound can be used in the light-emitting device, and an inorganic compound may also be included. Each layer included in the light-emitting device can be formed by an evaporation method (including a vacuum evaporation method), a transfer method, a printing method, an ink-jet method, a coating method, or the like.

For example, the first layer 113a, the second layer 113b, and the third layer 113c may each include one or more of a hole-injection layer, a hole-transport layer, a hole-blocking layer, an electron-blocking layer, an electron-transport layer, and an electron-injection layer. Furthermore, the first layer 113a, the second layer 113b, and the third layer 113c may each include a charge-generation layer.

The fourth layer 114 can include one or more of a hole-injection layer, a hole-transport layer, a hole-blocking layer, an electron-blocking layer, an electron-transport layer, and an electron-injection layer. For example, in the case where the conductive layer 111a to the conductive layer 111c each function as an anode and the common electrode 115 functions as a cathode, the fourth layer 114 preferably includes an electron-injection layer.

A hole-injection layer is a layer injecting holes from an anode to a hole-transport layer, and a layer containing a substance with a high hole-injection property. Examples of the substance with a high hole-injection property include an aromatic amine compound and a composite material containing a hole-transport material and an acceptor material (electron-accepting material).

In the light-emitting device, the hole-transport layer is a layer that transports holes injected from the anode by the hole-injection layer, to the light-emitting layer. In the light-receiving device, the hole-transport layer is a layer that transports holes generated in the active layer on the basis of incident light, to the anode. The hole-transport layer is a layer containing a hole-transport material. As the hole-transport material, a substance having a hole mobility greater than or equal to 1×10⁻⁶ cm²/Vs is preferable. Note that other substances can also be used as long as they have a hole-transport property higher than an electron-transport property. As the hole-transport material, a substance having a high hole-transport property, such as a n-electron rich heteroaromatic compound (e.g., a carbazole derivative, a thiophene derivative, or a furan derivative) or an aromatic amine (a compound having an aromatic amine skeleton), is preferable.

In the light-emitting device, the electron-transport layer is a layer that transports electrons injected from the cathode by the electron-injection layer, to the light-emitting layer. In the light-receiving device, the electron-transport layer is a layer that transports electrons generated in the active layer on the basis of incident light, to the cathode. The electron-transport layer is a layer containing an electron-transport material. As the electron-transport material, a substance having an electron mobility greater than or equal to 1×10⁻⁶ cm²/Vs is preferable. Note that other substances can also be used as long as they have an electron-transport property higher than a hole-transport property. As the electron-transport material, it is possible to use a substance having a high electron-transport property, such as a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative having a quinoline ligand, a benzoquinoline derivative, a quinoxaline derivative, a dibenzoquinoxaline derivative, a pyridine derivative, a bipyridine derivative, a pyrimidine derivative, or a n-electron deficient heteroaromatic compound such as a nitrogen-containing heteroaromatic compound.

The electron-injection layer is a layer injecting electrons from a cathode to the electron-transport layer, and a layer containing a substance with a high electron-injection property. As the substance with a high electron-injection property, an alkali metal, an alkaline earth metal, or a compound thereof can be used. As the substance with a high electron-injection property, a composite material containing an electron-transport material and a donor material (electron-donating material) can also be used.

For the electron-injection layer, for example, an alkali metal, an alkaline earth metal, or a compound thereof, such as lithium, cesium, ytterbium, lithium fluoride (LiF), cesium fluoride (CsF), calcium fluoride (CaF₂), 8-(quinolinolato)lithium (abbreviation: Liq), 2-(2-pyridyl)phenolatolithium (abbreviation: LiPP), 2-(2-pyridyl)-3-pyridinolatolithium (abbreviation: LiPPy), 4-phenyl-2-(2-pyridyl)phenolatolithium (abbreviation: LiPPP), lithium oxide (LiOx), or cesium carbonate can be used. The electron-injection layer may have a stacked-layer structure of two or more layers. In the stacked-layer structure, for example, lithium fluoride can be used for the first layer and ytterbium can be used for the second layer.

Alternatively, an electron-transport material may be used for the electron-injection layer. For example, a compound having an unshared electron pair and having an electron deficient heteroaromatic ring can be used as the electron-transport material. Specifically, a compound with at least one of a pyridine ring, a diazine ring (a pyrimidine ring, a pyrazine ring, and a pyridazine ring), and a triazine ring can be used.

Note that the lowest unoccupied molecular orbital (LUMO) of the organic compound having an unshared electron pair is preferably greater than or equal to −3.6 eV and less than or equal to −2.3 eV. In general, the highest occupied molecular orbital (HOMO) level and the LUMO level of an organic compound can be estimated by CV (cyclic voltammetry), photoelectron spectroscopy, optical absorption spectroscopy, inverse photoelectron spectroscopy, or the like.

For example, 4,7-diphenyl-1,10-phenanthroline (abbreviation: BPhen), 2,9-bis(naphthalen-2-yl)-4,7-diphenyl-1,10-phenanthroline (abbreviation: NBPhen), diquinoxalino[2,3-a:2′,3′-c]phenazine (abbreviation: HATNA), or 2,4,6-tris[3′-(pyridin-3-yl)biphenyl-3-yl]-1,3,5-triazine (abbreviation: TmPPPyTz) can be used as the organic compound having an unshared electron pair. Note that NBPhen has a higher glass transition temperature (Tg) than BPhen and thus has high heat resistance.

For the charge-generation layer, for example, a material that can be used for the electron-injection layer, such as lithium, can be suitably used. For the charge-generation layer, for example, a material that can be used for the hole-injection layer can be suitably used. For the charge-generation layer, a layer containing a hole-transport material and an acceptor material (electron-accepting material) can be used. For the charge-generation layer, a layer containing an electron-transport material and a donor material can be used. Forming the charge-generation layer including such a layer can inhibit an increase in the driving voltage that would be caused by stacking light-emitting units.

The fifth layer 113d and the sixth layer 113e each include an active layer. The fifth layer 113d and the sixth layer 113e may include active layers having the same structure or active layers having different structures. For example, with the light-receiving devices having a microcavity structure, the fifth layer 113d and the sixth layer 113e can detect light with different wavelengths even when the active layers have the same structure. Note that the microcavity structures can be formed by making the thicknesses of the pixel electrodes or the thicknesses of optical adjustment layers different between the light-receiving devices 150d and 150e. In that case, the fifth layer 113d and the sixth layer 113e can have the same structure in some cases.

The active layer contains a semiconductor. Examples of the semiconductor include an inorganic semiconductor such as silicon and an organic semiconductor including an organic compound. This embodiment shows an example in which an organic semiconductor is used as the semiconductor contained in the active layer. An organic semiconductor is preferably used, in which case the light-emitting layer and the active layer can be formed by the same method (e.g., a vacuum evaporation method) and thus the same manufacturing equipment can be used.

Examples of an n-type semiconductor material included in the active layer are electron-accepting organic semiconductor materials such as fullerene (e.g., C₆₀ fullerene and C₇₀ fullerene) and fullerene derivatives. Fullerene has a soccer ball-like shape, which is energetically stable. Both the HOMO level and the LUMO level of fullerene are deep (low). Having a deep LUMO level, fullerene has an extremely high electron-accepting property (acceptor property). In general, when n-electron conjugation (resonance) spreads in a plane as in benzene, an electron-donating property (donor property) becomes high; however, since fullerene has a spherical shape, fullerene has a high electron-accepting property even when π-electrons widely spread. The high electron-accepting property efficiently causes rapid charge separation and is useful for a light-receiving device. Both C₆₀ fullerene and C₇₀ fullerene have a wide absorption band in the visible light region, and C₇₀ is especially preferable because of having a larger π-electron conjugated system and a wider absorption band in the long wavelength region than C₆₀. Other examples of fullerene derivatives include [6,6]-Phenyl-C₇₁-butyric acid methyl ester (abbreviation: PC₇₀BM), [6,6]-Phenyl-C₆₁-butyric acid methyl ester (abbreviation: PC₆₀BM), and 1′,1″,4′,4″-Tetrahydro-di[1,4]methanonaphthaleno[1,2:2′,3′,56,60:2″,3″][5,6]fullerene-C₆₀ (abbreviation: ICBA).

Other examples of an n-type semiconductor material include a metal complex having a quinoline skeleton, a metal complex having a benzoquinoline skeleton, a metal complex having an oxazole skeleton, a metal complex having a thiazole skeleton, an oxadiazole derivative, a triazole derivative, an imidazole derivative, an oxazole derivative, a thiazole derivative, a phenanthroline derivative, a quinoline derivative, a benzoquinoline derivative, a quinoxaline derivative, a dibenzoquinoxaline derivative, a pyridine derivative, a bipyridine derivative, a pyrimidine derivative, a naphthalene derivative, an anthracene derivative, a coumarin derivative, a rhodamine derivative, a triazine derivative, and a quinone derivative.

Examples of a p-type semiconductor material contained in the active layer include electron-donating organic semiconductor materials such as copper(II) phthalocyanine (CuPc), tetraphenyldibenzoperiflanthene (DBP), zinc phthalocyanine (ZnPc), tin (II) phthalocyanine (SnPc), and quinacridone.

Examples of a p-type semiconductor material include a carbazole derivative, a thiophene derivative, a furan derivative, and a compound having an aromatic amine skeleton. Other examples of the p-type semiconductor material include a naphthalene derivative, an anthracene derivative, a pyrene derivative, a triphenylene derivative, a fluorene derivative, a pyrrole derivative, a benzofuran derivative, a benzothiophene derivative, an indole derivative, a dibenzofuran derivative, a dibenzothiophene derivative, an indolocarbazole derivative, a porphyrin derivative, a phthalocyanine derivative, a naphthalocyanine derivative, a quinacridone derivative, a polyphenylene vinylene derivative, a polyparaphenylene derivative, a polyfluorene derivative, a polyvinylcarbazole derivative, and a polythiophene derivative.

The HOMO level of the electron-donating organic semiconductor material is preferably shallower (higher) than the HOMO level of the electron-accepting organic semiconductor material. The LUMO level of the electron-donating organic semiconductor material is preferably shallower (higher) than the LUMO level of the electron-accepting organic semiconductor material.

Fullerene having a spherical shape is preferably used as the electron-accepting organic semiconductor material, and an organic semiconductor material having a substantially planar shape is preferably used as the electron-donating organic semiconductor material. Molecules of similar shapes tend to aggregate, and aggregated molecules of the same kind, which have molecular orbital energy levels close to each other, can improve a carrier-transport property.

For example, the active layer is preferably formed by co-evaporation of an n-type semiconductor and a p-type semiconductor. Alternatively, the active layer may be formed by stacking an n-type semiconductor and a p-type semiconductor.

In addition to the active layer, each of the fifth layer 113d and the sixth layer 113e may further include a layer containing any of a substance with a high hole-transport property, a substance with a high electron-transport property, a substance with a bipolar property (a substance with a high electron-transport property and a high hole-transport property), and the like. Each of the fifth layer 113d and the sixth layer 113e may include a variety of functional layers that can be used in the first layer 113a, the second layer 113b, and the third layer 113c.

Either a low molecular compound or a high molecular compound can be used in the light-receiving device, and an inorganic compound may also be included. Each layer included in the light-receiving device can be formed by an evaporation method (including a vacuum evaporation method), a transfer method, a printing method, an ink-jet method, a coating method, or the like.

As the hole-transport material, a high molecular compound such as poly(3,4-ethylenedioxythiophene)/poly(styrenesulfonic acid) (PEDOT/PSS), or an inorganic compound such as molybdenum oxide or copper iodide (CuI) can be used, for example. As the electron-transport material, an inorganic compound such as zinc oxide (ZnO) can be used.

For the active layer, a high molecular compound such as Poly[[4,8-bis[5-(2-ethylhexyl)-2-thienyl]benzo[1,2-b: 4,5-b′]dithiophene-2,6-diyl]-2,5-thiophenediyl[5,7-bis(2-ethylhexyl)-4,8-dioxo-4H,8H-benzo[1,2-c:4,5-c′]dithiophene-1,3-diyl]] polymer (abbreviation: PBDB-T) or a PBDB-T derivative, which functions as a donor, can be used. For example, a method in which an acceptor material is dispersed to PBDB-T or a PBDB-T derivative can be used.

The active layer may contain a mixture of three or more kinds of materials. For example, a third material may be mixed with an n-type semiconductor material and a p-type semiconductor material in order to extend the absorption wavelength range. The third material may be a low molecular compound or a high molecular compound.

Thin films that form the display apparatus (insulating films, semiconductor films, conductive films, and the like) can be formed by a sputtering method, a CVD method, a vacuum evaporation method, a PLD method, an ALD method, or the like. Examples of the CVD method include a plasma enhanced chemical vapor deposition (PECVD: Plasma Enhanced CVD) method and a thermal CVD method. As an example of the thermal CVD method, a metal organic chemical vapor deposition (MOCVD: Metal Organic CVD) method can be given.

The thin films that form the display apparatus (insulating films, semiconductor films, conductive films, and the like) can be formed by a method such as spin coating, dipping, spray coating, ink-jetting, dispensing, screen printing, offset printing, a doctor knife, slit coating, roll coating, curtain coating, or knife coating.

For fabrication of the light-emitting devices, a vacuum process such as an evaporation method or a solution process such as a spin coating method or an ink-jet method can be especially used. As examples of the evaporation method, a physical vapor deposition method (PVD method) such as a sputtering method, an ion plating method, an ion beam evaporation method, a molecular beam evaporation method, or a vacuum evaporation method, a chemical vapor deposition method (CVD method), and the like can be given. Specifically, the functional layers (e.g., the hole-injection layer, the hole-transport layer, the light-emitting layer, the electron-transport layer, and the electron-injection layer) included in the EL layers can be formed by an evaporation method (e.g., a vacuum evaporation method), a coating method (e.g., a dip coating method, a die coating method, a bar coating method, a spin coating method, or a spray coating method), a printing method (e.g., an ink-jet method, a screen printing (stencil) method, an offset printing (planography) method, a flexography (relief printing) method, a gravure printing method, or a micro-contact printing method), or the like.

The thin films included in the display apparatus can be processed by a photolithography method or the like. Alternatively, a nanoimprinting method, a sandblasting method, a lift-off method, or the like may be used for the processing of the thin films. Island-shaped thin films may be directly formed by a film formation method using a shielding mask such as a metal mask.

There are the following two typical examples of a photolithography method. In one of the methods, a resist mask is formed over a thin film that is to be processed, the thin film is processed by etching or the like, and the resist mask is removed. In the other method, after a photosensitive thin film is formed, light exposure and development are performed, so that the thin film is processed into a desired shape.

As the light used for light exposure in the photolithography method, for example, an i-line (with a wavelength of 365 nm), a g-line (with a wavelength of 436 nm), an h-line (with a wavelength of 405 nm), or combined light of any of them can be used. Besides, ultraviolet light, KrF laser light, ArF laser light, or the like can be used. Light exposure may be performed by liquid immersion light exposure technique. As the light used for the light exposure, extreme ultraviolet (EUV) light or X-rays may be used. Furthermore, instead of the light used for the light exposure, an electron beam can also be used. EUV light, X-rays, or an electron beam is preferably used to enable extremely minute processing. Note that in the case of performing light exposure by scanning of a beam such as an electron beam, a photomask is not needed.

For etching of the thin film, a dry etching method, a wet etching method, a sandblasting method, or the like can be used.

As described above, in the display apparatus of one embodiment of the present invention, an island-shaped EL layer is formed by processing an EL layer formed over the entire surface, not by using a fine metal mask; thus, the island-shaped EL layer can be formed to have a uniform thickness. Furthermore, a high-resolution display apparatus or a display apparatus with a high aperture ratio, which has been difficult to obtain, can be obtained. Moreover, a high-resolution display apparatus or a display apparatus with a high aperture ratio, which incorporates a light-receiving device and has a light detection function, can be obtained.

The first layer, the second layer, and the third layer included in the light-emitting devices of different colors are formed in separate steps. Accordingly, the EL layers can be formed to have structures (material, thickness, and the like) appropriate for the light-emitting devices of the respective colors. Thus, the light-emitting devices can have favorable characteristics.

This embodiment can be combined with the other embodiments as appropriate.

### Embodiment 3

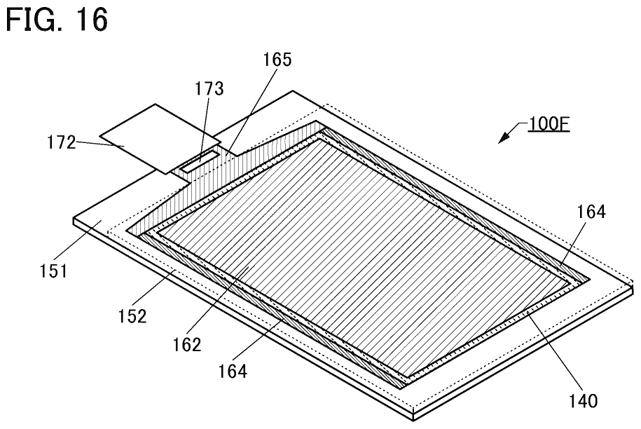

In this embodiment, the display apparatus of one embodiment of the present invention will be described with reference to FIG. 16 to FIG. 18.

The display apparatus in this embodiment can be a high-definition display apparatus or a large-sized display apparatus. Accordingly, the display apparatus of this embodiment can be used for display portions of a digital camera, a digital video camera, a digital photo frame, a mobile phone, a portable game console, a portable information terminal, and an audio reproducing device, in addition to display portions of electronic devices with a relatively large screen, such as a television device, a desktop or notebook personal computer, a monitor of a computer or the like, digital signage, and a large game machine such as a pachinko machine.

### [Display Apparatus 100F]

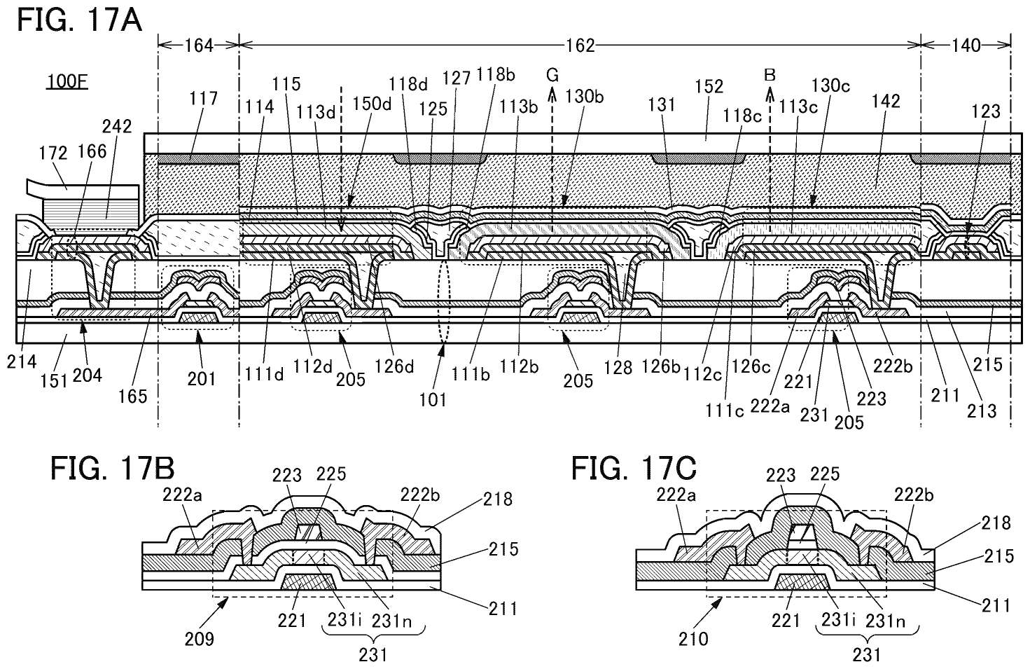

FIG. 16 is a perspective view of a display apparatus 100F, and FIG. 17A is a cross-sectional view of the display apparatus 100F.

The display apparatus 100F has a structure where a substrate 152 and a substrate 151 are bonded to each other. In FIG. 16, the substrate 152 is denoted by a dashed line.

The display apparatus 100F includes a display portion 162, the connection portion 140, a circuit 164, a wiring 165, and the like. FIG. 16 illustrates an example in which an IC 173 and an FPC 172 are mounted on the display apparatus 100F. Thus, the structure illustrated in FIG. 16 can be regarded as a display module including the display apparatus 100F, the IC (integrated circuit), and the FPC.

The connection portion 140 is provided outside the display portion 162. The connection portion 140 can be provided along one or more sides of the display portion 162. The number of connection portions 140 can be one or more. FIG. 16 illustrates an example where the connection portion 140 is provided to surround the four sides of the display portion. A common electrode of a light-emitting device is electrically connected to a conductive layer in the connection portion 140, so that a potential can be supplied to the common electrode.

As the circuit 164, a scan line driver circuit can be used, for example.

The wiring 165 has a function of supplying a signal and power to the display portion 162 and the circuit 164. The signal and power are input to the wiring 165 from the outside through the FPC 172 or input to the wiring 165 from the IC 173.

FIG. 16 illustrates an example in which the IC 173 is provided over the substrate 151 by a COG (Chip On Glass) method, a COF (Chip On Film) method, or the like. An IC including a scan line driver circuit, a signal line driver circuit, or the like can be used as the IC 173, for example. Note that the display apparatus 100F and the display module are not necessarily provided with an IC. The IC may be mounted on the FPC by a COF method or the like.

FIG. 17A illustrates an example of cross sections of part of a region including the FPC 172, part of the circuit 164, part of the display portion 162, part of the connection portion 140, and part of a region including an end portion in the display apparatus 100F.

The display apparatus 100F illustrated in FIG. 17A includes a transistor 201, a transistor 205, the light-receiving device 150d, the light-emitting device 130b which emits green light, the light-emitting device 130c which emits blue light, and the like between the substrate 151 and the substrate 152.

The display apparatus 100F can employ any of the pixel layouts illustrated in FIG. 2A to FIG. 2G, FIG. 3A and FIG. 3B, and FIG. 5A to FIG. 5D that are described in Embodiment 1, for example. The light-receiving device 150d can be provided in the subpixel PS or the subpixel IRS.

The light-receiving device 150d includes the conductive layer 111d, a conductive layer 112d over the conductive layer 111d, and a conductive layer 126d over the conductive layer 112d. All of the conductive layers 111d, 112d, and 126d can be referred to as the pixel electrode, or one or two of them can be referred to as the pixel electrode.

The conductive layer 111d is connected to a conductive layer 222b included in the transistor 205 through an opening provided in an insulating layer 214. The end portion of the conductive layer 112d is positioned outward from the end portion of the conductive layer 111d. The end portion of the conductive layer 112d and the end portion of the conductive layer 126d are aligned or substantially aligned with each other. For example, a conductive layer functioning as a reflective electrode can be used as the conductive layer 111d and the conductive layer 112d, and a conductive layer functioning as a transparent electrode can be used as the conductive layer 126d.

The light-emitting device 130b includes the conductive layer 111b, a conductive layer 112b over the conductive layer 111b, and a conductive layer 126b over the conductive layer 112b. The light-emitting device 130c includes a conductive layer 111c, a conductive layer 112c over the conductive layer 111c, and a conductive layer 126c over the conductive layer 112c.

Detailed description of the conductive layers 111b, 112b, and 126b of the light-emitting device 130b and the conductive layers 111c, 112c, and 126c of the light-emitting device 130c is omitted because these conductive layers are similar to the conductive layers 111d, 112d, and 126d of the light-receiving device 150d.

Depressed portions are formed on the conductive layers 111b, 111c, and 111d to cover the openings provided in the insulating layer 214. A layer 128 is embedded in each of the depressed portions.

The layer 128 has a function of enabling planarization in the depressed portions on the conductive layers 111b, 111c, and 111d. The conductive layers 112b, 112c, and 112d electrically connected to the conductive layers 111b, 111c, and 111d, respectively, are provided over the conductive layers 111b, 111c, and 111d and the layer 128. Thus, regions overlapping with the depressed portions on the conductive layers 111b, 111c, and 111d can also be used as the light-emitting regions, increasing the aperture ratio of the pixel.

The layer 128 may be an insulating layer or a conductive layer. Any of a variety of inorganic insulating materials, organic insulating materials, and conductive materials can be used for the layer 128 as appropriate. In particular, the layer 128 is preferably formed using an insulating material.

An insulating layer containing an organic material can be suitably used as the layer 128. For the layer 128, an acrylic resin, a polyimide resin, an epoxy resin, a polyamide resin, a polyimide-amide resin, a siloxane resin, a benzocyclobutene-based resin, a phenol resin, a precursor of any of these resins, or the like can be used, for example. A photosensitive resin can also be used for the layer 128. As the photosensitive resin, a positive photosensitive material or a negative photosensitive material can be used.

When a photosensitive resin is used, the layer 128 can be formed through only light-exposure and development steps, reducing the influence of dry etching, wet etching, or the like on the surfaces of the conductive layers 111b, 111c, and 111d. When the layer 128 is formed using a negative photosensitive resin, the layer 128 can sometimes be formed using the same photomask (light-exposure mask) as the photomask used for forming the opening in the insulating layer 214.

The top surface and the side surface of the conductive layer 112d and the top surface and the side surface of the conductive layer 126d are covered with the fifth layer 113d. The fifth layer 113d includes at least an active layer.

Similarly, the top surface and the side surface of the conductive layer 112b and the top surface and the side surface of the conductive layer 126b are covered with the second layer 113b. Moreover, the top surface and the side surface of the conductive layer 112c and the top surface and the side surface of the conductive layer 126c are covered with the third layer 113c. Accordingly, regions provided with the conductive layers 112b and 112c can be entirely used as the light-emitting regions of the light-emitting devices 130b and 130c, increasing the aperture ratio of the pixel.

The side surfaces of the second layer 113b, the third layer 113c, and the fifth layer 113d are covered with the insulating layers 125 and 127. The sacrificial layer 118b is positioned between the second layer 113b and the insulating layer 125. A sacrificial layer 118c is positioned between the third layer 113c and the insulating layer 125, and a sacrificial layer 118d is positioned between the fifth layer 113d and the insulating layer 125. The fourth layer 114 is provided over the second layer 113b, the third layer 113c, the fifth layer 113d, and the insulating layers 125 and 127, and the common electrode 115 is provided over the fourth layer 114. The fourth layer 114 and the common electrode 115 are each one continuous film shared by the light-receiving device and the light-emitting devices. The protective layer 131 is provided over the light-emitting devices 130b and 130c and the light-receiving device 150d.

The protective layer 131 and the substrate 152 are bonded to each other with an adhesive layer 142. A solid sealing structure, a hollow sealing structure, or the like can be employed to seal the light-emitting devices. In FIG. 17A, a solid sealing structure is employed in which a space between the substrate 152 and the substrate 151 is filled with the adhesive layer 142. Alternatively, a hollow sealing structure in which the space is filled with an inert gas (e.g., nitrogen or argon) may be employed. The adhesive layer 142 may be provided not to overlap with the light-emitting device. The space may be filled with a resin different from that of the frame-like adhesive layer 142.

The conductive layer 123 is provided over the insulating layer 214 in the connection portion 140. An example is described in which the conductive layer 123 has a stacked-layer structure of a conductive film obtained by processing the same conductive film as the conductive layers 111b, 111c, and 111d; a conductive film obtained by processing the same conductive film as the conductive layers 112b, 112c, and 112d; and a conductive film obtained by processing the same conductive film as the conductive layers 126b, 126c, and 126d. The end portion of the conductive layer 123 is covered with the sacrificial layer, the insulating layer 125, and the insulating layer 127. The fourth layer 114 is provided over the conductive layer 123, and the common electrode 115 is provided over the fourth layer 114. The conductive layer 123 and the common electrode 115 are electrically connected to each other through the fourth layer 114. Note that a structure in which the fourth layer 114 is not formed in the connection portion 140 may be employed. In that case, the conductive layer 123 and the common electrode 115 are in direct contact with each other to be electrically connected to each other.

The display apparatus 100F is of a top-emission type. Light from the light-emitting device is emitted toward the substrate 152 side. For the substrate 152, a material having a high visible-light-transmitting property is preferably used. The pixel electrode contains a material that reflects visible light, and a counter electrode (the common electrode 115) contains a material that transmits visible light.

A stacked-layer structure including the substrate 151 and the components thereover up to the insulating layer 214 corresponds to the layer 101 including transistors in Embodiment 1.

The transistor 201 and the transistor 205 are formed over the substrate 151. These transistors can be fabricated using the same material in the same step.

An insulating layer 211, an insulating layer 213, an insulating layer 215, and the insulating layer 214 are provided in this order over the substrate 151. Part of the insulating layer 211 functions as a gate insulating layer of each transistor. Part of the insulating layer 213 functions as a gate insulating layer of each transistor. The insulating layer 215 is provided to cover the transistors. The insulating layer 214 is provided to cover the transistors and has a function of a planarization layer. Note that the number of gate insulating layers and the number of insulating layers covering the transistors are not limited and may each be one or two or more.

A material that does not easily allow diffusion of impurities such as water and hydrogen is preferably used for at least one of the insulating layers covering the transistors. In that case, the insulating layer can function as a barrier layer. Such a structure can effectively inhibit diffusion of impurities into the transistors from the outside and increase the reliability of the display apparatus.

An inorganic insulating film is preferably used as each of the insulating layer 211, the insulating layer 213, and the insulating layer 215. As the inorganic insulating film, a silicon nitride film, a silicon oxynitride film, a silicon oxide film, a silicon nitride oxide film, an aluminum oxide film, or an aluminum nitride film can be used, for example. A hafnium oxide film, an yttrium oxide film, a zirconium oxide film, a gallium oxide film, a tantalum oxide film, a magnesium oxide film, a lanthanum oxide film, a cerium oxide film, a neodymium oxide film, or the like may be used. A stack including two or more of the above insulating films may also be used.

An organic insulating film is suitable for the insulating layer 214 functioning as the planarization layer. Examples of materials that can be used for the organic insulating film include an acrylic resin, a polyimide resin, an epoxy resin, a polyamide resin, a polyimide-amide resin, a siloxane resin, a benzocyclobutene-based resin, a phenol resin, and precursors of these resins. The insulating layer 214 may have a stacked-layer structure of an organic insulating film and an inorganic insulating film. The outermost layer of the insulating layer 214 preferably functions as an etching protective film. In that case, the formation of a depressed portion in the insulating layer 214 can be inhibited in processing of the conductive layer 111b, the conductive layer 112b, the conductive layer 126b, or the like. Alternatively, a depressed portion may be formed in the insulating layer 214 in processing of the conductive layer 111b, the conductive layer 112b, the conductive layer 126b, or the like.

Each of the transistor 201 and the transistor 205 includes a conductive layer 221 functioning as a gate, the insulating layer 211 functioning as a gate insulating layer, a conductive layer 222a and the conductive layer 222b functioning as a source and a drain, a semiconductor layer 231, the insulating layer 213 functioning as a gate insulating layer, and a conductive layer 223 functioning as a gate. Here, a plurality of layers obtained by processing the same conductive film are shown with the same hatching pattern. The insulating layer 211 is positioned between the conductive layer 221 and the semiconductor layer 231. The insulating layer 213 is positioned between the conductive layer 223 and the semiconductor layer 231.

There is no particular limitation on the structure of the transistors included in the display apparatus of this embodiment. For example, a planar transistor, a staggered transistor, or an inverted staggered transistor can be used. Either of a top-gate transistor structure and a bottom-gate transistor structure may be used. Alternatively, gates may be provided above and below a semiconductor layer where a channel is formed.

The structure in which the semiconductor layer where a channel is formed is provided between two gates is used for the transistor 201 and the transistor 205. The two gates may be connected to each other and supplied with the same signal to operate the transistor. Alternatively, the threshold voltage of the transistor may be controlled by applying a potential for controlling the threshold voltage to one of the two gates and a potential for driving to the other of the two gates.

There is no particular limitation on the crystallinity of a semiconductor material used for the transistors, and any of an amorphous semiconductor, a single crystal semiconductor, and a semiconductor having crystallinity other than single crystal (a microcrystalline semiconductor, a polycrystalline semiconductor, or a semiconductor partly including crystal regions) may be used. It is preferable to use a single crystal semiconductor or a semiconductor having crystallinity, in which case deterioration of the transistor characteristics can be inhibited.

It is preferable that the semiconductor layer of the transistor contain a metal oxide (also referred to as an oxide semiconductor). That is, a transistor including a metal oxide in its channel formation region (hereinafter, an OS transistor) is preferably used for the display apparatus of this embodiment. Alternatively, the semiconductor layer of the transistor may contain silicon. Examples of silicon include amorphous silicon and crystalline silicon (e.g., low-temperature polysilicon or single crystal silicon).

The semiconductor layer preferably contains indium, M (Mis one or more kinds selected from gallium, aluminum, silicon, boron, yttrium, tin, copper, vanadium, beryllium, titanium, iron, nickel, germanium, zirconium, molybdenum, lanthanum, cerium, neodymium, hafnium, tantalum, tungsten, and magnesium), and zinc, for example. Specifically, M is preferably one or more kinds selected from aluminum, gallium, yttrium, and tin.

It is particularly preferable that an oxide containing indium (In), gallium (Ga), and zinc (Zn) (also referred to as IGZO) be used for the semiconductor layer. Alternatively, it is preferable to use an oxide containing indium, tin, and zinc. Further alternatively, it is preferable to use an oxide containing indium, gallium, tin, and zinc.

When the semiconductor layer is an In-M-Zn oxide, the atomic ratio of In is preferably greater than or equal to the atomic ratio ofMin the In-M-Zn oxide. Examples of the atomic ratio of the metal elements in such an In-M-Zn oxide include In:M:Zn=1:1:1 or a composition in the neighborhood thereof, In:M:Zn=1:1:1.2 or a composition in the neighborhood thereof, In:M:Zn=2:1:3 or a composition in the neighborhood thereof, In:M:Zn=3:1:2 or a composition in the neighborhood thereof, In:M:Zn=4:2:3 or a composition in the neighborhood thereof, In:M:Zn=4:2:4.1 or a composition in the neighborhood thereof, In:M:Zn=5:1:3 or a composition in the neighborhood thereof, In:M:Zn=5:1:6 or a composition in the neighborhood thereof, In:M:Zn=5:1:7 or a composition in the neighborhood thereof, In:M:Zn=5:1:8 or a composition in the neighborhood thereof, In:M:Zn=6:1:6 or a composition in the neighborhood thereof, and In:M:Zn=5:2:5 or a composition in the neighborhood thereof. Note that a composition in the neighborhood includes the range of ±30% of an intended atomic ratio.

For example, when the atomic ratio is described as In:Ga:Zn=4:2:3 or a composition in the neighborhood thereof, the case is included where Ga is greater than or equal to 1 and less than or equal to 3 and Zn is greater than or equal to 2 and less than or equal to 4 with In being 4. When the atomic ratio is described as In:Ga:Zn=5:1:6 or a composition in the neighborhood thereof, the case is included where Ga is greater than 0.1 and less than or equal to 2 and Zn is greater than or equal to 5 and less than or equal to 7 with In being 5. When the atomic ratio is described as In:Ga:Zn=1:1:1 or a composition in the neighborhood thereof, the case is included where Ga is greater than 0.1 and less than or equal to 2 and Zn is greater than 0.1 and less than or equal to 2 with In being 1.

The transistor included in the circuit 164 and the transistor included in the display portion 162 may have the same structure or different structures. One structure or two or more kinds of structures may be employed for a plurality of transistors included in the circuit 164. Similarly, one structure or two or more kinds of structures may be employed for a plurality of transistors included in the display portion 162.

FIG. 17B and FIG. 17C illustrate other structure examples of transistors.

A transistor 209 and a transistor 210 each include the conductive layer 221 functioning as a gate, the insulating layer 211 functioning as a gate insulating layer, the semiconductor layer 231 including a channel formation region 231i and a pair of low-resistance regions 231n, the conductive layer 222a connected to one of the low-resistance regions 231n, the conductive layer 222b connected to the other low-resistance region 231n, an insulating layer 225 functioning as a gate insulating layer, the conductive layer 223 functioning as a gate, and the insulating layer 215 covering the conductive layer 223. The insulating layer 211 is positioned between the conductive layer 221 and the channel formation region 231i. The insulating layer 225 is positioned at least between the conductive layer 223 and the channel formation region 231i. Furthermore, an insulating layer 218 covering the transistor may be provided.

FIG. 17B illustrates an example of the transistor 209 in which the insulating layer 225 covers the top surface and the side surface of the semiconductor layer 231. The conductive layer 222a and the conductive layer 222b are connected to the low-resistance regions 231n through openings provided in the insulating layer 225 and the insulating layer 215. One of the conductive layer 222a and the conductive layer 222b functions as a source, and the other functions as a drain.

In the transistor 210 illustrated in FIG. 17C, the insulating layer 225 overlaps with the channel formation region 231i of the semiconductor layer 231 and does not overlap with the low-resistance regions 231n. The structure illustrated in FIG. 17C is obtained by processing the insulating layer 225 with the conductive layer 223 as a mask, for example. In FIG. 17C, the insulating layer 215 is provided to cover the insulating layer 225 and the conductive layer 223, and the conductive layer 222a and the conductive layer 222b are connected to the low-resistance regions 231n through the openings in the insulating layer 215.

A connection portion 204 is provided in a region of the substrate 151 where the substrate 152 does not overlap. In the connection portion 204, the wiring 165 is electrically connected to the FPC 172 through a conductive layer 166 and a connection layer 242. An example is described in which the conductive layer 166 has a stacked-layer structure of a conductive film obtained by processing the same conductive film as the conductive layers 111b, 111c, and 111d; a conductive film obtained by processing the same conductive film as the conductive layers 112b, 112c, and 112d; and a conductive film obtained by processing the same conductive film as the conductive layers 126b, 126c, and 126d. On the top surface of the connection portion 204, the conductive layer 166 is exposed. Thus, the connection portion 204 and the FPC 172 can be electrically connected to each other through the connection layer 242.

A light-blocking layer 117 is preferably provided on the surface of the substrate 152 on the substrate 151 side. The light-blocking layer 117 can be provided between adjacent light-emitting devices, in the connection portion 140, and in the circuit 164, for example. Any of a variety of optical members can be arranged on the outer surface of the substrate 152. Examples of the optical members include a polarizing plate, a retardation plate, a light diffusion layer (e.g., a diffusion film), an anti-reflective layer, and a light-condensing film. Furthermore, an antistatic film inhibiting the attachment of dust, a water repellent film suppressing the attachment of stain, a hard coat film inhibiting generation of a scratch caused by the use, an impact-absorbing layer, or the like may be arranged on the outer surface of the substrate 152.

The protective layer 131 provided to cover the light-emitting devices and the light-receiving device can inhibit an impurity such as water from entering the light-emitting devices and the light-receiving device, and increase the reliability of the light-emitting devices and the light-receiving device.

The materials that can be used for the substrate 120 given as examples in Embodiment 2 can be used for each of the substrate 151 and the substrate 152. The substrate on the side from which light from the light-emitting device is extracted is formed using a material that transmits the light. When the substrate 151 and the substrate 152 are formed using a flexible material, the flexibility of the display apparatus can be increased. Furthermore, a polarizing plate may be used as the substrate 151 or the substrate 152.

The materials that can be used for the resin layer 122 given as examples in Embodiment 2 can be used for the adhesive layer 142.

For the connection layer 242, an anisotropic conductive film (ACF), an anisotropic conductive paste (ACP), or the like can be used.

### [Display Apparatus 100G]

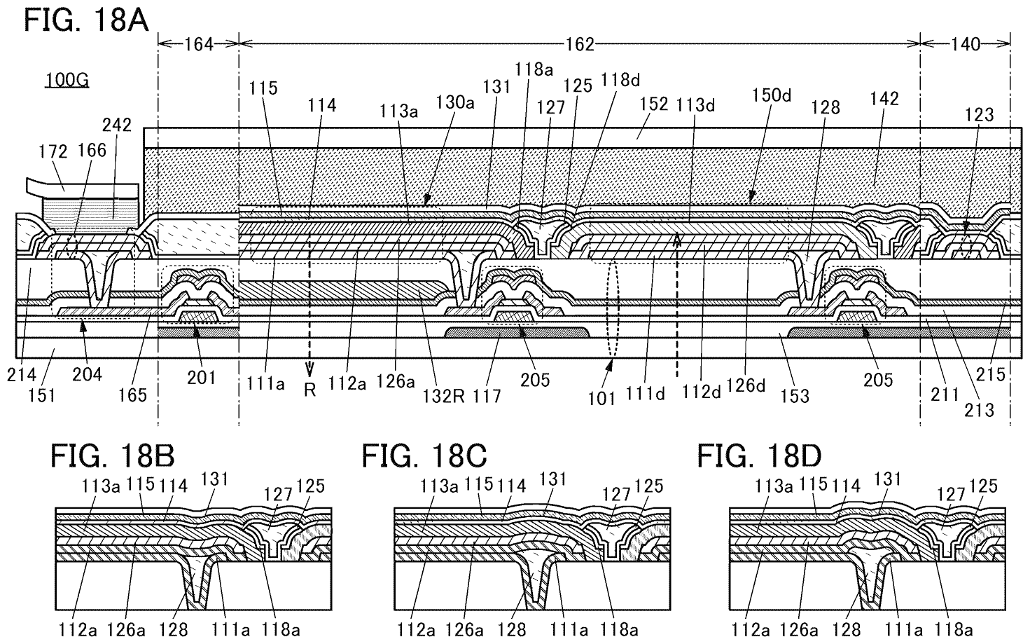

A display apparatus 100G illustrated in FIG. 18A is different from the display apparatus 100F mainly in that the display apparatus 100G is a bottom-emission display apparatus in which a white-light-emitting device and a color filter are combined. Note that in the description of the display apparatus below, portions similar to those of the above-mentioned display apparatus are not described in some cases.

Light from the light-emitting device is emitted toward the substrate 151 side. Light enters the light-receiving device from the substrate 151 side. For the substrate 151, a material having a high visible-light-transmitting property is preferably used. By contrast, there is no limitation on the light-transmitting property of a material used for the substrate 152.

The light-blocking layer 117 is preferably formed between the substrate 151 and the transistor 201 and between the substrate 151 and the transistor 205. FIG. 18A illustrates an example where the light-blocking layer 117 is provided over the substrate 151, an insulating layer 153 is provided over the light-blocking layer 117, and the transistors 201 and 205 and the like are provided over the insulating layer 153.

The light-emitting device 130a and a coloring layer 132R overlap with each other, and light emitted from the light-emitting device 130a passes through the red coloring layer 132R and is extracted as red light to the outside of the display apparatus 100G.

The light-emitting device 130a includes the conductive layer 111a, a conductive layer 112a over the conductive layer 111a, and a conductive layer 126a over the conductive layer 112a.

The light-receiving device 150d includes the conductive layer 111d, the conductive layer 112d over the conductive layer 111d, and the conductive layer 126d over the conductive layer 112d.

A material having a high visible-light-transmitting property is used for each of the conductive layers 111a, 111d, 112a, 112d, 126a, and 126d. A material that reflects visible light is preferably used for the common electrode 115.

The top surface and the side surface of the conductive layer 112a and the top surface and the side surface of the conductive layer 126a are covered with the first layer 113a. The side surface of the first layer 113a is covered with the insulating layers 125 and 127. The sacrificial layer 118a is positioned between the first layer 113a and the insulating layer 125. The fourth layer 114 is provided over the first layer 113a, the fifth layer 113d, and the insulating layers 125 and 127, and the common electrode 115 is provided over the fourth layer 114. The fourth layer 114 and the common electrode 115 are each one continuous film shared by the light-receiving device and the light-emitting devices. The protective layer 131 is provided over the light-emitting device 130a and the light-receiving device 150d.

Each of the light-emitting devices included in the subpixels of respective colors can emit white light. FIG. 18A illustrates the first layer 113a having three layers; specifically, a stacked-layer structure of a first light-emitting unit, a charge-generation layer, and a second light-emitting unit can be employed.

Although FIG. 17A, FIG. 18A, and the like illustrate an example where the top surface of the layer 128 includes a flat portion, the shape of the layer 128 is not particularly limited. FIG. 18B to FIG. 18D illustrate variation examples of the layer 128.

As shown in FIG. 18B and FIG. 18D, the top surface of the layer 128 can have a shape in which its center and the vicinity thereof are depressed, i.e., a shape including a concave surface, in a cross-sectional view.

As shown in FIG. 18C, the top surface of the layer 128 can have a shape in which its center and the vicinity thereof bulge, i.e., a shape including a convex surface, in a cross-sectional view.

The top surface of the layer 128 may include one or both of a convex surface and a concave surface. The number of convex surfaces and the number of concave surfaces included in the top surface of the layer 128 are not limited and can each be one or more.

The level of the top surface of the layer 128 and the level of the top surface of the conductive layer 111a may be the same or substantially the same, or may be different from each other. For example, the level of the top surface of the layer 128 may be either lower or higher than the level of the top surface of the conductive layer 111a.

FIG. 18B can be regarded as illustrating an example in which the layer 128 fits in the depressed portion formed on the conductive layer 111a. By contrast, as shown in FIG. 18D, the layer 128 may exist outside the depressed portion formed on the conductive layer 111a, that is, the layer 128 may be formed to have a top surface wider than the depressed portion.

This embodiment can be combined with the other embodiments as appropriate.

### Embodiment 4

In this embodiment, a light-emitting device that can be used in the display device of one embodiment of the present invention will be described.

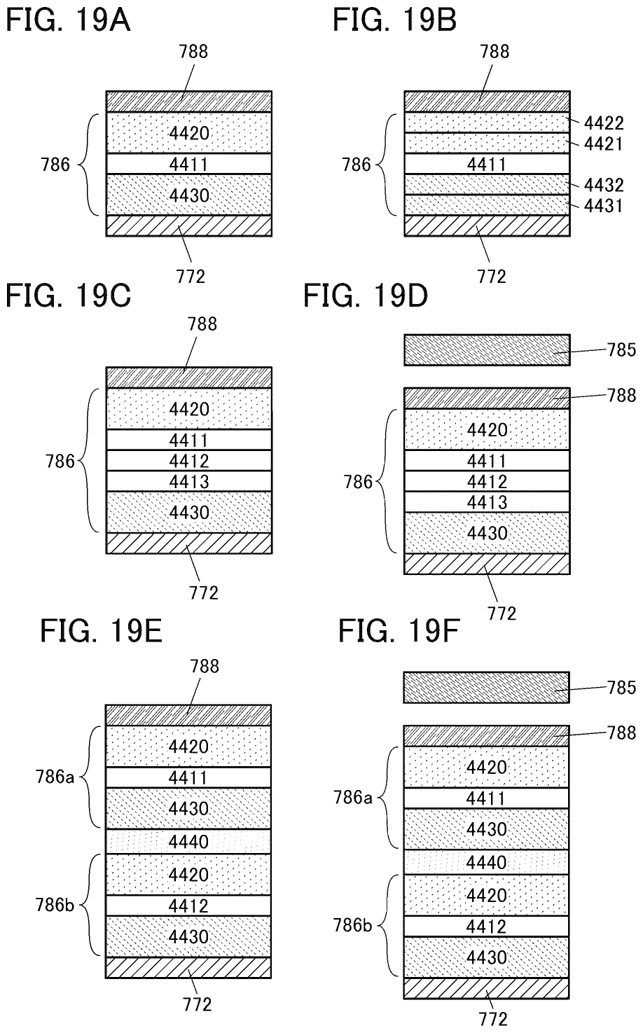

As illustrated in FIG. 19A, the light-emitting device includes an EL layer 786 between a pair of electrodes (a lower electrode 772 and an upper electrode 788). The EL layer 786 can be formed of a plurality of layers such as a layer 4420, a light-emitting layer 4411, and a layer 4430. The layer 4420 can include, for example, a layer containing a substance with a high electron-injection property (an electron-injection layer) and a layer containing a substance with a high electron-transport property (an electron-transport layer). The light-emitting layer 4411 contains a light-emitting compound, for example. The layer 4430 can include, for example, a layer containing a substance with a high hole-injection property (a hole-injection layer) and a layer containing a substance with a high hole-transport property (a hole-transport layer).

The structure including the layer 4420, the light-emitting layer 4411, and the layer 4430 provided between the pair of electrodes can function as a single light-emitting unit, and the structure in FIG. 19A is referred to as a single structure in this specification.

FIG. 19B is a modification example of the EL layer 786 included in the light-emitting device illustrated in FIG. 19A. Specifically, the light-emitting device illustrated in FIG. 19B includes a layer 4431 over the lower electrode 772, a layer 4432 over the layer 4431, the light-emitting layer 4411 over the layer 4432, a layer 4421 over the light-emitting layer 4411, a layer 4422 over the layer 4421, and the upper electrode 788 over the layer 4422. When the lower electrode 772 is an anode and the upper electrode 788 is a cathode, for example, the layer 4431 functions as a hole-injection layer, the layer 4432 functions as a hole-transport layer, the layer 4421 functions as an electron-transport layer, and the layer 4422 functions as an electron-injection layer. Alternatively, when the lower electrode 772 is a cathode and the upper electrode 788 is an anode, the layer 4431 functions as an electron-injection layer, the layer 4432 functions as an electron-transport layer, the layer 4421 functions as a hole-transport layer, and the layer 4422 functions as a hole-injection layer. With such a layered structure, carriers can be efficiently injected to the light-emitting layer 4411, and the efficiency of the recombination of carriers in the light-emitting layer 4411 can be enhanced.

Note that a structure in which a plurality of light-emitting layers (light-emitting layers 4411, 4412, and 4413) are provided between the layer 4420 and the layer 4430 as illustrated in FIG. 19C or FIG. 19D is a variation of the single structure.

A structure in which a plurality of light-emitting units (an EL layer 786a and an EL layer 786b) are connected in series with a charge-generation layer 4440 therebetween as illustrated in FIG. 19E or FIG. 19F is referred to as a tandem structure in this specification. Note that a tandem structure may be referred to as a stack structure. The tandem structure enables a light-emitting device capable of high luminance light emission.

In FIG. 19C and FIG. 19D, light-emitting materials that emit light of the same color, or moreover, the same light-emitting material may be used for the light-emitting layer 4411, the light-emitting layer 4412, and the light-emitting layer 4413. For example, a light-emitting material that emits blue light may be used for the light-emitting layer 4411, the light-emitting layer 4412, and the light-emitting layer 4413. A color conversion layer may be provided as a layer 785 illustrated in FIG. 19D.

Alternatively, light-emitting materials that emit light of different colors may be used for the light-emitting layer 4411, the light-emitting layer 4412, and the light-emitting layer 4413. White light emission can be obtained when light emitted from the light-emitting layer 4411, light emitted from the light-emitting layer 4412, and light emitted from the light-emitting layer 4413 have a relationship of complementary colors. A color filter (also referred to as a coloring layer) may be provided as the layer 785 illustrated in FIG. 19D. When white light passes through a color filter, light of a desired color can be obtained.

In FIG. 19E and FIG. 19F, light-emitting materials that emit light of the same color, or moreover, the same light-emitting material may be used for the light-emitting layer 4411 and the light-emitting layer 4412. Alternatively, light-emitting materials that emit light of different colors may be used for the light-emitting layer 4411 and the light-emitting layer 4412. White light emission can be obtained when light emitted from the light-emitting layer 4411 and light emitted from the light-emitting layer 4412 have a relationship of complementary colors. FIG. 19F illustrates an example in which the layer 785 is further provided. One or both of a color conversion layer and a color filter (coloring layer) can be used as the layer 785.

Also in the structures illustrated in FIG. 19C, FIG. 19D, FIG. 19E, and FIG. 19F, the layer 4420 and the layer 4430 may each have a stacked-layer structure of two or more layers as illustrated in FIG. 19B.

A structure in which light-emitting devices of different emission colors (e.g., blue (B), green (G), and red (R)) are separately formed is referred to as an SBS (Side By Side) structure in some cases.

The emission color of the light-emitting device can be red, green, blue, cyan, magenta, yellow, white, or the like depending on the material of the EL layer 786. Furthermore, the color purity can be further increased when the light-emitting device has a microcavity structure.

A light-emitting device that emits white light preferably contains two or more kinds of light-emitting substances in its light-emitting layer. To obtain white light emission, two or more light-emitting substances are selected such that their emission colors are complementary. For example, when the emission color of a first light-emitting layer and the emission color of a second light-emitting layer are complementary colors, it is possible to obtain a light-emitting device which emits white light as a whole. The same can be applied to a light-emitting device including three or more light-emitting layers.

The light-emitting layer preferably contains two or more light-emitting substances that emit light of R (red), G (green), B (blue), Y (yellow), 0 (orange), and the like. Alternatively, the light-emitting layer preferably contains two or more light-emitting substances that emit light containing two or more of spectral components of R, G, and B.

This embodiment can be combined with the other embodiments as appropriate.

### Embodiment 5

In this embodiment, a metal oxide (also referred to as an oxide semiconductor) that can be used in the OS transistor described in the above embodiment will be described.

The metal oxide preferably contains at least indium or zinc. In particular, indium and zinc are preferably contained. In addition, aluminum, gallium, yttrium, tin, or the like is preferably contained. Furthermore, one or more kinds selected from boron, silicon, titanium, iron, nickel, germanium, zirconium, molybdenum, lanthanum, cerium, neodymium, hafnium, tantalum, tungsten, magnesium, cobalt, and the like may be contained.

The metal oxide can be formed by a sputtering method, a chemical vapor deposition (CVD) method such as a metal organic chemical vapor deposition (MOCVD) method, an atomic layer deposition (ALD) method, or the like.

### <Classification of Crystal Structure>

Amorphous (including completely amorphous), CAAC (c-axis-aligned crystalline), nc (nanocrystalline), CAC (cloud-aligned composite), single-crystal, and polycrystalline (polycrystal) structures can be given as examples of a crystal structure of an oxide semiconductor.

Note that a crystal structure of a film or a substrate can be evaluated with an X-ray diffraction (XRD) spectrum. For example, evaluation is possible using an XRD spectrum which is obtained by GIXD (Grazing-Incidence XRD) measurement. Note that a GIXD method is also referred to as a thin film method or a Seemann-Bohlin method.

For example, an XRD spectrum of a quartz glass substrate shows a peak with a substantially bilaterally symmetrical shape. On the other hand, a peak of an XRD spectrum of an IGZO film having a crystal structure has a bilaterally asymmetrical shape. The asymmetrical peak of the XRD spectrum clearly shows the existence of crystals in the film or the substrate. In other words, the crystal structure of the film or the substrate cannot be regarded as “amorphous” unless it has a bilaterally symmetrical peak in the XRD spectrum.

A crystal structure of a film or a substrate can also be evaluated with a diffraction pattern obtained by a nanobeam electron diffraction (NBED) method (such a pattern is also referred to as a nanobeam electron diffraction pattern). For example, a halo pattern is observed in the diffraction pattern of the quartz glass substrate, which indicates that the quartz glass substrate is in an amorphous state. Furthermore, not a halo pattern but a spot-like pattern is observed in a diffraction pattern of an IGZO film formed at room temperature. Thus, it is suggested that the IGZO film formed at room temperature is in an intermediate state, which is neither a crystal state nor an amorphous state, and it cannot be concluded that the IGZO film is in an amorphous state.

### <<Structure of Oxide Semiconductor>>

Oxide semiconductors might be classified in a manner different from the above-described one when classified in terms of the structure. Oxide semiconductors are classified into a single crystal oxide semiconductor and a non-single-crystal oxide semiconductor, for example. Examples of the non-single-crystal oxide semiconductor include the above-described CAAC-OS and nc-OS. Other examples of the non-single-crystal oxide semiconductor include a polycrystalline oxide semiconductor, an amorphous-like oxide semiconductor (a-like OS), and an amorphous oxide semiconductor.

Here, the above-described CAAC-OS, nc-OS, and a-like OS are described in detail.

### [CAAC-OS]

The CAAC-OS is an oxide semiconductor that has a plurality of crystal regions each of which has c-axis alignment in a particular direction. Note that the particular direction refers to the film thickness direction of a CAAC-OS film, the normal direction of the surface where the CAAC-OS film is formed, or the normal direction of the surface of the CAAC-OS film. The crystal region refers to a region having a periodic atomic arrangement. When an atomic arrangement is regarded as a lattice arrangement, the crystal region also refers to a region with a uniform lattice arrangement. The CAAC-OS has a region where a plurality of crystal regions are connected in the a-b plane direction, and the region has distortion in some cases. Note that distortion refers to a portion where the direction of a lattice arrangement changes between a region with a uniform lattice arrangement and another region with a uniform lattice arrangement in a region where a plurality of crystal regions are connected. That is, the CAAC-OS is an oxide semiconductor having c-axis alignment and having no clear alignment in the a-b plane direction.

Note that each of the plurality of crystal regions is formed of one or more fine crystals (crystals each of which has a maximum diameter of less than 10 nm). In the case where the crystal region is formed of one fine crystal, the maximum diameter of the crystal region is less than 10 nm. In the case where the crystal region is formed of a large number of fine crystals, the size of the crystal region may be approximately several tens of nanometers.

In the case of an In-M-Zn oxide (the element M is one or more kinds selected from aluminum, gallium, yttrium, tin, titanium, and the like), the CAAC-OS tends to have a layered crystal structure (also referred to as a layered structure) in which a layer containing indium (In) and oxygen (hereinafter, an In layer) and a layer containing the element M, zinc (Zn), and oxygen (hereinafter, an (M,Zn) layer) are stacked. Indium and the element M can be replaced with each other. Therefore, indium may be contained in the (M,Zn) layer. In addition, the element M may be contained in the In layer. Note that Zn may be contained in the In layer. Such a layered structure is observed as a lattice image in a high-resolution TEM (Transmission Electron Microscope) image, for example.

When the CAAC-OS film is subjected to structural analysis by Out-of-plane XRD measurement with an XRD apparatus using θ/2θ scanning, for example, a peak indicating c-axis alignment is detected at 2θ of 31° or around 31°. Note that the position of the peak indicating c-axis alignment (the value of 2θ) may change depending on the kind, composition, or the like of the metal element contained in the CAAC-OS.

For example, a plurality of bright spots are observed in the electron diffraction pattern of the CAAC-OS film. Note that one spot and another spot are observed point-symmetrically with a spot of the incident electron beam passing through a sample (also referred to as a direct spot) as the symmetric center.

When the crystal region is observed from the particular direction, a lattice arrangement in the crystal region is basically a hexagonal lattice arrangement; however, a unit lattice is not always a regular hexagon and is a non-regular hexagon in some cases. A pentagonal lattice arrangement, a heptagonal lattice arrangement, and the like are included in the distortion in some cases. Note that a clear crystal grain boundary (grain boundary) cannot be observed even in the vicinity of the distortion in the CAAC-OS. That is, formation of a crystal grain boundary is inhibited by the distortion of lattice arrangement. This is probably because the CAAC-OS can tolerate distortion owing to a low density of arrangement of oxygen atoms in the a-b plane direction, an interatomic bond distance changed by substitution of a metal atom, and the like.

Note that a crystal structure in which a clear crystal grain boundary is observed is what is called polycrystal. It is highly probable that the crystal grain boundary becomes a recombination center and captures carriers and thus decreases the on-state current and field-effect mobility of a transistor, for example. Thus, the CAAC-OS in which no clear crystal grain boundary is observed is one of crystalline oxides having a crystal structure suitable for a semiconductor layer of a transistor. Note that Zn is preferably contained to form the CAAC-OS. For example, In—Zn oxide and In—Ga—Zn oxide are suitable because they can inhibit generation of a crystal grain boundary as compared with In oxide.

The CAAC-OS is an oxide semiconductor with high crystallinity in which no clear crystal grain boundary is observed. Thus, in the CAAC-OS, a reduction in electron mobility due to the crystal grain boundary is unlikely to occur. Moreover, since the crystallinity of an oxide semiconductor might be decreased by entry of impurities, formation of defects, or the like, the CAAC-OS can be regarded as an oxide semiconductor that has small amounts of impurities and defects (e.g., oxygen vacancies). Thus, an oxide semiconductor including the CAAC-OS is physically stable. Therefore, the oxide semiconductor including the CAAC-OS is resistant to heat and has high reliability. In addition, the CAAC-OS is stable with respect to high temperature in the manufacturing process (what is called thermal budget). Accordingly, the use of the CAAC-OS for the OS transistor can extend the degree of freedom of the manufacturing process.

[nc-OS]

In the nc-OS, a microscopic region (e.g., a region with a size greater than or equal to 1 nm and less than or equal to 10 nm, in particular, a region with a size greater than or equal to 1 nm and less than or equal to 3 nm) has a periodic atomic arrangement. In other words, the nc-OS includes a fine crystal. Note that the size of the fine crystal is, for example, greater than or equal to 1 nm and less than or equal to 10 nm, particularly greater than or equal to 1 nm and less than or equal to 3 nm; thus, the fine crystal is also referred to as a nanocrystal. Furthermore, there is no regularity of crystal orientation between different nanocrystals in the nc-OS. Thus, the orientation in the whole film is not observed. Accordingly, the nc-OS cannot be distinguished from an a-like OS or an amorphous oxide semiconductor by some analysis methods. For example, when an nc-OS film is subjected to structural analysis by Out-of-plane XRD measurement with an XRD apparatus using θ/2° scanning, a peak indicating crystallinity is not detected. Furthermore, a diffraction pattern like a halo pattern is observed when the nc-OS film is subjected to electron diffraction (also referred to as selected-area electron diffraction) using an electron beam with a probe diameter larger than the diameter of a nanocrystal (e.g., larger than or equal to 50 nm). Meanwhile, in some cases, a plurality of spots in a ring-like region with a direct spot as the center are observed in a nanobeam electron diffraction pattern of the nc-OS film obtained using an electron beam with a probe diameter nearly equal to or smaller than the diameter of a nanocrystal (e.g., larger than or equal to 1 nm and smaller than or equal to 30 nm).

### [A-Like OS]

The a-like OS is an oxide semiconductor having a structure between those of the nc-OS and the amorphous oxide semiconductor. The a-like OS contains a void or a low-density region. That is, the a-like OS has lower crystallinity than the nc-OS and the CAAC-OS. Moreover, the a-like OS has higher hydrogen concentration in the film than the nc-OS and the CAAC-OS.

### <<Structure of Oxide Semiconductor>>

Next, the above-described CAC-OS is described in detail. Note that the CAC-OS relates to the material composition.

### [CAC-OS]

The CAC-OS refers to one composition of a material in which elements constituting a metal oxide are unevenly distributed with a size greater than or equal to 0.5 nm and less than or equal to 10 nm, preferably greater than or equal to 1 nm and less than or equal to 3 nm, or a similar size, for example. Note that a state in which one or more metal elements are unevenly distributed and regions including the metal element(s) are mixed with a size greater than or equal to 0.5 nm and less than or equal to 10 nm, preferably greater than or equal to 1 nm and less than or equal to 3 nm, or a similar size in a metal oxide is hereinafter referred to as a mosaic pattern or a patch-like pattern.

In addition, the CAC-OS has a composition in which materials are separated into a first region and a second region to form a mosaic pattern, and the first regions are distributed in the film (this composition is hereinafter also referred to as a cloud-like composition). That is, the CAC-OS is a composite metal oxide having a composition in which the first regions and the second regions are mixed.

Here, the atomic ratios of In, Ga, and Zn to the metal elements contained in the CAC-OS in In—Ga—Zn oxide are denoted by [In], [Ga], and [Zn], respectively. For example, the first region in the CAC-OS in the In—Ga—Zn oxide has [In] higher than that in the composition of the CAC-OS. Moreover, the second region has [Ga] higher than that in the composition of the CAC-OS. For example, the first region has higher [In] and lower [Ga] than the second region. Moreover, the second region has higher [Ga] and lower [In] than the first region.

Specifically, the first region contains indium oxide, indium zinc oxide, or the like as its main component. The second region contains gallium oxide, gallium zinc oxide, or the like as its main component. That is, the first region can be referred to as a region containing In as its main component. The second region can be referred to as a region containing Ga as its main component.

Note that a clear boundary between the first region and the second region cannot be observed in some cases.

In a material composition of a CAC-OS in In—Ga—Zn oxide that contains In, Ga, Zn, and O, regions containing Ga as a main component are observed in part of the CAC-OS and regions containing In as a main component are observed in part thereof. These regions are randomly present to form a mosaic pattern. Thus, it is suggested that the CAC-OS has a structure in which metal elements are unevenly distributed.

The CAC-OS can be formed by a sputtering method under a condition where a substrate is not heated, for example. Moreover, in the case of forming the CAC-OS by a sputtering method, any one or more selected from an inert gas (typically, argon), an oxygen gas, and a nitrogen gas are used as a film formation gas. The ratio of the flow rate of an oxygen gas to the total flow rate of the film formation gas at the time of film formation is preferably as low as possible, and for example, the ratio of the flow rate of an oxygen gas to the total flow rate of the film formation gas at the time of film formation is preferably higher than or equal to 0% and lower than 30%, further preferably higher than or equal to 0% and lower than or equal to 10%.

For example, energy dispersive X-ray spectroscopy (EDX) is used to obtain EDX mapping, and according to the EDX mapping, the CAC-OS in the In—Ga—Zn oxide has a structure in which the region containing In as its main component (the first region) and the region containing Ga as its main component (the second region) are unevenly distributed and mixed.

Here, the first region has higher conductivity than the second region. In other words, when carriers flow through the first region, the conductivity of a metal oxide is exhibited. Accordingly, when the first regions are distributed in a metal oxide like a cloud, high field-effect mobility (μ) can be achieved.

The second region has a higher insulating property than the first region. In other words, when the second regions are distributed in a metal oxide, leakage current can be inhibited.

Thus, in the case where a CAC-OS is used for a transistor, by the complementary action of the conductivity due to the first region and the insulating property due to the second region, the CAC-OS can have a switching function (On/Off function). That is, the CAC-OS has a conducting function in part of the material and has an insulating function in another part of the material; as a whole, the CAC-OS has a function of a semiconductor. Separation of the conducting function and the insulating function can maximize each function. Accordingly, when the CAC-OS is used for a transistor, a high on-state current (Ion), high field-effect mobility 04 and excellent switching operation can be achieved.

A transistor using the CAC-OS has high reliability. Thus, the CAC-OS is most suitable for a variety of semiconductor devices such as display apparatuses.

An oxide semiconductor has various structures with different properties. Two or more kinds among the amorphous oxide semiconductor, the polycrystalline oxide semiconductor, the a-like OS, the CAC-OS, the nc-OS, and the CAAC-OS may be included in an oxide semiconductor of one embodiment of the present invention.

### <Transistor Including Oxide Semiconductor>

Next, the case where the above oxide semiconductor is used for a transistor is described.

When the above oxide semiconductor is used for a transistor, a transistor with high field-effect mobility can be obtained. In addition, a transistor having high reliability can be obtained.

An oxide semiconductor having a low carrier concentration is preferably used in a transistor. For example, the carrier concentration of an oxide semiconductor is lower than or equal to 1×10¹⁷ cm⁻³, preferably lower than or equal to 1×10¹⁵ cm⁻³, further preferably lower than or equal to 1×10¹³ cm⁻³, still further preferably lower than or equal to 1×10¹¹ cm⁻³, yet further preferably lower than 1×10¹⁰ cm⁻³, and higher than or equal to 1×10⁻⁹ cm⁻³. In order to reduce the carrier concentration in an oxide semiconductor film, the impurity concentration in the oxide semiconductor film is reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and might behave like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film also be reduced. Examples of impurities include hydrogen, nitrogen, an alkali metal, an alkaline earth metal, iron, nickel, and silicon.

### <Impurity>

Here, the influence of each impurity in the oxide semiconductor is described.

When silicon or carbon, which is one of Group 14 elements, is contained in the oxide semiconductor, defect states are formed in the oxide semiconductor. Thus, the concentration of silicon or carbon in the oxide semiconductor and the concentration of silicon or carbon in the vicinity of an interface with the oxide semiconductor (the concentration obtained by secondary ion mass spectrometry (SIMS)) are each set lower than or equal to 2×10¹⁸ atoms/cm⁻³, preferably lower than or equal to 2×10¹⁷ atoms/cm⁻³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the oxide semiconductor, which is obtained by SIMS, is set lower than or equal to 1×10¹⁸ atoms/cm⁻³, preferably lower than or equal to 2×10¹⁶ atoms/cm⁻³.

Furthermore, when the oxide semiconductor contains nitrogen, the oxide semiconductor easily becomes n-type by generation of electrons serving as carriers and an increase in carrier concentration. As a result, a transistor using an oxide semiconductor containing nitrogen as a semiconductor is likely to have normally-on characteristics. When nitrogen is contained in the oxide semiconductor, trap states are sometimes formed. This might make the electrical characteristics of the transistor unstable. Therefore, the concentration of nitrogen in the oxide semiconductor, which is obtained by SIMS, is set lower than 5×10¹⁹ atoms/cm⁻³, preferably lower than or equal to 5×10¹⁸ atoms/cm⁻³, further preferably lower than or equal to 1×10¹⁸ atoms/cm⁻³, still further preferably lower than or equal to 5×10¹⁷ atoms/cm⁻³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor containing hydrogen is likely to have normally-on characteristics. Accordingly, hydrogen in the oxide semiconductor is preferably reduced as much as possible. Specifically, the hydrogen concentration in the oxide semiconductor, which is obtained by SIMS, is set lower than 1×10²⁰ atoms/cm⁻³, preferably lower than 1×10¹⁹ atoms/cm⁻³, further preferably lower than 5×10¹⁸ atoms/cm⁻³, still further preferably lower than 1×10¹⁸ atoms/cm⁻³.

When an oxide semiconductor with sufficiently reduced impurities is used for the channel formation region of the transistor, stable electrical characteristics can be given.

This embodiment can be combined with the other embodiments as appropriate.

### Embodiment 6

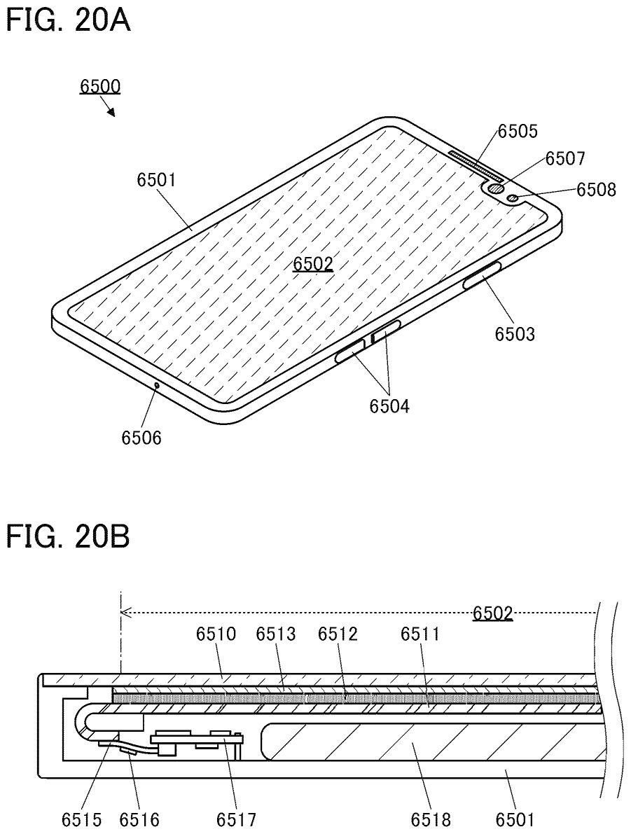

In this embodiment, electronic devices of embodiments of the present invention will be described with reference to FIG. 20 to FIG. 22.

An electronic device of this embodiment is provided with the display apparatus of one embodiment of the present invention in a display portion. The display apparatus of one embodiment of the present invention can be easily increased in resolution and definition. Thus, the display apparatus of one embodiment of the present invention can be used for a display portion of a variety of electronic devices.

Examples of electronic devices include a digital camera, a digital video camera, a digital photo frame, a mobile phone, a portable game console, a portable information terminal, and an audio reproducing device in addition to electronic devices with a relatively large screen, such as a television device, a desktop or notebook personal computer, a monitor of a computer or the like, digital signage, and a large game machine like a pachinko machine.

The display apparatus of one embodiment of the present invention can have high resolution, and thus can be favorably used for an electronic device having a relatively small display portion. Examples of such an electronic device include watch-type and bracelet-type information terminal devices (wearable devices) and wearable devices capable of being worn on a head, such as a VR (Virtual Reality) device like a head-mounted display, a glasses-type AR (Augmented Reality) device, and an MR (Mixed Reality) device.

The definition of the display apparatus of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, the definition is preferably 4K, 8K, or higher. Furthermore, the pixel density (resolution) of the display apparatus of one embodiment of the present invention is preferably higher than or equal to 100 ppi, higher than or equal to 300 ppi, further preferably higher than or equal to 500 ppi, still further preferably higher than or equal to 1000 ppi, still further preferably higher than or equal to 2000 ppi, still further preferably higher than or equal to 3000 ppi, still further preferably higher than or equal to 5000 ppi, and yet further preferably higher than or equal to 7000 ppi. With the use of such a display apparatus having one or both of high definition and high resolution, the electronic device can provide higher realistic sensation, sense of depth, and the like in personal use such as portable use and home use. There is no particular limitation on the screen ratio (aspect ratio) of the display apparatus of one embodiment of the present invention. For example, the display apparatus is compatible with a variety of screen ratios such as 1:1 (a square), 4:3, 16:9, and 16:10.

The electronic device in this embodiment may include a sensor (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

An electronic device 6500 illustrated in FIG. 20A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, and the like. The display portion 6502 has a touch panel function.

The display apparatus of one embodiment of the present invention can be used for the display portion 6502.

FIG. 20B is a schematic cross-sectional view including the end portion of the housing 6501 on the microphone 6506 side.

A protection member 6510 having a light-transmitting property is provided on a display surface side of the housing 6501, and a display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used as the display panel 6511. Thus, an extremely lightweight electronic device can be obtained. Since the display panel 6511 is extremely thin, the battery 6518 with high capacity can be mounted while the thickness of the electronic device is reduced. Moreover, part of the display panel 6511 is folded back so that a connection portion with the FPC 6515 is provided on the back side of the pixel portion, whereby an electronic device with a narrow bezel can be obtained.

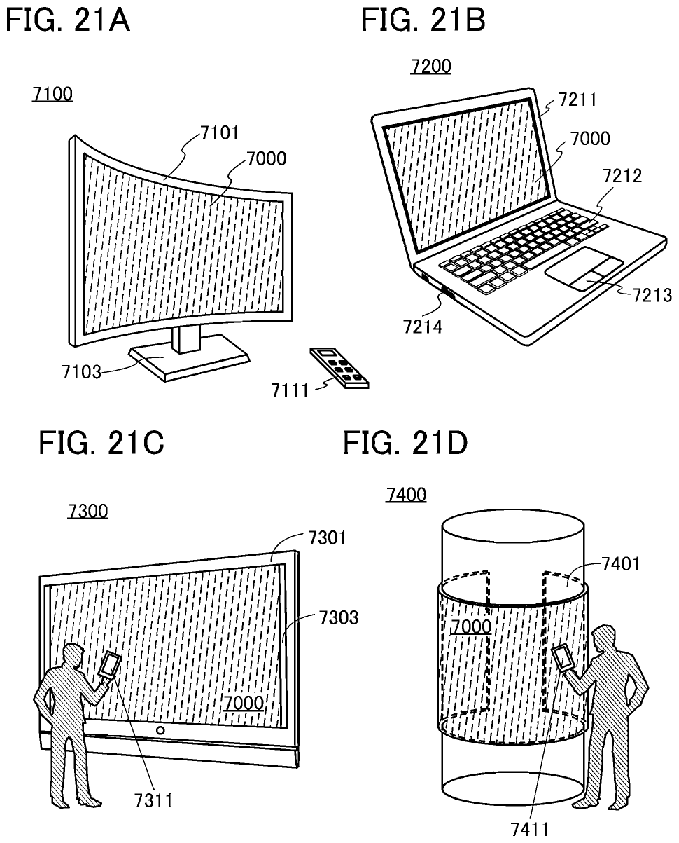

FIG. 21A illustrates an example of a television device. In a television device 7100, a display portion 7000 is incorporated in a housing 7101. Here, the housing 7101 is supported by a stand 7103.

The display apparatus of one embodiment of the present invention can be used for the display portion 7000.

Operation of the television device 7100 illustrated in FIG. 21A can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be operated and videos displayed on the display portion 7000 can be operated.

Note that the television device 7100 has a structure in which a receiver, a modem, and the like are provided. A general television broadcast can be received with the receiver. When the television device is connected to a communication network with or without wires via the modem, one-way (from a transmitter to a receiver) or two-way (between a transmitter and a receiver or between receivers, for example) data communication can be performed.

FIG. 21B illustrates an example of a notebook personal computer. A notebook personal computer 7200 includes a housing 7211, a keyboard 7212, a pointing device 7213, an external connection port 7214, and the like. In the housing 7211, the display portion 7000 is incorporated.

The display apparatus of one embodiment of the present invention can be used for the display portion 7000.

FIG. 21C and FIG. 21D illustrate examples of digital signage.

Digital signage 7300 illustrated in FIG. 21C includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 21D is digital signage 7400 attached to a cylindrical pillar 7401. The digital signage 7400 includes the display portion 7000 provided along a curved surface of the pillar 7401.

The display apparatus of one embodiment of the present invention can be used for the display portion 7000 in FIG. 21C and FIG. 21D.

A larger area of the display portion 7000 can increase the amount of information that can be provided at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As shown in FIG. 21C and FIG. 21D, it is preferable that the digital signage 7300 or the digital signage 7400 can work with an information terminal 7311 or an information terminal 7411 such as a smartphone a user has through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

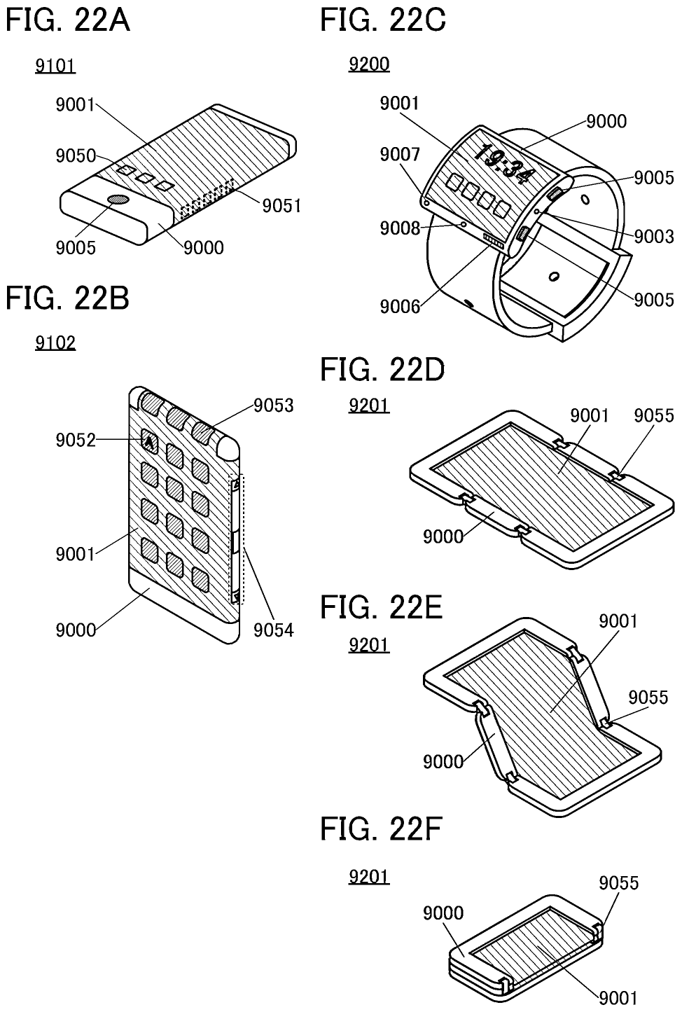

Electronic devices illustrated in FIG. 22A to FIG. 22F each include a housing 9000, a display portion 9001, a speaker 9003, an operation key 9005 (including a power switch or an operation switch), a connection terminal 9006, a sensor 9007 (a sensor having a function of measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays), a microphone 9008, and the like.

The display apparatus of one embodiment of the present invention can be used for the display portion 9001 in FIG. 22A to FIG. 22F.

The electronic devices illustrated in FIG. 22A to FIG. 22F have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. The electronic devices may each be provided with a camera or the like and have a function of taking a still image or a moving image, a function of storing the taken image in a storage medium (an external storage medium or a storage medium incorporated in the camera), a function of displaying the taken image on the display portion, or the like.

The electronic devices illustrated in FIG. 22A to FIG. 22F are described in detail below.

FIG. 22A is a perspective view illustrating a portable information terminal 9101. For example, the portable information terminal 9101 can be used as a smartphone. Note that the portable information terminal 9101 may include the speaker 9003, the connection terminal 9006, the sensor 9007, or the like. The portable information terminal 9101 can display characters and image information on its plurality of surfaces. FIG. 22A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 22B is a perspective view illustrating a portable information terminal 9102. The portable information terminal 9102 has a function of displaying information on three or more surfaces of the display portion 9001. Shown here is an example in which information 9052, information 9053, and information 9054 are displayed on different surfaces. For example, a user of the portable information terminal 9102 can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 22C is a perspective view illustrating a watch-type portable information terminal 9200. For example, the portable information terminal 9200 can be used as a Smartwatch (registered trademark). The display surface of the display portion 9001 is curved, and an image can be displayed on the curved display surface. Furthermore, intercommunication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 22D to FIG. 22F are perspective views illustrating a foldable portable information terminal 9201. FIG. 22D is a perspective view of an opened state of the portable information terminal 9201, FIG. 22F is a perspective view of a folded state thereof, and FIG. 22E is a perspective view of a state in the middle of change from one of FIG. 22D and FIG. 22F to the other. The portable information terminal 9201 is highly portable when folded. When the portable information terminal 9201 is opened, a seamless large display region is highly browsable. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

This embodiment can be combined with the other embodiments as appropriate.

### Example

In this example, inference results of the position data of non-contact objects obtained by using the display apparatus of one embodiment of the present invention and a machine learning model using AI will be described.

In this example, first, images of the non-contact objects captured by the display apparatus were obtained. Next, learning of the machine learning model was performed using a data set including images and their position data. After that, images were input to the learned model, and the inference results of the position data of the objects obtained by the learned model were evaluated.

### [Image Acquisition]

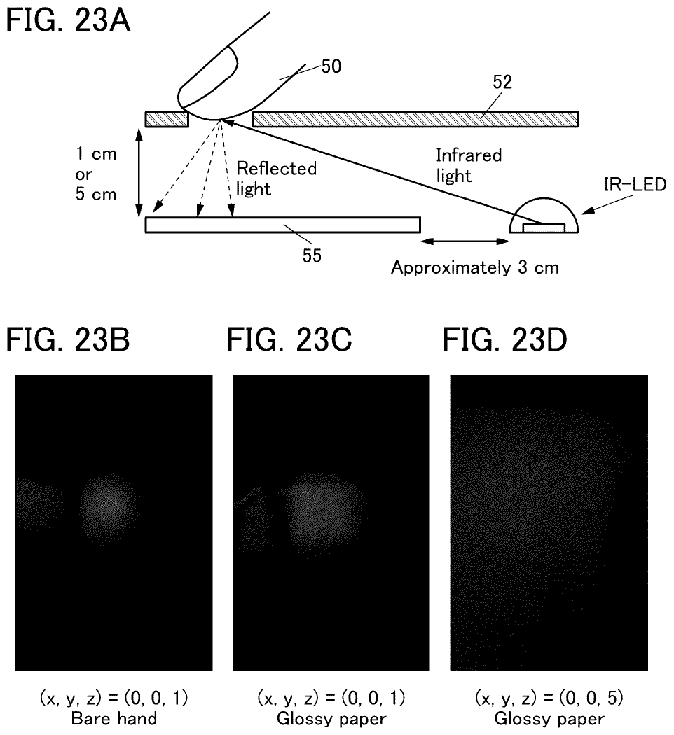

FIG. 23A is a schematic diagram of an evaluation system illustrating, for example, the positional relationship between the display apparatus and a light source used for the evaluation.

In this example, the evaluation was performed using a display apparatus 55 including the subpixel R, the subpixel G, the subpixel B, and the subpixel IRS in a pixel.

The subpixel R includes a light-emitting device that emits red light. The subpixel G includes a light-emitting device that emits green light. The subpixel B includes a light-emitting device that emits blue light. Organic EL devices were used as the light-emitting devices.

The subpixel IRS includes a light-receiving device that detects infrared light. An organic optical sensor was used as the light-receiving device.

An LED emitting infrared light with a wavelength of 880 nm was used as a light source IR-LED, and was driven at 0.3 A. The distance between the light source IR-LED and the display apparatus 55 was approximately 3 cm.

In this example, reflected light obtained by reflecting infrared light emitted from the light source IR-LED by an object 50 was detected by the light-receiving device included in the subpixel IRS.

Three kinds of objects 50 were used: a finger of a bare hand, a gray glove, and glossy paper (with a total luminous reflectance of 80%). Note that the gray glove is made of conductive fiber in which copper sulfide is mixed with chemical fiber, and can be detected by a capacitive touch sensor.

The evaluation was performed in the following manner: an opening (also referred to as a window) with 1 cm square was formed in a black plate 52 (with a total luminous reflectance of 5%), and the object 50 was exposed through the opening. Accordingly, image capturing data including the position data of the object and information on light reflection by the object can be obtained. It can be said that the image capturing data corresponds to an image obtained by cutting a part of an image captured by the display apparatus, which is used for inferring the position of the object.

Fifty different coordinates were used as the coordinates of the object 50 in a three-dimensional space. There were 25 conditions of the position in the horizontal direction (the product of 5 conditions for the X direction, −2 cm, −1 cm, 0 cm (reference point), 1 cm, and 2 cm, and 5 conditions for the Y direction, −2 cm, −1 cm, 0 cm (reference point), 1 cm, and 2 cm). Note that the position of the object 50 in the horizontal direction was adjusted by moving a stage movable in the X direction and the Y direction at 1-cm intervals. Furthermore, there were two conditions of the position in the perpendicular direction: positions 1 cm and 5 cm away from the display apparatus.

FIG. 23B to FIG. 23D show examples of images of the object 50 actually captured by the display apparatus 55. FIG. 23B shows an image capturing result of a finger of a bare hand at a position of (x, y, z)=(0 cm, 0 cm, 1 cm), FIG. 23C shows an image capturing result of glossy paper at a position of (x, y, z)=(0 cm, 0 cm, 1 cm), and FIG. 23D shows an image capturing result of glossy paper at a position of (x, y, z)=(0 cm, 0 cm, 5 cm).

The comparison between FIG. 23B and FIG. 23C demonstrates that the image capturing results differ depending on the kind of the object 50 even when the positions of the object 50 are the same. Furthermore, the comparison between FIG. 23C and FIG. 23D demonstrates that the image capturing results differ depending on the position of the object 50 even when the kinds of the object 50 are the same.

In this example, 15000 images of the object 50 captured by the display apparatus 55 in the above manner were prepared.

### [Learning of Machine Learning Model]

Next, learning of the machine learning model using AI was performed using a data set including the images of the object 50 captured by the display apparatus 55 and their position data (x, y, z) as teacher data.

Specifically, image data was given as input data (examples) and position data was given as output data (answers) to the machine learning model so that learning of the machine learning model was performed.

As the machine learning model, AlexNet and MobileNet, each of which was a model using a convolutional neural network (CNN), were used. Note that MobileNet is a light model having fewer parameters than AlexNet.

Among the 15000 obtained images, 14250 images were used for learning and the rest 750 images were used for evaluation of the learned model.

Each of the image data was resized to 100 pixels×100 pixels, converted to the arrangement of 100×100, and input to the machine learning model.

In this example, a regression model that estimates the value of the position data (x, y, z) when image data is input was created.

### [Evaluation of Machine Learning Model]

First, image data was input to the learned model using AlexNet and inference of the position data (x, y, z) was performed. Table 1 shows examples of the inference results.

TABLE 1

| | | Position data | | | Inference result | | | Error | | |
|---|---|---|---|---|---|---|---|---|---|---|
| | Object | x | y | z | x | y | z | x | y | z |
| Sample 1 | Bare hand | −2 | 1 | 5 | −2.00 | 1.00 | 4.97 | 0.00 | 0.00 | 0.03 |
| Sample 2 | Glove | −1 | −2 | 1 | −1.00 | −2.01 | 1.00 | 0.00 | 0.01 | 0.00 |
| Sample 3 | Glossy paper | 1 | −2 | 5 | 0.99 | −1.98 | 4.90 | 0.01 | 0.02 | 0.10 |

Table 1 revealed that the position of the object was able to be inferred from an image with high accuracy regardless of the kind of object.

Next, image data was input to the learned model using MobileNet and inference of the position data (x, y, z) was performed.

Table 2 shows the numbers of parameters and the averages of inference result errors of the 750 images of the learned model using AlexNet and the learned model using MobileNet.

TABLE 2

| Model | Number of parameters | Average of errors |
|---|---|---|
| AlexNet | 57,016,131 | 0.019 |
| MobileNet | 2,227,715 | 0.012 |

It was revealed that AlexNet and MobileNet were able to infer the position of the object from an image with high accuracy regardless of the difference in the number of parameters.

The results in this example revealed that when an image of a non-contact object was captured by the display apparatus of one embodiment of the present invention and the captured image data was input to a machine learning model, the position data of the object was able to be inferred. In this manner, the object can be detected even when the object is not touching the display apparatus. This indicates that operation of a screen such as swipe or scroll can be performed in a non-contact manner.

### REFERENCE NUMERALS

CL: wiring, IR-LED: light source, IR: subpixel, IRS: subpixel, M11: transistor, M12: transistor, M13: transistor, M14: transistor, M15: transistor, NN: neural network, PS: subpixel, RS: wiring, SE: wiring, SW: wiring, TX: wiring, VCP: wiring, VPI: wiring, VRS: wiring, WX: wiring, 10: electronic device, 11: processing portion, 12: display portion, 13: memory portion, 15: image capturing data, 17: image, 19: position data, 31B: light, 31G: light, 31IR: infrared light, 31R: light, 32G: reflected light, 3218: reflected light, 50: object, 52: black plate, 55: display apparatus, 100A: display apparatus, 100B: display apparatus, 100C: display apparatus, 100D: display apparatus, 100E: display apparatus, 100F: display apparatus, 100G: display apparatus, 100: display apparatus, 101: layer including transistors, 102: substrate, 103: housing, 104: light source, 105: protection member, 106: substrate, 108: object, 109a: pixel, 109b: pixel, 110a: subpixel, 110b: subpixel, 110c: subpixel, 110d: subpixel, 110e: subpixel, 110: pixel, 111a: conductive layer, 111b: conductive layer, 111c: conductive layer, 111d: conductive layer, 111e: conductive layer, 112a: conductive layer, 112b: conductive layer, 112c: conductive layer, 112d: conductive layer, 113a: first layer, 113b: second layer, 113c: third layer, 113d: fifth layer, 113e: sixth layer, 114: fourth layer, 115: common electrode, 117: light-blocking layer, 118a: sacrificial layer, 118b: sacrificial layer, 118c: sacrificial layer, 118d: sacrificial layer, 119a: sacrificial layer, 119b: sacrificial layer, 120: substrate, 121: insulating layer, 122: resin layer, 123: conductive layer, 125: insulating layer, 126a: conductive layer, 126b: conductive layer, 126c: conductive layer, 126d: conductive layer, 127: insulating layer, 128: layer, 130a: light-emitting device, 130B: light-emitting device, 130b: light-emitting device, 130c: light-emitting device, 130G: light-emitting device, 1301R: light-emitting device, 130R: light-emitting device, 131: protective layer, 132R: coloring layer, 134: space, 139: region, 140: connection portion, 142: adhesive layer, 150d: light-receiving device, 150e: light-receiving device, 1501RS: light-receiving device, 150PS: light-receiving device, 151: substrate, 152: substrate, 153: insulating layer, 162: display portion, 164: circuit, 165: wiring, 166: conductive layer, 172: FPC, 173: IC, 180A: pixel, 180B: pixel, 180C: pixel, 201: transistor, 204: connection portion, 205: transistor, 209: transistor, 210: transistor, 211: insulating layer, 213: insulating layer, 214: insulating layer, 215: insulating layer, 218: insulating layer, 221: conductive layer, 222a: conductive layer, 222b: conductive layer, 223: conductive layer, 225: insulating layer, 231i: channel formation region, 231n: low-resistance region, 231: semiconductor layer, 242: connection layer, 772: lower electrode, 785: layer, 786a: EL layer, 786b: EL layer, 786: EL layer, 788: upper electrode, 4411: light-emitting layer, 4412: light-emitting layer, 4413: light-emitting layer, 4420: layer, 4421: layer, 4422: layer, 4430: layer, 4431: layer, 4432: layer, 4440: charge-generation layer, 6500: electronic device, 6501: housing, 6502: display portion, 6503: power supply button, 6504: button, 6505: speaker, 6506: microphone, 6507: camera, 6508: light source, 6510: protection member, 6511: display panel, 6512: optical member, 6513: touch sensor panel, 6515: FPC, 6516: IC, 6517: printed circuit board, 6518: battery, 7000: display portion, 7100: television device, 7101: housing, 7103: stand, 7111: remote controller, 7200: notebook personal computer, 7211: housing, 7212: keyboard, 7213: pointing device, 7214: external connection port, 7300: digital signage, 7301: housing, 7303: speaker, 7311: information terminal, 7400: digital signage, 7401: pillar, 7411: information terminal, 9000: housing, 9001: display portion, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9200: portable information terminal, 9201: portable information terminal

1. An electronic device comprising a display portion, a processing portion, and a memory portion,
wherein the display portion comprises a display apparatus comprising a light-emitting device and a light-receiving device,
wherein the display portion is configured to display an image using the light-emitting device and is configured to capture an image using the light-receiving device,
wherein the memory portion has a machine learning model using a neural network, and
wherein the processing portion is configured to infer position data of an object not in contact with the electronic device using the machine learning model from image capturing data captured by the display portion.

2. An electronic device comprising a display portion, a processing portion, and a memory portion,
wherein the display portion comprises a display apparatus comprising a first pixel,
wherein the first pixel comprises a first light-emitting device, a first light-receiving device, and a second light-receiving device,
wherein a wavelength range of light detected by the first light-receiving device comprises a maximum peak wavelength in an emission spectrum of the first light-emitting device,
wherein the second light-receiving device is configured to detect infrared light,
wherein the display portion is configured to display an image using the first light-emitting device and is configured to capture an image using one or both of the first light-receiving device and the second light-receiving device,
wherein the memory portion has a machine learning model using a neural network, and
wherein the processing portion is configured to infer position data of an object not in contact with the electronic device using the machine learning model from image capturing data captured by the display portion.

3. An electronic device comprising a display portion, a processing portion, and a memory portion,
wherein the display portion comprises a display apparatus comprising a first pixel,
wherein the first pixel comprises a first subpixel, a second subpixel, a third subpixel, a fourth subpixel, and a fifth subpixel,
wherein the first subpixel comprises a first light-emitting device and is configured to emit red light,
wherein the second subpixel comprises a second light-emitting device is configured to emit green light,
wherein the third subpixel comprises a third light-emitting device and is configured to emit blue light,
wherein the fourth subpixel comprises a first light-receiving device,
wherein a wavelength range of light detected by the first light-receiving device comprises a maximum peak wavelength in an emission spectrum of at least one of the first light-emitting device, the second light-emitting device, and the third light-emitting device,
wherein the fifth subpixel comprises a second light-receiving device and is configured to detect infrared light,
wherein the display portion is configured to display an image using the first subpixel, the second subpixel, and the third subpixel and is configured to capture an image using one or both of the first light-receiving device and the second light-receiving device,
wherein the memory portion has a machine learning model using a neural network, and
wherein the processing portion is configured to infer position data of an object not in contact with the electronic device using the machine learning model from image capturing data captured by the display portion.

4. The electronic device according to claim 2,
wherein an area of a light-receiving region of the first light-receiving device is smaller than an area of a light-receiving region of the second light-receiving device.

5. The electronic device according to claim 2,
wherein the display apparatus further comprises a second pixel, and
wherein the second pixel comprises the first light-emitting device, the first light-receiving device, and a sensor device.

6. The electronic device according to claim 5,
wherein the electronic device is configured to measure, with the sensor device, at least one of force, displacement, position, speed, acceleration, angular velocity, rotational frequency, distance, magnetism, temperature, chemical substance, time, hardness, electric field, electric current, voltage, electric power, radiation, flow rate, humidity, gradient, oscillation, odor, physical condition, pulse, body temperature, and blood oxygen level.

7. The electronic device according to claim 2,
wherein the display apparatus further comprises a second pixel,
wherein the second pixel comprises the first light-emitting device, a fourth light-emitting device, and the first light-receiving device, and
wherein the fourth light-emitting device is configured to emit infrared light.

8. The electronic device according to claim 1, further comprising a fourth light-emitting device,
wherein the fourth light-emitting device is configured to emit infrared light.

9. The electronic device according to claim 8,
wherein the fourth light-emitting device emits light outside the electronic device through the display apparatus.

10. The electronic device according to claim 2, further comprising a fourth light-emitting device,
wherein the fourth light-emitting device is configured to emit infrared light.

11. The electronic device according to claim 10,
wherein the fourth light-emitting device emits light outside the electronic device through the display apparatus.

12. The electronic device according to claim 3, further comprising a fourth light-emitting device,
wherein the fourth light-emitting device is configured to emit infrared light.

13. The electronic device according to claim 12,
wherein the fourth light-emitting device emits light outside the electronic device through the display apparatus.

14. The electronic device according to claim 3,
wherein an area of a light-receiving region of the first light-receiving device is smaller than an area of a light-receiving region of the second light-receiving device.

15. The electronic device according to claim 3,
wherein the display apparatus further comprises a second pixel, and
wherein the second pixel comprises the first light-emitting device, the first light-receiving device, and a sensor device.

16. The electronic device according to claim 15,
wherein the electronic device is configured to measure, with the sensor device, at least one of force, displacement, position, speed, acceleration, angular velocity, rotational frequency, distance, magnetism, temperature, chemical substance, time, hardness, electric field, electric current, voltage, electric power, radiation, flow rate, humidity, gradient, oscillation, odor, physical condition, pulse, body temperature, and blood oxygen level.

17. The electronic device according to claim 3,
wherein the display apparatus further comprises a second pixel,
wherein the second pixel comprises the first light-emitting device, a fourth light-emitting device, and the first light-receiving device, and
wherein the fourth light-emitting device is configured to emit infrared light.
